(19) United States
(12) Patent Application Publication
(10) Pub. No.: US 2025/0313699 A1
(43) Pub. Date: Oct. 9, 2025

(54) CORE-SHELL DYE, PHOTOSENSITIVE RESIN COMPOSITION COMPRISING SAME, PHOTOSENSITIVE RESIN FILM, COLOR FILTER, AND CMOS IMAGE SENSOR

(71) Applicant: SAMSUNG SDI CO., LTD., Yongin-si, Gyeonggi-do (KR)

(72) Inventors: Chaehyuk KO, Suwon-si, Gyeonggi-do (KR); Yeji YANG, Suwon-si, Gyeonggi-do (KR); Sundae KIM, Suwon-si, Gyeonggi-do (KR); Young LEE, Suwon-si, Gyeonggi-do (KR); Arum YU, Suwon-si, Gyeonggi-do (KR)

(21) Appl. No.: 18/031,233

(22) PCT Filed: Dec. 2, 2021
(86) PCT No.: PCT/KR2021/018077

§ 371 Date: Jun. 6, 2025

(30) Foreign Application Priority Data
Dec. 22, 2020 (KR) 10-2020-0181067
Nov. 16, 2021 (KR) 10-2021-0157798

(51) Int. Cl. C09B 67/20; C09B 57/00; C09D 4/06; C09D 7/41; H10F 39/00

(52) U.S. Cl. CPC C09B 67/0065; C09B 57/007; C09D 4/06; C09D 7/41; H10F 39/8053

(57) ABSTRACT

Provided are a core-shell dye that includes a core including a compound represented by a specific chemical formula and a shell surrounding the core, a photosensitive resin composition including the same, a photosensitive resin film manufactured using the photosensitive resin composition, a color filter including the photosensitive resin film, and a CMOS image sensor including the color filter.

### TECHNICAL FIELD

The present disclosure relates to a core-shell dye, a photosensitive resin composition including the same, a photosensitive resin film manufactured using the same, a color filter including the photosensitive resin film, and a CMOS image sensor including the color filter.

### BACKGROUND ART

A liquid crystal display among many types of displays has an advantage of lightness, thinness, low cost, low power consumption for operation, and improved adherence to an integrated circuit and has been more widely used for a laptop computer, a monitor, and a TV screen. The liquid crystal display device includes a lower substrate on which a black matrix, a color filter, and an ITO pixel electrode are formed, and an upper substrate on which an active circuit portion including a liquid crystal layer, a thin film transistor, and a capacitor layer and an ITO pixel electrode are formed. Color filters are formed in a pixel region by sequentially stacking a plurality of pixel portions which are generally formed of three primary colors such as red (R), green (G), and blue (B) in a predetermined order to form each pixel, and a black matrix layer is disposed in a predetermined pattern on a transparent substrate to form a boundary between the pixels.

The pigment dispersion method that is one of methods of forming a color filter provides a colored thin film by repeating a series of processes such as coating a photopolymerizable composition including a colorant on a transparent substrate including a black matrix, exposing a formed pattern to light, removing a non-exposed portion with a solvent, and thermally curing the same. A coloring photosensitive resin composition used for manufacturing a color filter according to the pigment dispersion method generally includes an alkali soluble resin, a photopolymerization monomer, a photopolymerization initiator, an epoxy resin, a solvent, other additives, and the like. The pigment dispersion method is actively applied to manufacture an LCD such as a mobile phone, a laptop, a monitor, and TV. However, a photosensitive resin composition for a color filter for the pigment dispersion method has recently required improved performance as well as excellent pattern characteristics. Particularly, high color reproducibility and high luminance and high contrast ratio characteristics are urgently required.

An image sensor is a part for photographing images in a portable phone camera or DSC (a digital still camera). It may be classified as a charge-coupled device (CCD) image sensor and a complementary metal oxide semiconductor (CMOS) image sensor depending upon the manufacturing process and the application method. A color imaging device for a charge-coupled device image sensor or a complementary metal oxide semiconductor image sensor includes color filters each having filter segments of mixing primary color of red, green, and blue, and the colors are separated. A recent color filter mounted in the color imaging device has a pattern size of 2 μm or less, which is 1/100th to 1/200th of the pattern size of a conventional color filter pattern for LCDs. Accordingly, increased resolution and decreased pattern residues are important factors for determining the performance of a device.

A color filter manufactured by using a pigment-type photosensitive resin composition has a limit in luminance and a contrast ratio due to the size of pigment particles. In addition, a color imaging device for an image sensor needs a smaller dispersion particle diameter for forming a fine pattern. In order to correspond to the requirements, an attempt to realize a color filter having improved luminance and a contrast ratio has been made by introducing a dye forming no particle instead of the pigment to prepare a photosensitive resin composition appropriate for the dye. However, a dye has inferior durability such as light resistance and heat resistance, and the like to a pigment and thus luminance may be deteriorated.

### DISCLOSURE

### Technical Problem

An embodiment provides a core-shell dye having excellent coloring strength, chemical resistance, and contrast ratio characteristics due to low fluorescence quantum efficiency and high light absorption efficiency.

Another embodiment provides a photosensitive resin composition including the core-shell dye.

Another embodiment provides a photosensitive resin film manufactured using the photosensitive resin composition.

Another embodiment provides a color filter including the photosensitive resin film.

Another embodiment provides a CMOS image sensor including the color filter.

### Technical Solution

An embodiment provides a core-shell dye that includes a core including a compound represented by Chemical Formula 1 or Chemical Formula 2 and a shell surrounding the core.

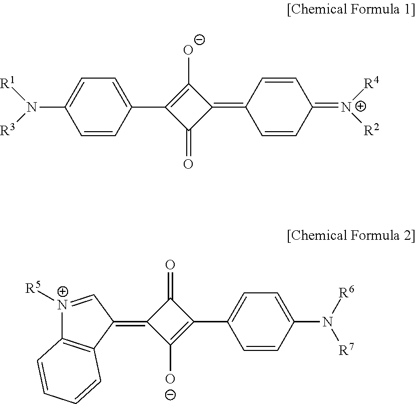

In Chemical Formula 1 or Chemical Formula 2,
R¹ to R⁷ are each independently a substituted or unsubstituted C1 to C20 alkyl group, a substituted or unsubstituted C3 to C20 cycloalkyl group, a substituted or unsubstituted C6 to C20 aryl group, a substituted or unsubstituted C2 to C20 heteroaryl group, or a combination thereof.
R¹ to R⁷ may each independently be a substituted or unsubstituted C1 to C20 alkyl group or a functional group represented by Chemical Formula 3.

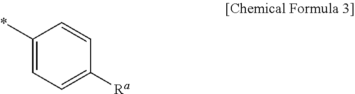

In Chemical Formula 3,
R^{a} is hydrogen, a substituted or unsubstituted C1 to C20 alkyl group, a substituted or unsubstituted C1 to C20 alkoxy group, a nitro group (—NO₂), a glycidoxy group, a (meth)acrylate group, a carbamate group, or a combination thereof.

The core-shell dye may have a molar extinction coefficient of greater than or equal to 3.1×10⁵ M⁻¹·cm⁻¹ and a fluorescence quantum efficiency of less than or equal to 5%.

The compound represented by Chemical Formula 1 may be represented by any one of Chemical Formula 1-1 to Chemical Formula 1-3, and the compound represented by Chemical Formula 2 may be represented by any one of Chemical Formula 2-1 to Chemical Formula 2-4.

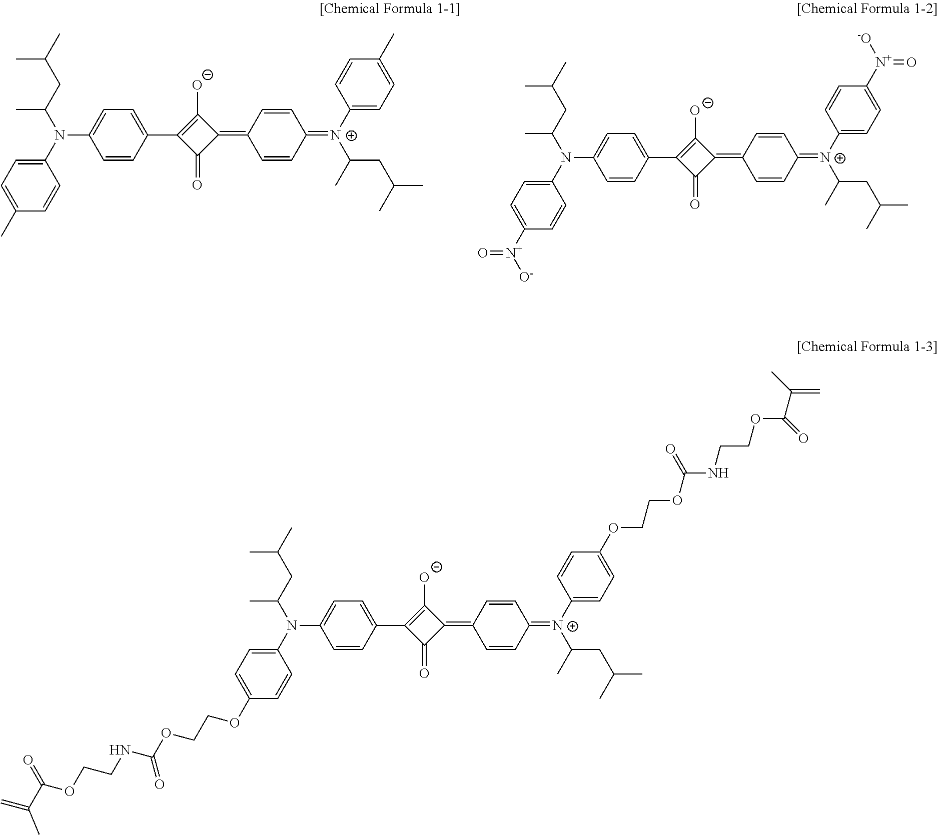

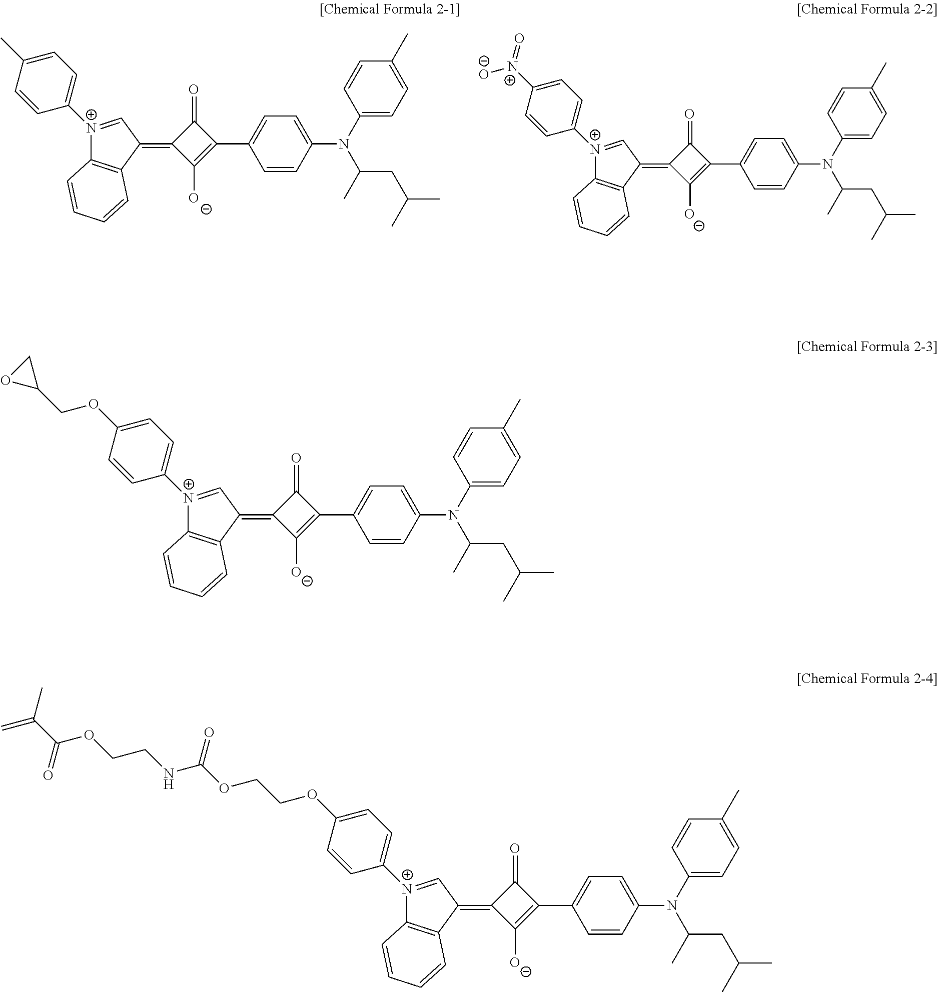 [SMILES: Cc1ccc(N(c2ccc(C3=C([O-])/C(=C4/C=[N+](c5ccc(C)cc5)c5ccccc54)C3=O)cc2)C(C)CC(C)C)cc1 ; Cc1ccc(N(c2ccc(C3=C([O-])/C(=C4/C=[N+](c5ccc([N+](=O)[O-])cc5)c5ccccc54)C3=O)cc2)C(C)CC(C)C)cc1 ; Cc1ccc(N(c2ccc(C3=C([O-])/C(=C4/C=[N+](c5ccc(OCC6CO6)cc5)c5ccccc54)C3=O)cc2)C(C)CC(C)C)cc1 ; C=C(C)C(=O)OCCNC(=O)OCCOc1ccc([N+]2=C/C(=C3\C(=O)C(c4ccc(N(c5ccc(C)cc5)C(C)CC(C)C)cc4)=C3[O-])c3ccccc32)cc1]

The shell may be represented by Chemical Formula 4 or Chemical Formula 5.

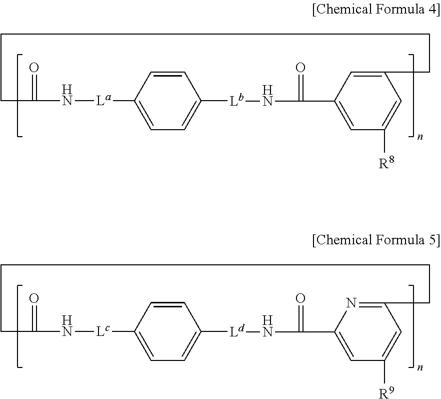

In Chemical Formula 4 or Chemical Formula 5,
R⁸ and R⁹ are each independently hydrogen, a substituted or unsubstituted C1 to C20 alkyl group, a substituted or unsubstituted C1 to C20 alkoxy group, a nitro group (—NO₂), a glycidoxy group, a (meth)acrylate group, a carbamate group, or a combination thereof,
L^{a} to L^{d} are each independently a single bond, or a substituted or unsubstituted C1 to C10 alkylene group, and
n is an integer from 1 to 4.
L^{a} to L^{d} may each independently be a substituted or unsubstituted C1 to C10 alkylene group.

The shell may be represented by Chemical Formula 4-1 or Chemical Formula 5-1.

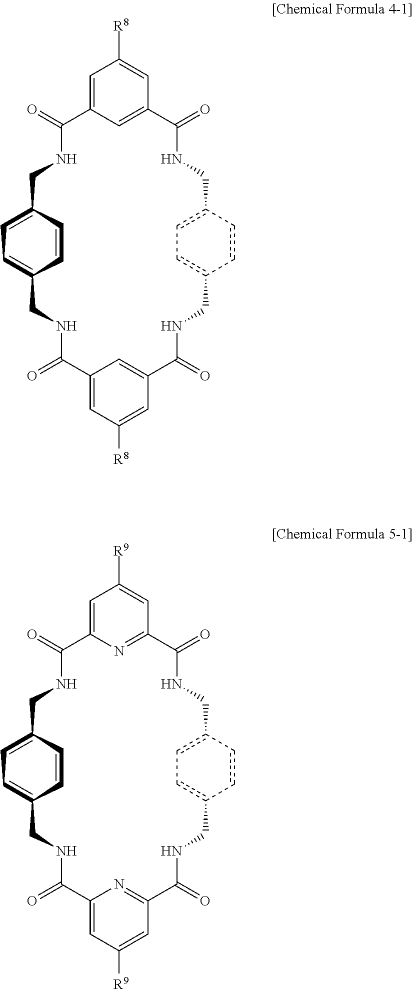

In Chemical Formulas 4-1 and 5-1,
R⁸ and R⁹ are each independently hydrogen, a substituted or unsubstituted C1 to C20 alkyl group, a substituted or unsubstituted C1 to C20 alkoxy group, a nitro group (—NO₂), a glycidoxy group, a (meth)acrylate group, a carbamate group, or a combination thereof.

The shell may be represented by any one of Chemical Formula 4-a to Chemical Formula 4-d and Chemical Formula 5-a to Chemical Formula 5-d.

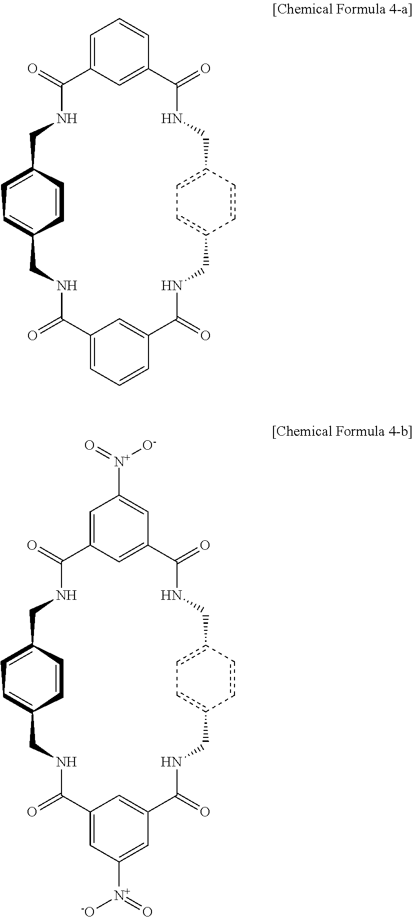

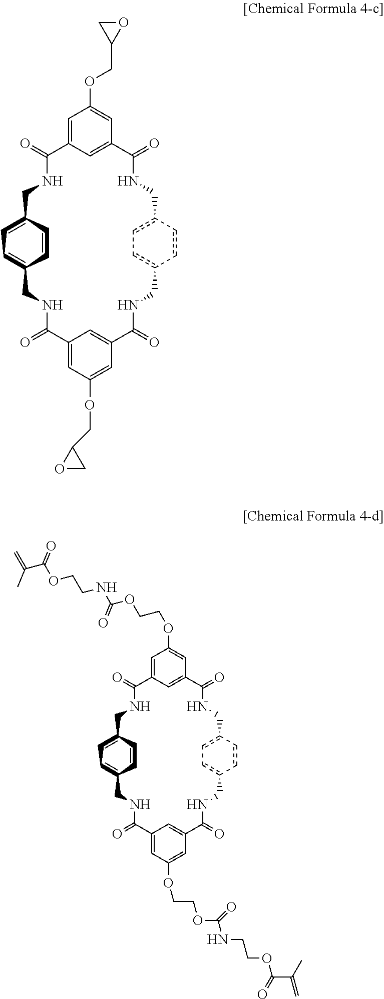

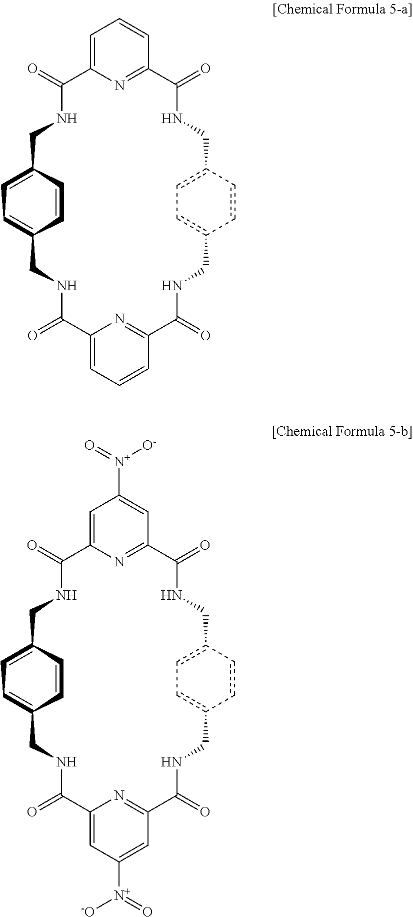

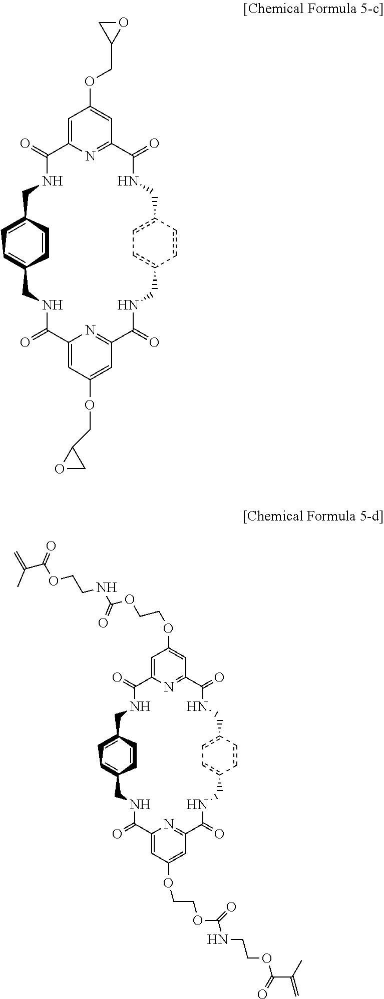

The shell may have a cage width of 6.5 Å to 7.5 Å.

A length of the core may be 1 nm to 3 nm.

The core may have a maximum absorption peak at a wavelength of 590 nm to 670 nm.

The core-shell dye may be represented by any one of the compounds represented by Chemical Formula 6 to Chemical Formula 57.

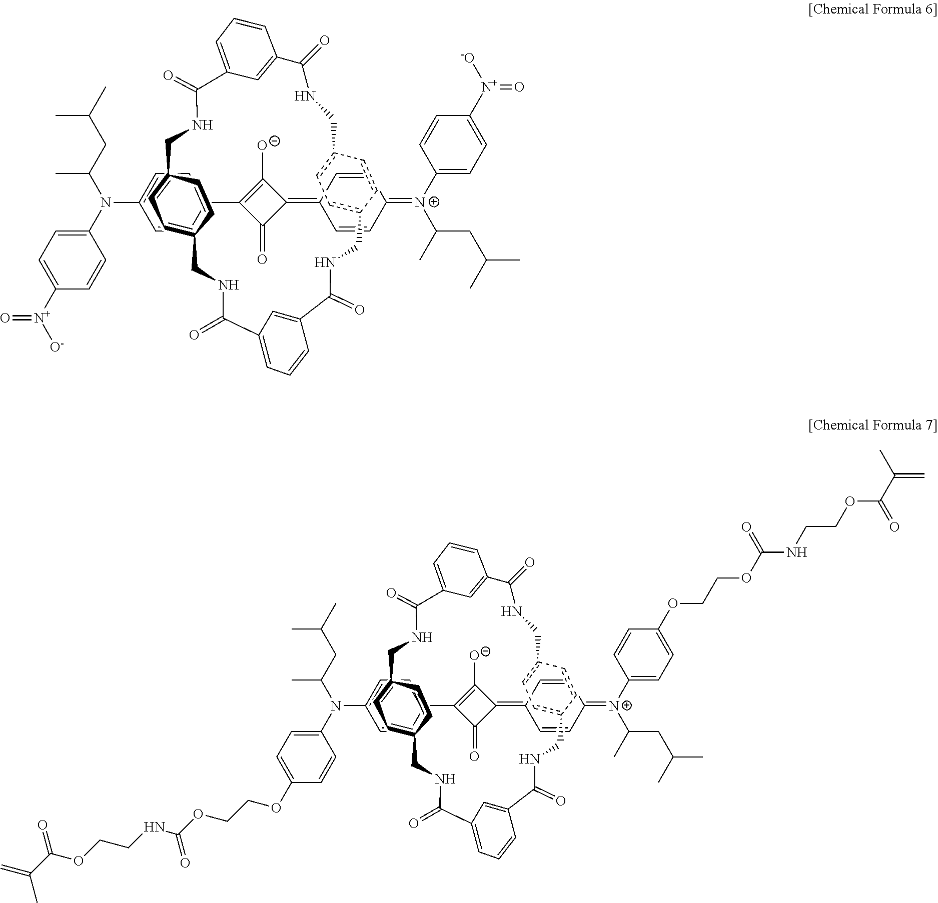

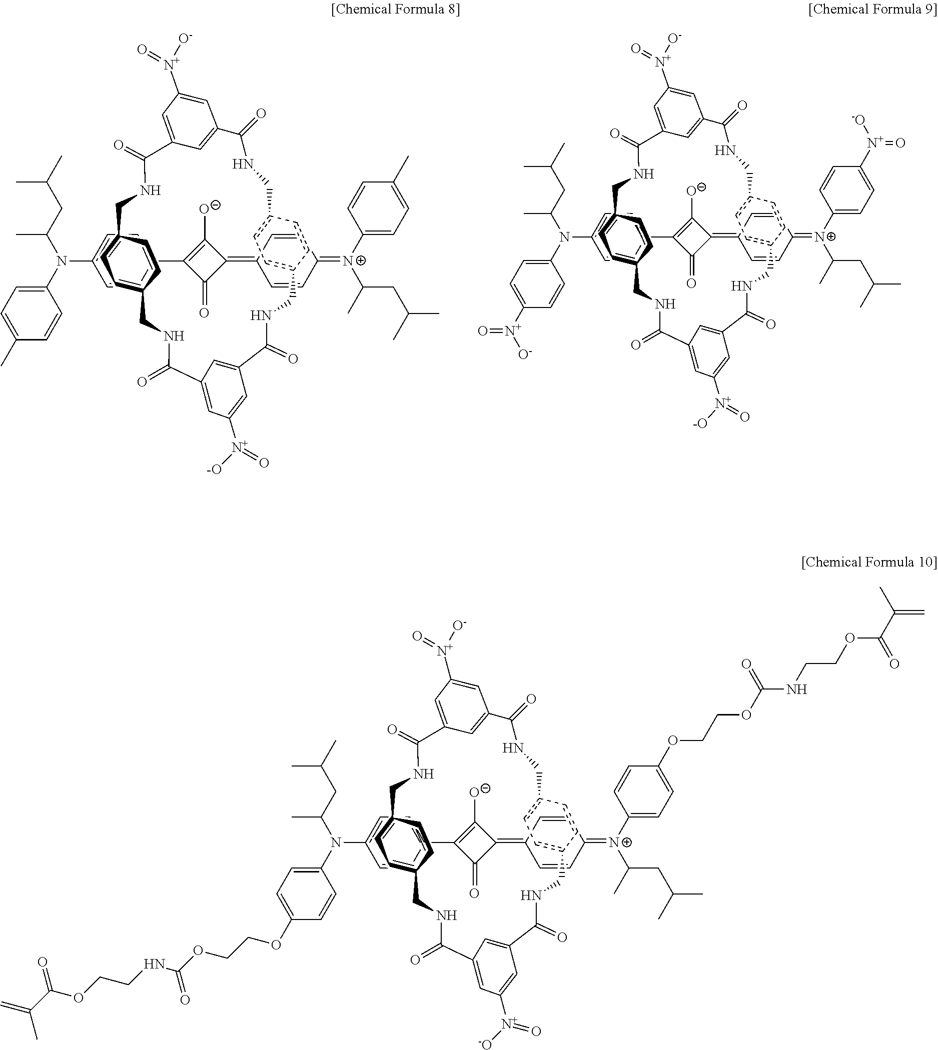

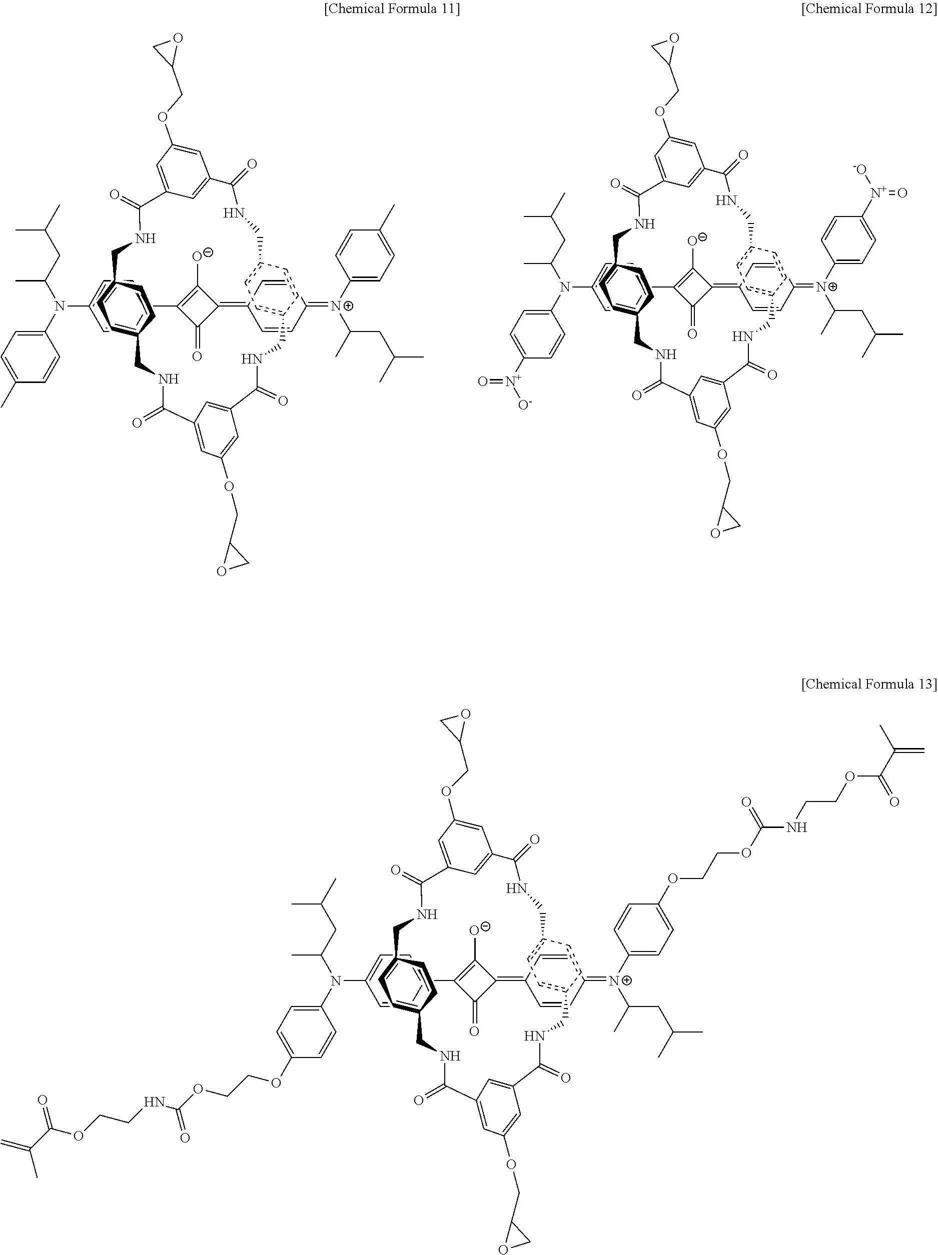

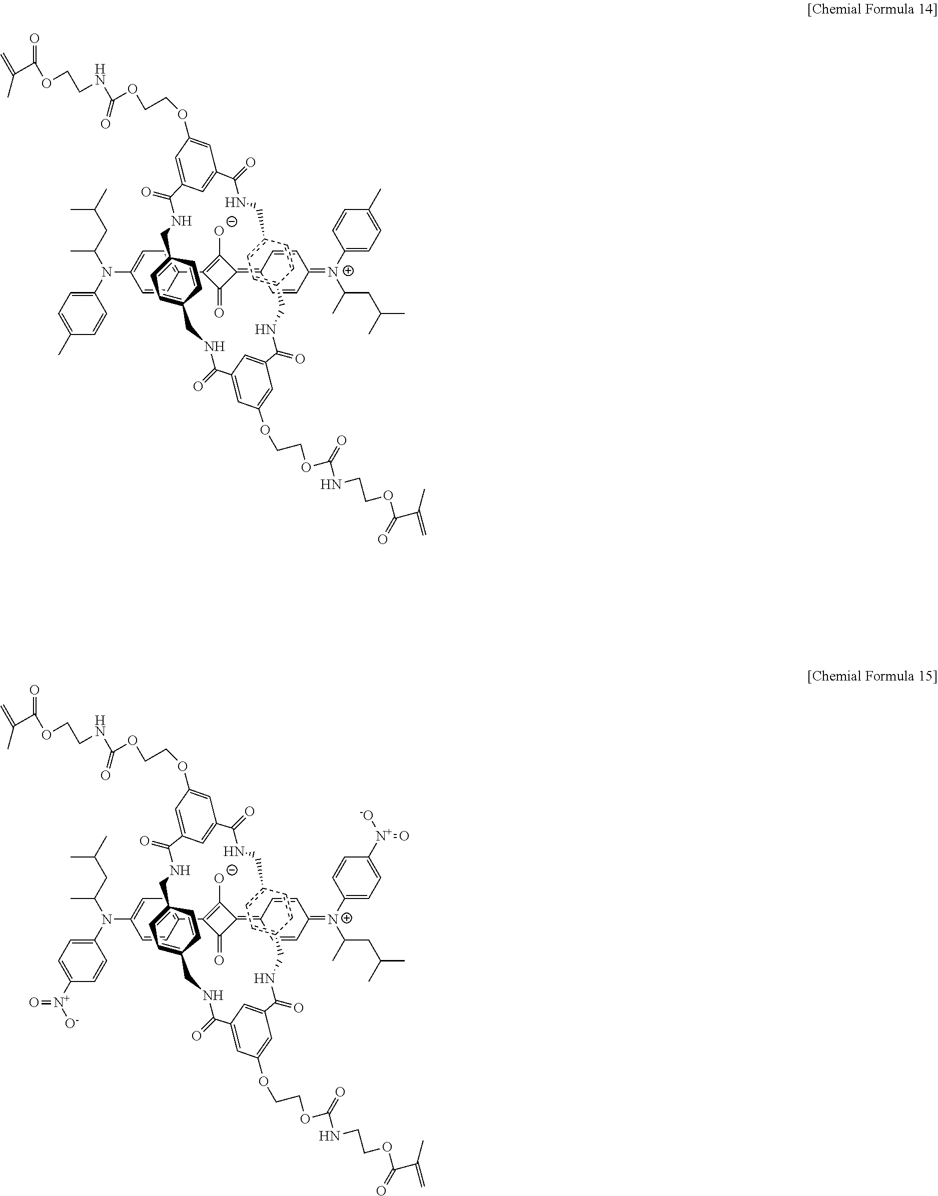

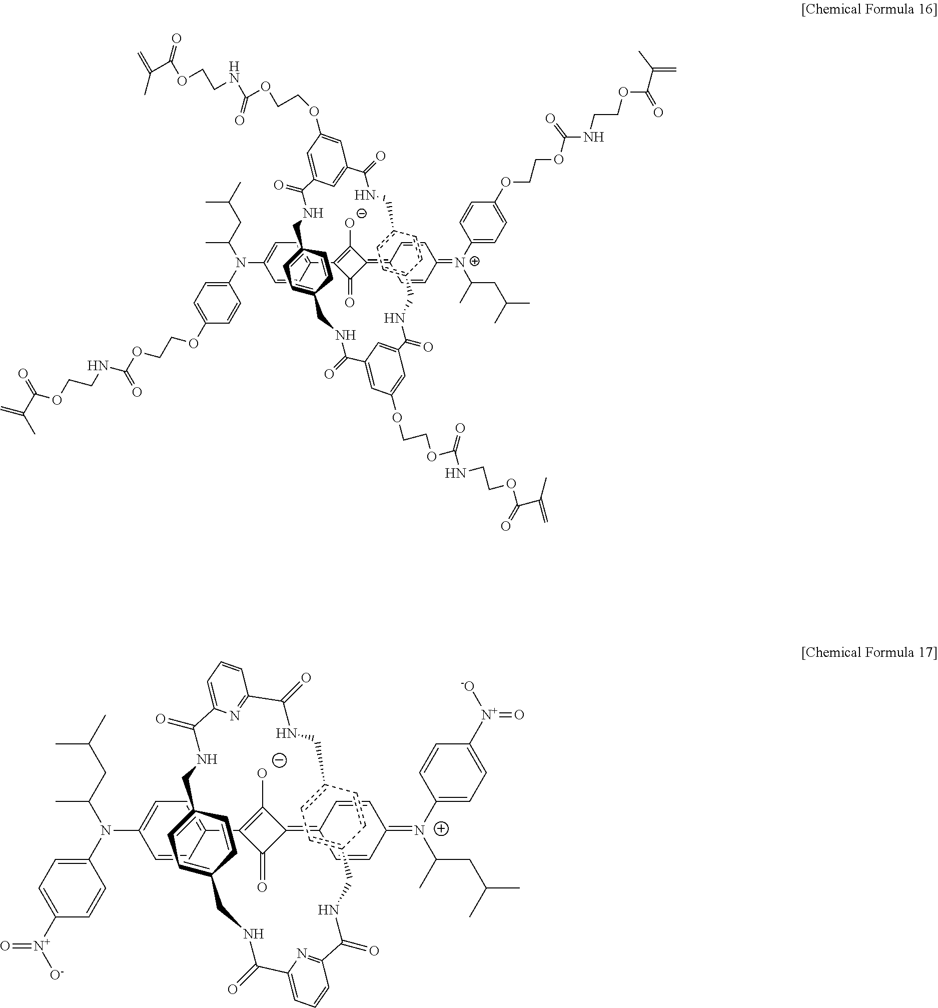

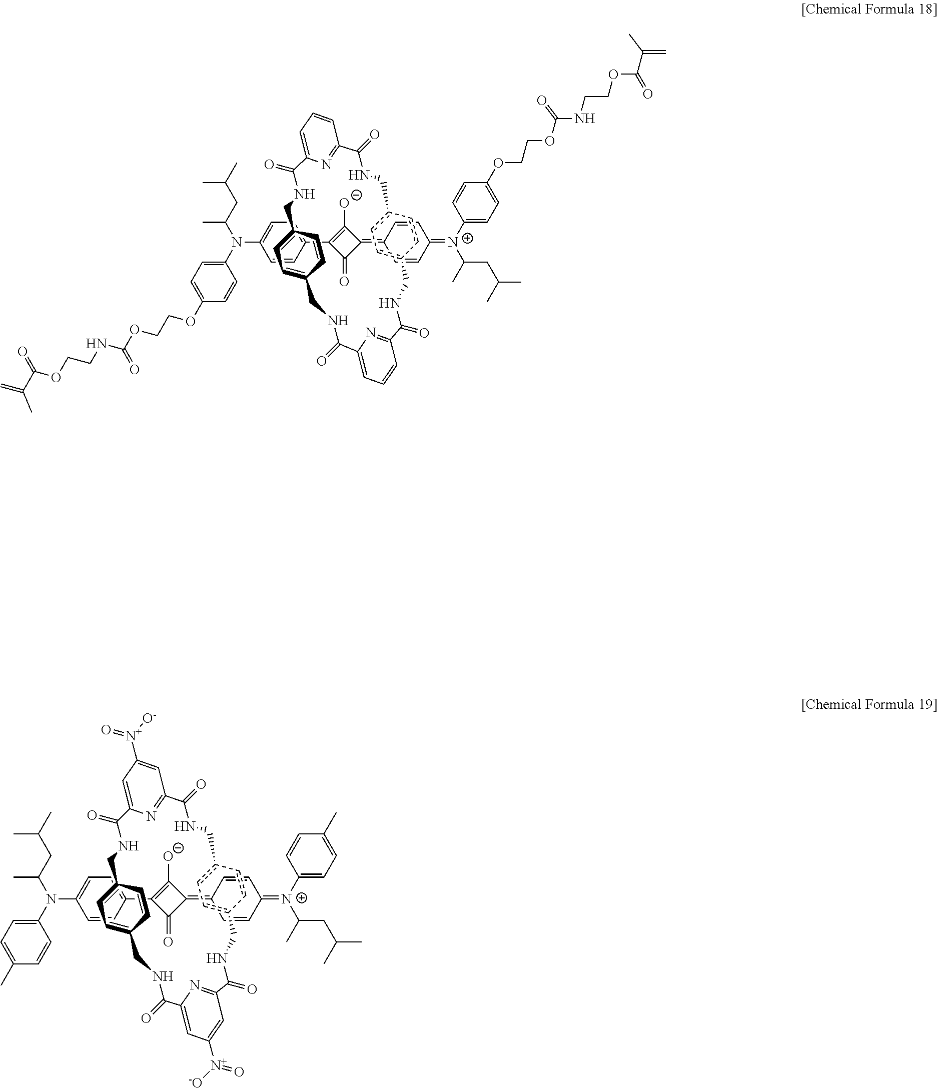

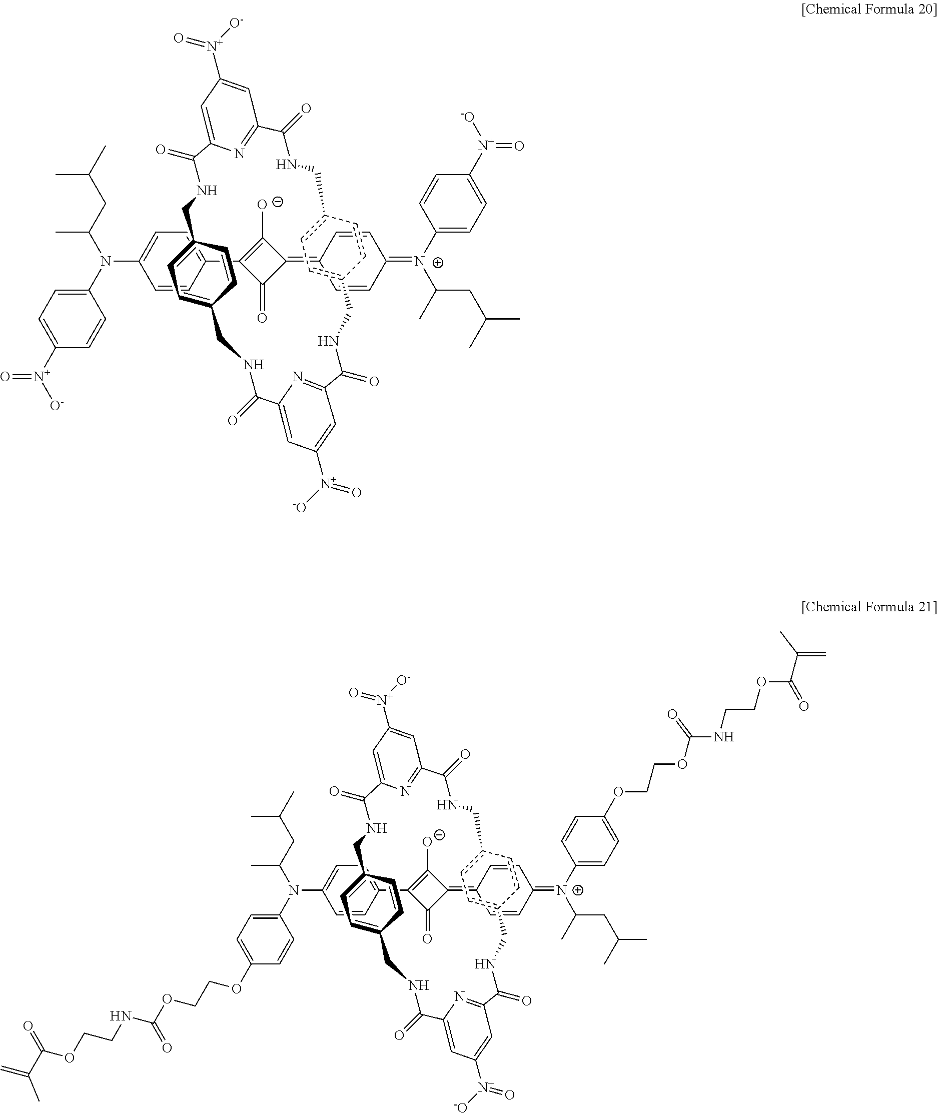

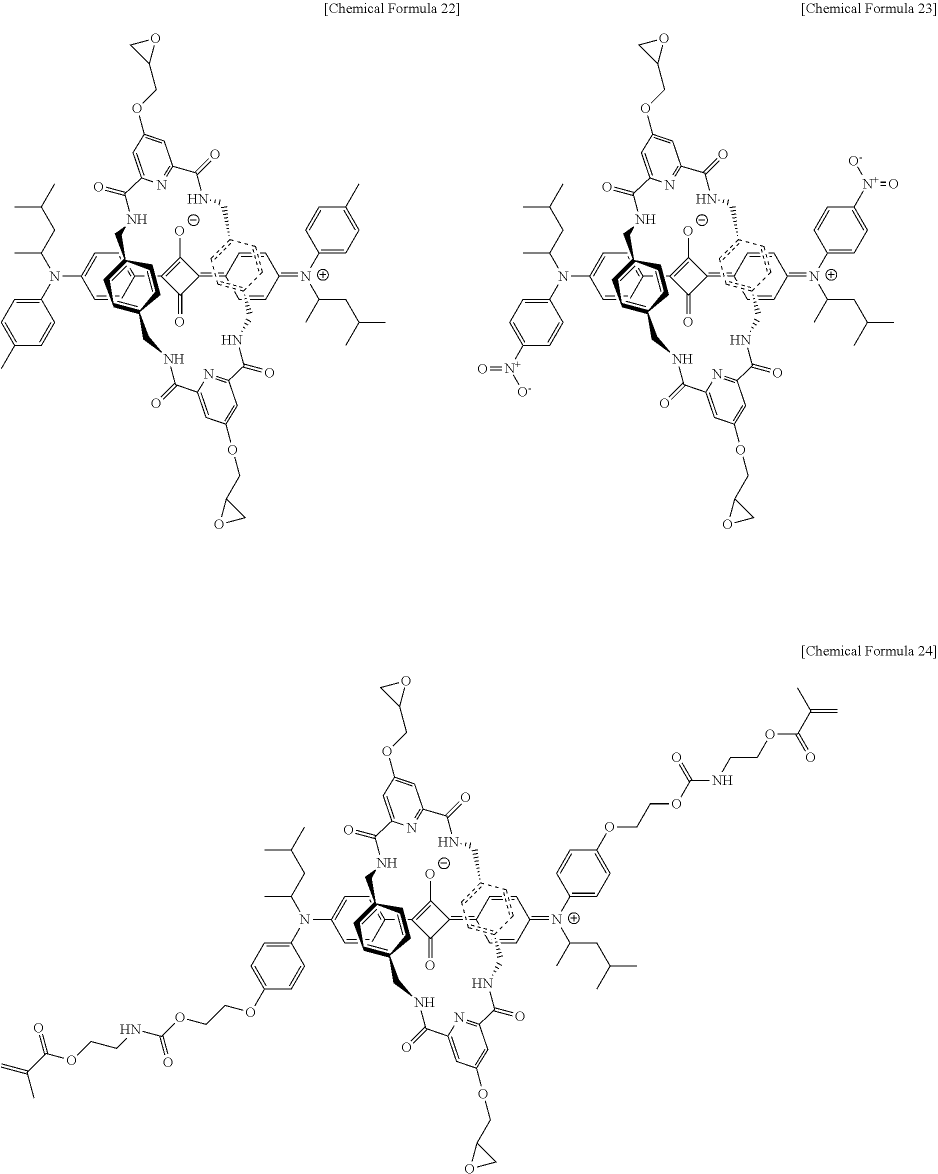

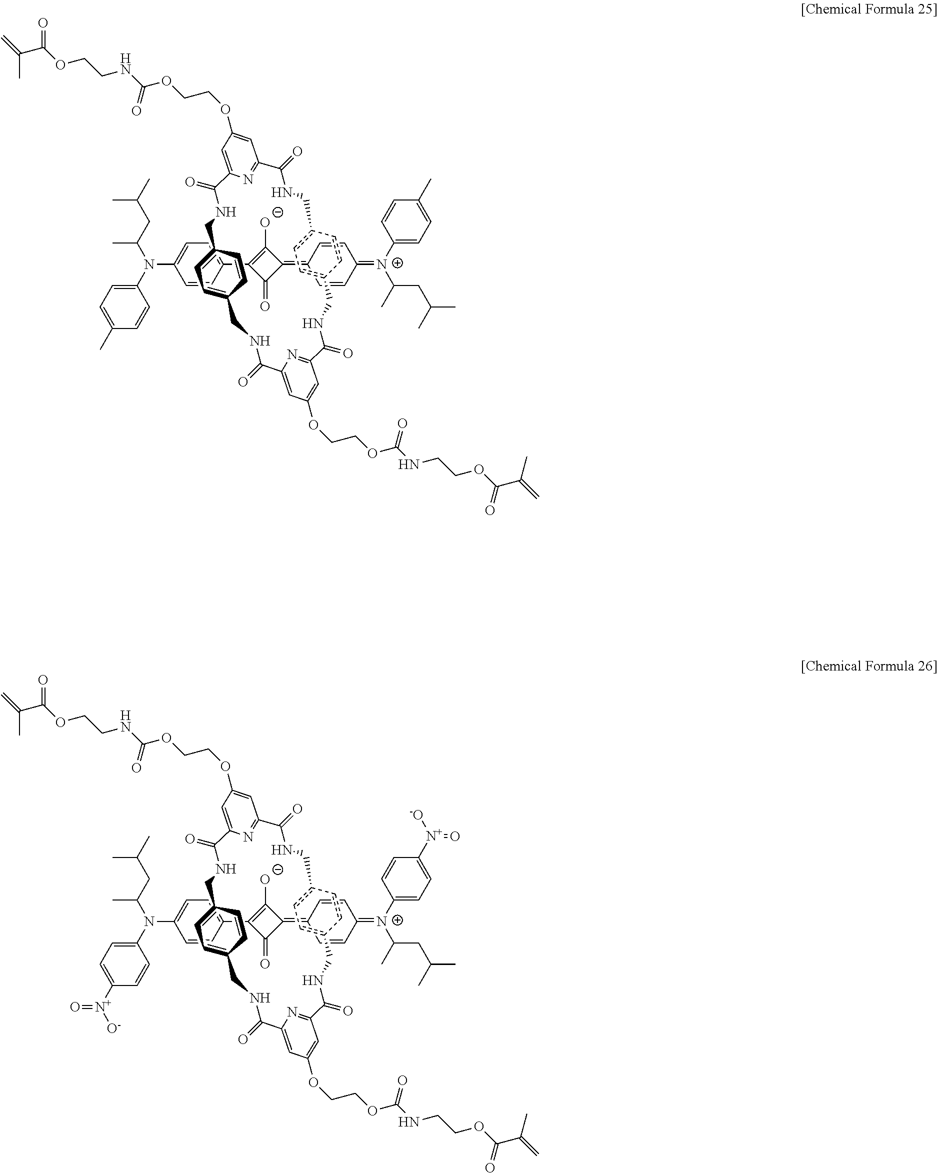

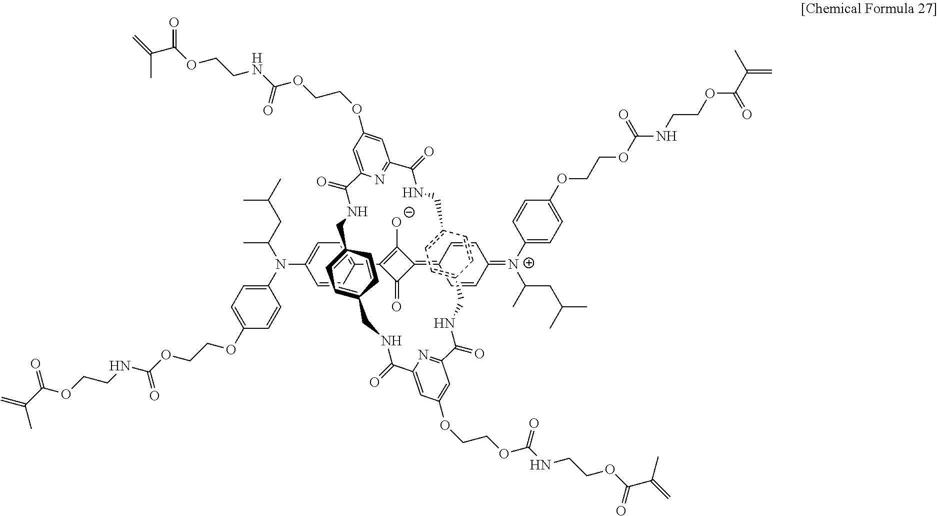

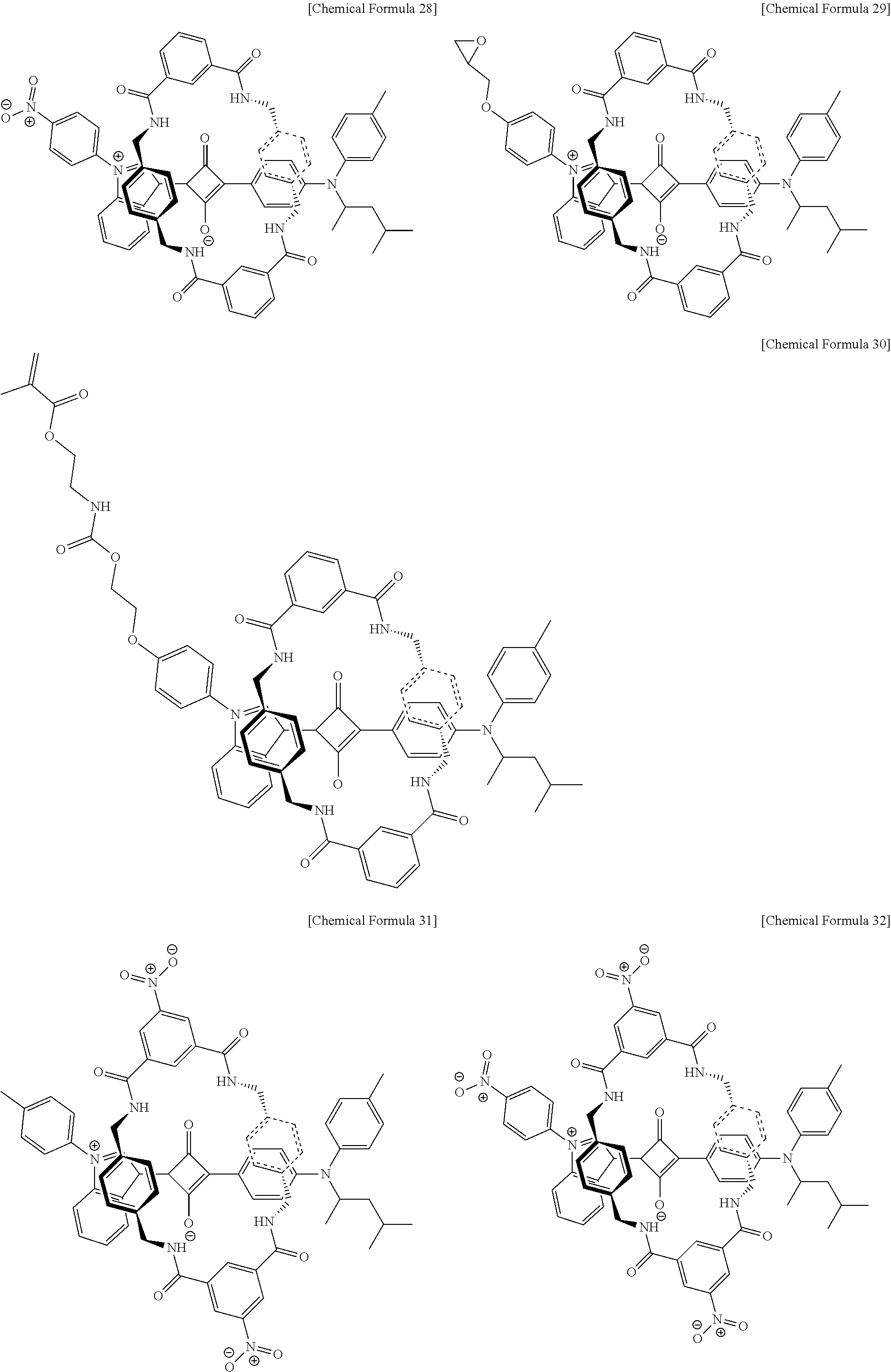

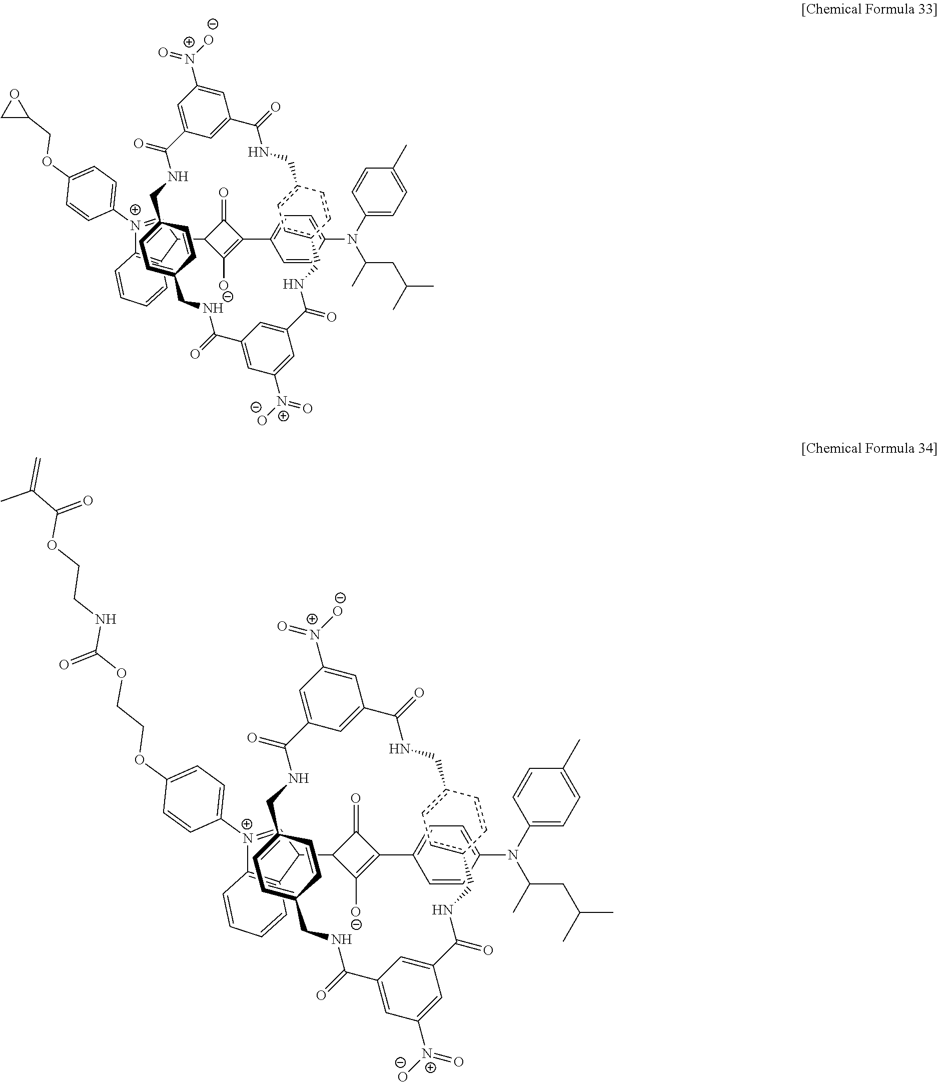

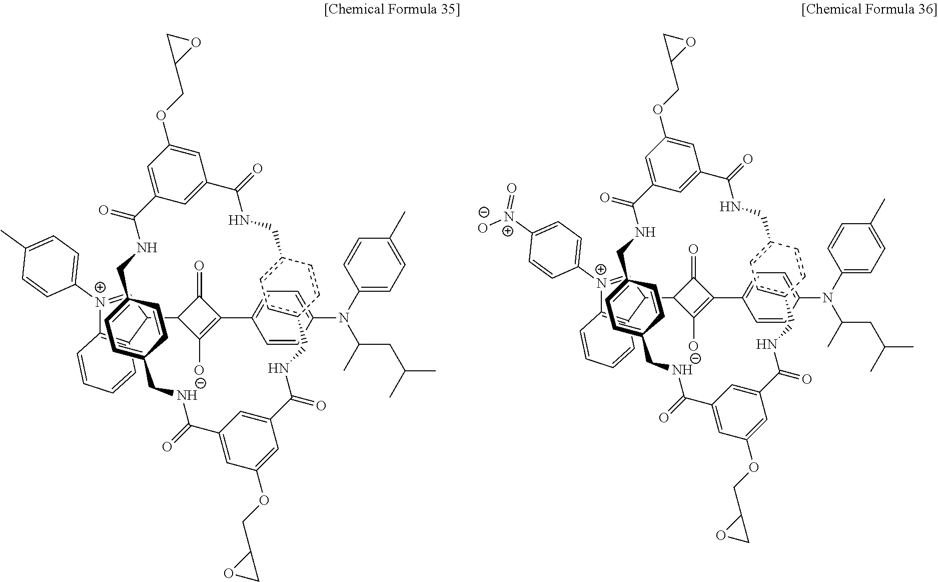

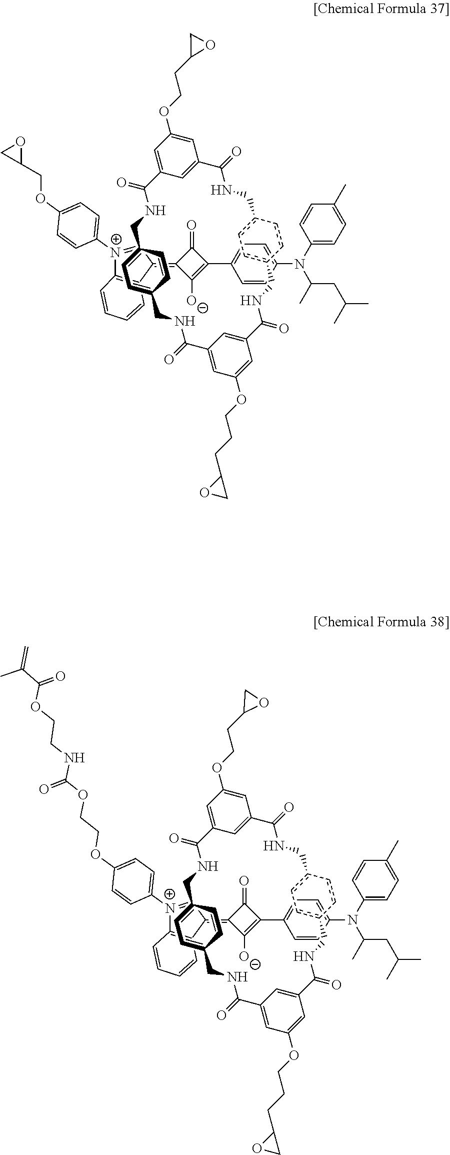

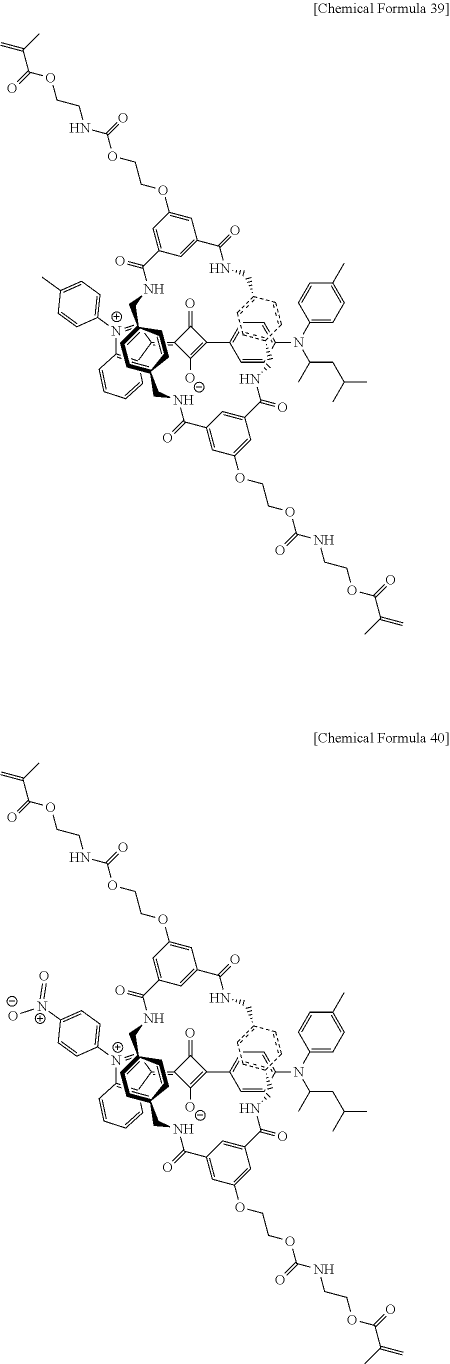

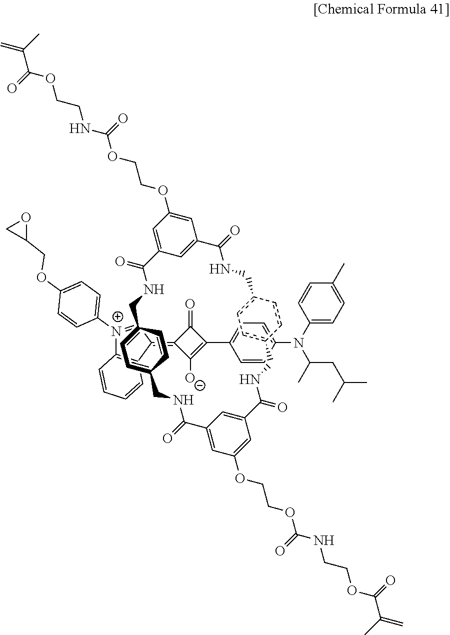

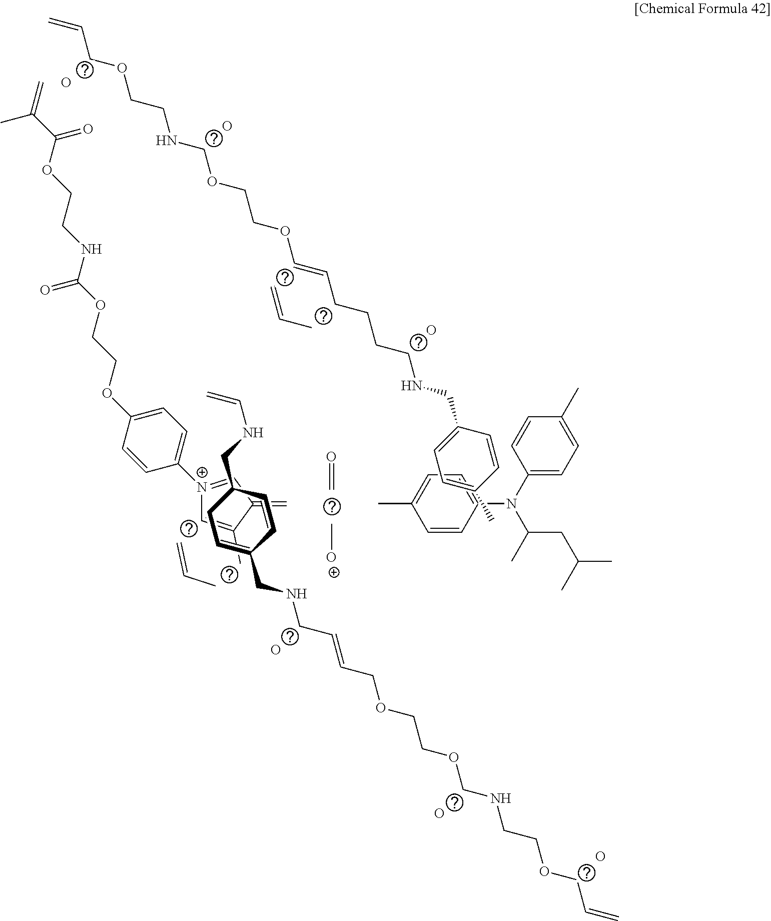

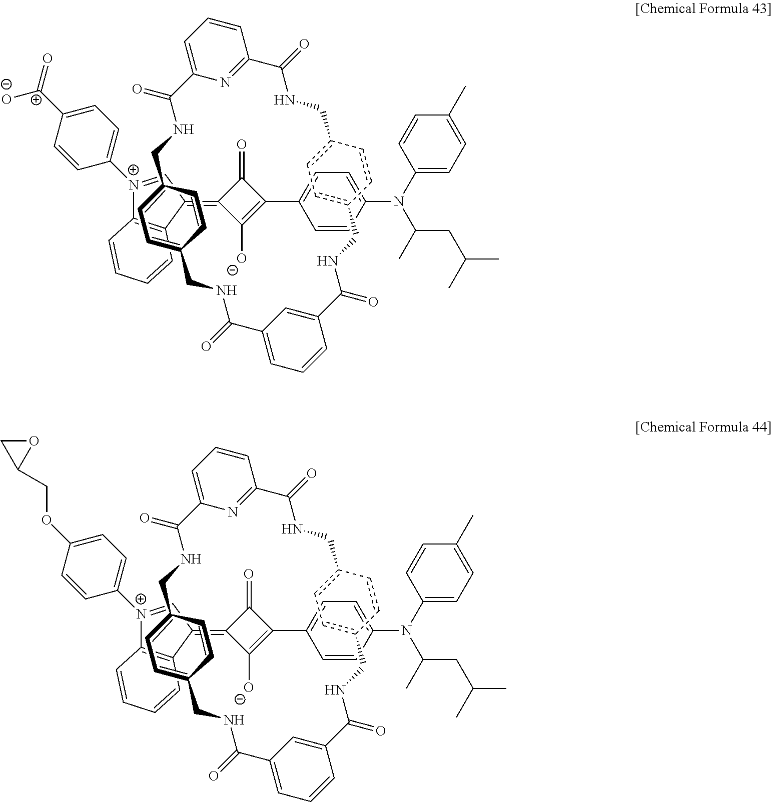

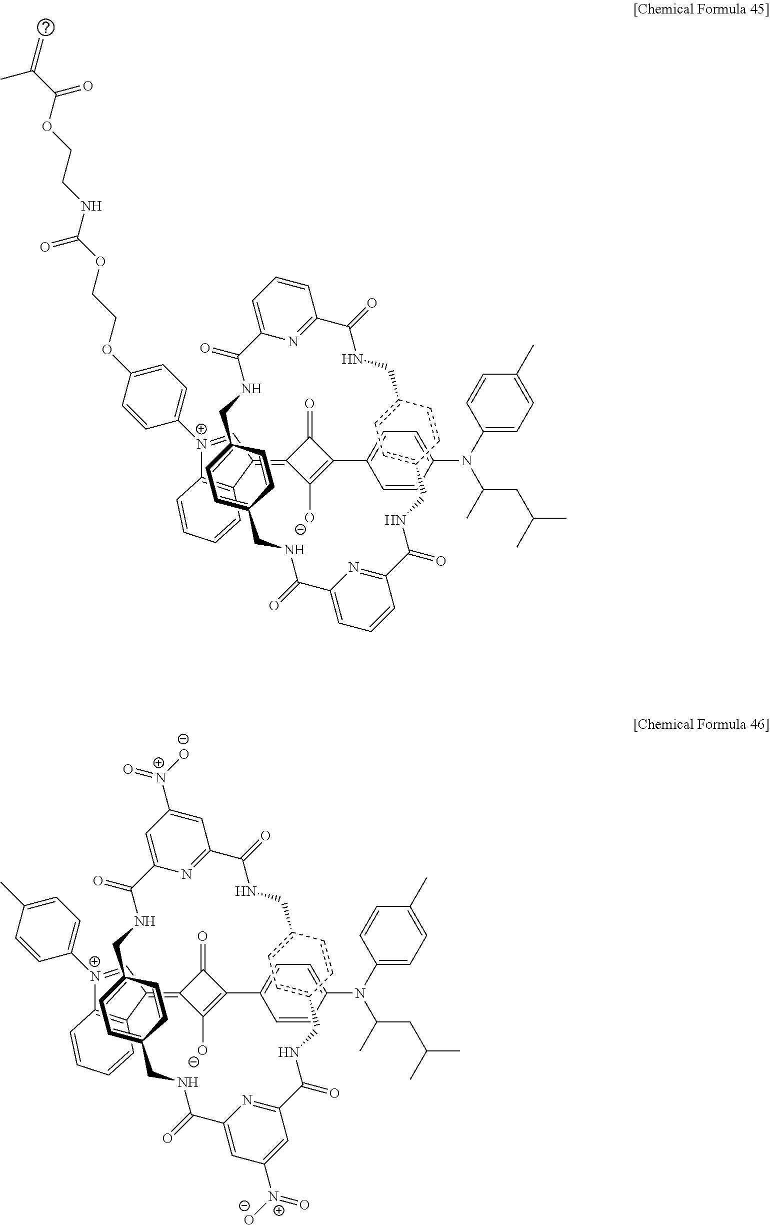

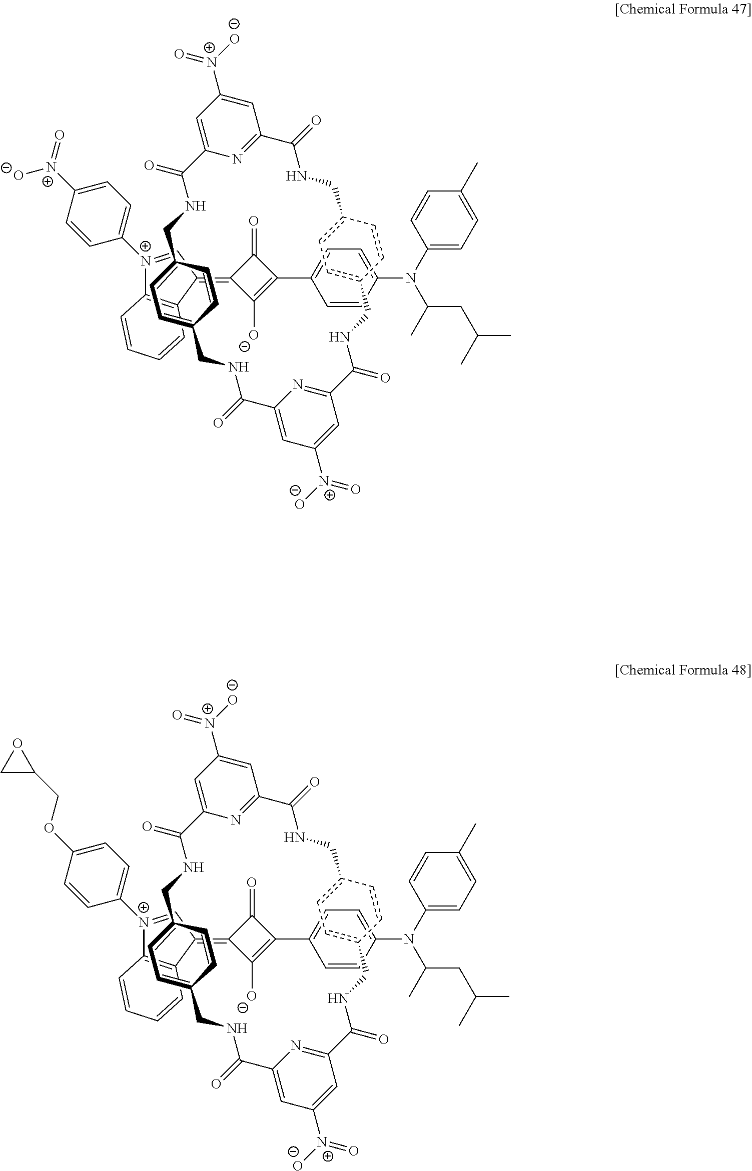

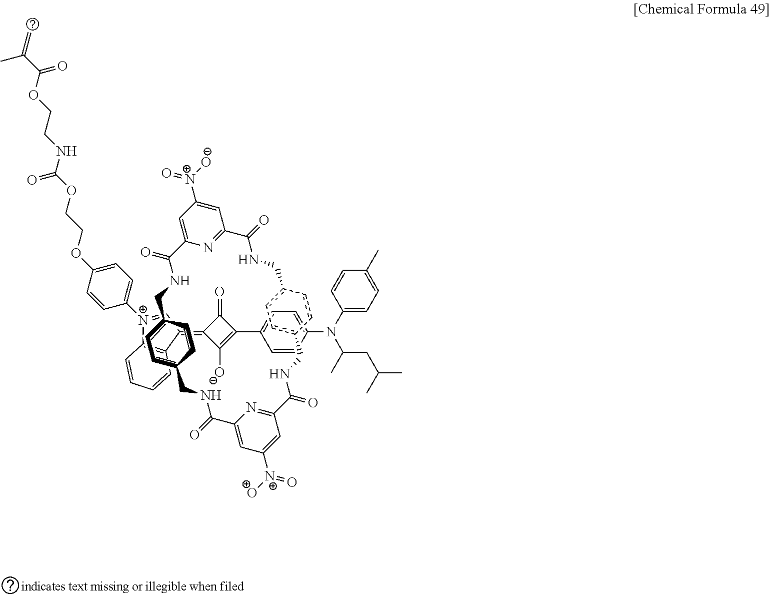

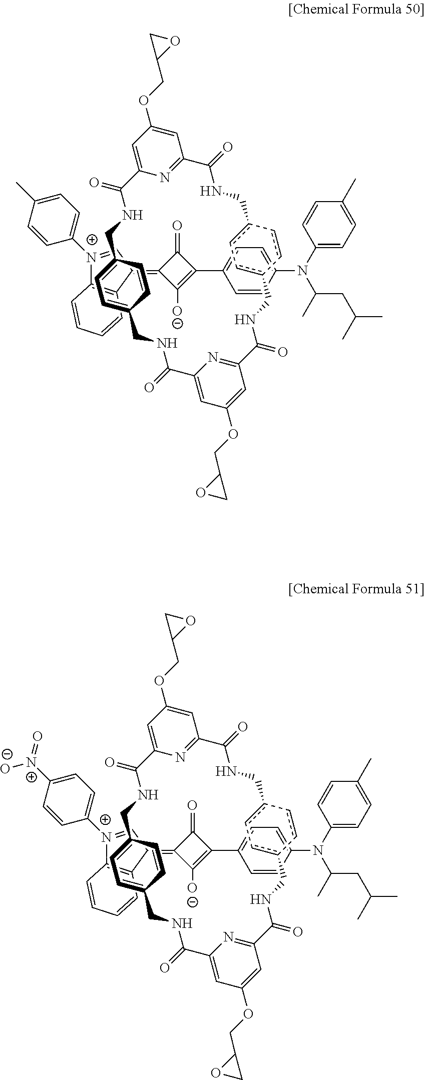

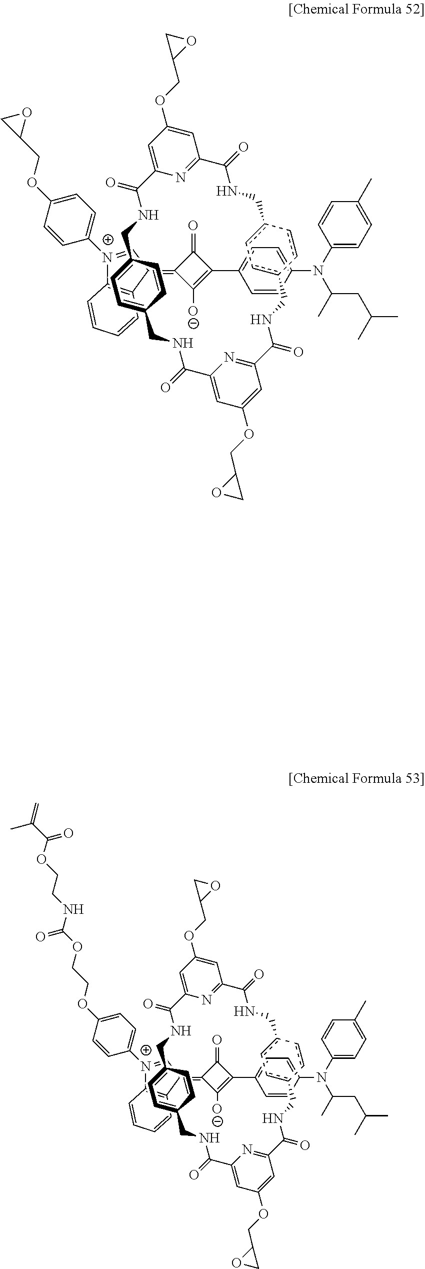

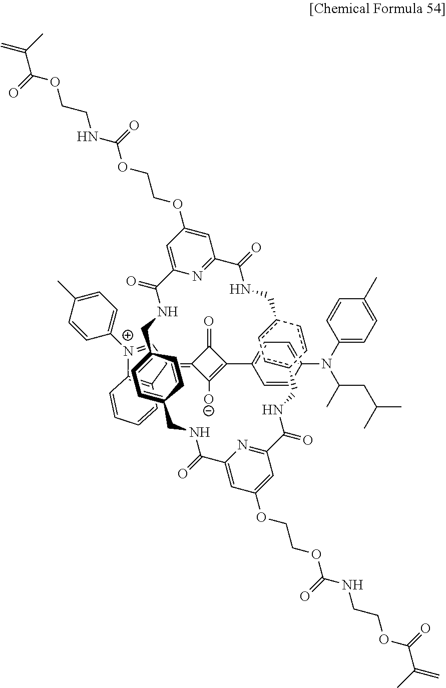

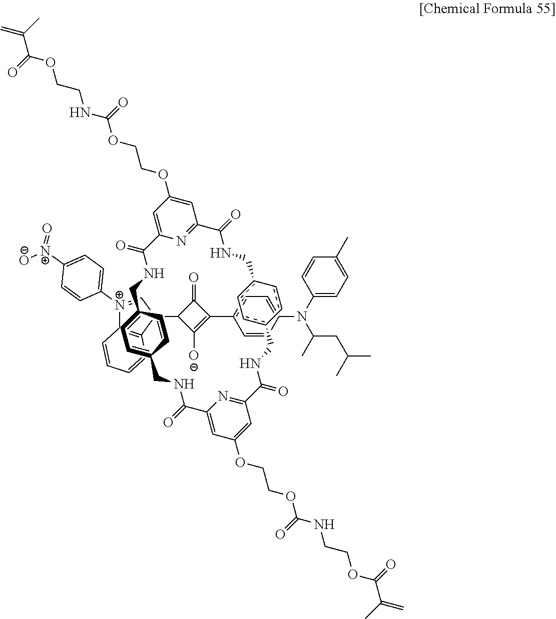

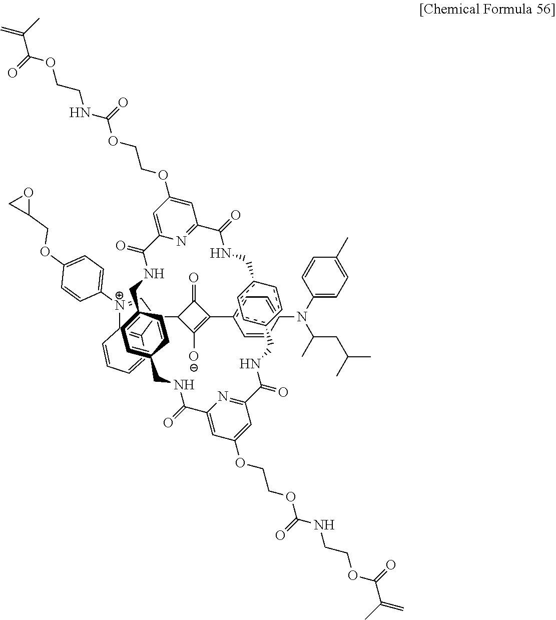

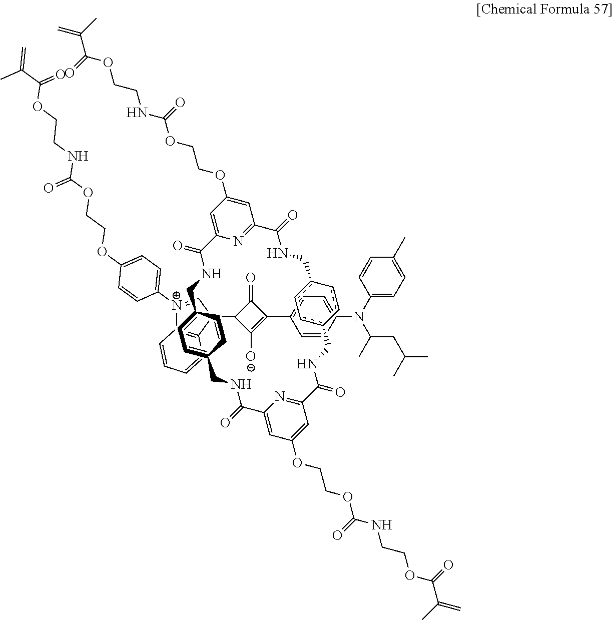

The core-shell dye may include the core and the shell in a mole ratio of 1:1.

Another embodiment provides a photosensitive resin composition including the core-shell dye.

The photosensitive resin composition may further include a binder resin, a photopolymerizable monomer, a photopolymerization initiator, and a solvent.

The photosensitive resin composition may further include malonic acid, 3-amino-1,2-propanediol, a silane-based coupling agent including a vinyl group or a (meth)acryloxy group, a leveling agent, a surfactant, a radical polymerization initiator, or a combination thereof.

Another embodiment provides a photosensitive resin film manufactured using the photosensitive resin composition.

Another embodiment provides a color filter including the photosensitive resin film.

Another embodiment provides a CMOS image sensor including the color filter.

### Advantageous Effects

A color filter having improved luminance and contrast ratio and a CMOS image sensor including the same may be implemented by using the compound or core-shell dye according to an embodiment.

### DESCRIPTION OF THE DRAWINGS

FIG. 1 is a view showing a cage width of a shell represented by Chemical Formula 5-1.

### MODE FOR INVENTION

Hereinafter, embodiments of the present invention are described in detail. However, these embodiments are exemplary, the present invention is not limited thereto and the present invention is defined by the scope of claims.

In the present specification, when a specific definition is not otherwise provided, “substituted” refers to replacement of at least one hydrogen of a compound by a substituent selected from a halogen atom (F, Cl, Br, or I), a hydroxy group, a C1 to C20 alkoxy group, a nitro group, a glycidoxy group, a (meth)acrylate group, a carbamate group, a cyano group, an amine group, an imino group, an azido group, an amidino group, a hydrazino group, a hydrazono group, a carbonyl group, a carbamyl group, a thiol group, ester group, an ether group, a carboxyl group or a salt thereof, a sulfonic acid group or a salt thereof, a phosphoric acid or a salt thereof, a C1 to C20 alkyl group, a C2 to C20 alkenyl group, a C2 to C20 alkynyl group, a C6 to C30 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, and a combination thereof.

In the present specification, when a specific definition is not otherwise provided, “heterocycloalkyl group”, “heterocycloalkenyl group”, “heterocycloalkynyl group” and “heterocycloalkylene group” refer to a cycloalkyl, cycloalkenyl, cycloalkynyl and cycloalkylene cyclic compound including at least one heteroatom of N, O, S, or P.

In the present specification, when a specific definition is not otherwise provided, “combination” refers to mixing or copolymerization.

In the present specification, when a definition is not otherwise provided, in chemical formula, hydrogen is bound at the position when a chemical bond is not drawn where supposed to be given.

In the present specification, when specific definition is not otherwise provided, “(meth)acrylate” refers to “acrylate” and “methacrylate” and “(meth)acrylic acid” refers to “acrylic acid” and “methacrylic acid.”

In the present specification, when specific definition is not otherwise provided, “alkyl group” refers to a C1 to C20 alkyl group, and specifically a C1 to C15 alkyl group, “cycloalkyl group” refers to a C3 to C20 cycloalkyl group, and specifically a C3 to C18 cycloalkyl group, “alkoxy group” refers to a C1 to C20 alkoxy group, and specifically a C1 to C18 alkoxy group, “aryl group” refers to a C6 to C20 aryl group, and specifically a C6 to C18 aryl group, “alkenyl group” refers to a C2 to C20 alkenyl group, and specifically a C2 to C18 alkenyl group, “alkylene group” refers to a C1 to C20 alkylene group, and specifically C1 to C18 alkylene group, and “arylene group” refers to a C6 to C20 arylene group, and specifically a C6 to C16 arylene group.

In the present specification, when specific definition is not otherwise provided, indicates a point where the same or different atom or chemical formula is linked.

An embodiment provides a core-shell dye that includes a core including a compound represented by Chemical Formula 1 or Chemical Formula 2 and a shell surrounding the core.

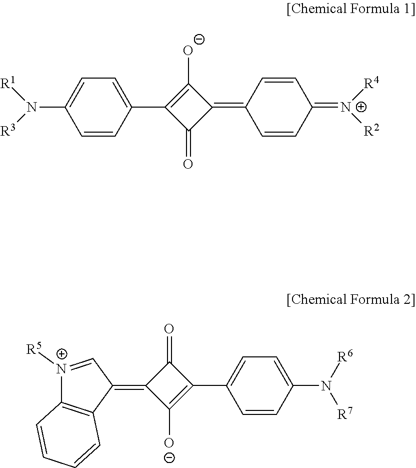

In Chemical Formula 1 or Chemical Formula 2,
R¹ to R⁷ are each independently a substituted or unsubstituted C1 to C20 alkyl group, a substituted or unsubstituted C3 to C20 cycloalkyl group, a substituted or unsubstituted C6 to C20 aryl group, a substituted or unsubstituted C2 to C20 heteroaryl group, or a combination thereof.
R¹ to R⁷ may each independently be a substituted or unsubstituted C1 to C20 alkyl group or may be represented by Chemical Formula 3.

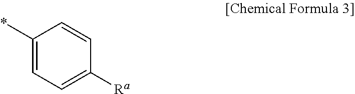

In Chemical Formula 3,
R^{a} is hydrogen, a substituted or unsubstituted C1 to C20 alkyl group, a substituted or unsubstituted C1 to C20 alkoxy group, a nitro group (—NO₂), a glycidoxy group, a (meth)acrylate group, a carbamate group, or a combination thereof.

The core dye including the compound represented by Chemical Formula 1 and Chemical Formula 2 according to an embodiment may include both a core with a symmetric structure represented by Chemical Formula 1 and a core with an asymmetric structure represented by Chemical Formula 2. As the core dye according to an embodiment includes the compound represented by Chemical Formula 1 and Chemical Formula 2, a photosensitive resin composition including the core dye may have excellent heat resistance and chemical resistance characteristics.
R¹ to R⁷ may be the functional group represented by Chemical Formula 3.

For example, in Chemical Formula 1, at least one of R¹ and R³ and at least one of R² and R⁴ may be a functional group represented by Chemical Formula 3.

For example, in Chemical Formula 2, R⁵ may be the functional group represented by Chemical Formula 3 and at least one of R⁶ and R⁷ may be the functional group represented by Chemical Formula 3.

The functional group represented by Chemical Formula 3 has a structure that Rª is substituted at a para carbon position, while hydrogen is all substituted at ortho and meta carbon positions, based on benzene ring carbon connected to a nitrogen atom of the compound represented by Chemical Formula 1 and Chemical Formula 2. As the compound represented by Chemical Formula 3 has the above structure, the core-shell dye including the core represented by Chemical Formula 1 or Chemical Formula 2 including this compound as a substituent exhibits an increased molar extinction coefficient and thus improved light absorption efficiency characteristics but reduced fluorescence quantum efficiency characteristics. Accordingly, the photosensitive resin composition including the core-shell dye may exhibit improved dye coloring strength and chemical resistance characteristics and excellent contrast ratio and luminescence characteristics.

Specifically, as both of the ortho and meta carbons of the functional group represented by Chemical Formula 3 are all substituted with hydrogen, since an intermolecular steric hindrance effect of the compound represented by Chemical Formula 1 or Chemical Formula 2 may be reduced, intermolecular HOMO/LUMO orbitals may be sufficiently overlapped, resultantly increasing the molar extinction coefficient of the core-shell dye. In addition, as the intermolecular steric hindrance effect is reduced, vibration/rotation of the substituent substituted with the nitrogen atom of the compound represented by Chemical Formula 1 or Chemical Formula 2 is increased, which may promote non-radiative internal conversion and thus reduce fluorescence quantum efficiency.

In addition, when the R¹ to R⁷ are the functional group represented by Chemical Formula 3, chemical resistance characteristics of the core-shell dye including the same may be improved.

The core-shell dye may have a molar extinction coefficient of greater than or equal to 3.1×10⁵ M⁻¹·cm⁻¹ and fluorescent quantum efficiency of less than or equal to 5%. Specifically, the core-shell dye with an asymmetric structure may have a molar extinction coefficient which is 60% to 65% of that of the core-shell dye with a symmetric structure and in addition, a maximum absorption wavelength of about 590 nm to about 630 nm and thus an excellent effect of blocking a short wavelength region, compared with the core-shell dye with a symmetric structure (maximum absorption wavelength: about 630 nm to about 670 nm).

The molar extinction coefficient of the core-shell dye is calculated by diluting it in a dilution solvent (e.g., cyclohexanone) at a concentration of 0.001 wt % and measuring a maximum absorption wavelength of a UV-Vis Spectrum of each dye with UV-1800 (SHIMADZU Co., Ltd.) at room temperature.

The molar extinction coefficient of the core-shell dye may be for example, greater than or equal to 3.1×10⁵ M⁻¹·cm⁻¹, for example, greater than or equal to 3.2×10⁵ M⁻¹·cm⁻¹, for example, greater than or equal to 3.3×10⁵ M⁻¹·cm⁻¹, for example, greater than or equal to 3.4×10⁵ M⁻¹·cm⁻¹, for example, greater than or equal to 3.5×10⁵ M⁻¹·cm⁻¹, for example, greater than or equal to 3.6×10⁵ M⁻¹·cm⁻¹, for example, greater than or equal to 3.7×10⁵ M⁻¹·cm⁻¹, for example, greater than or equal to 3.8×10⁵ M⁻¹·cm⁻¹, for example, greater than or equal to 3.9×10⁵ M⁻¹·cm⁻¹, or for example, greater than or equal to 4.0×10⁵ M⁻¹·cm⁻¹ but is not limited thereto. When the core-shell dye has a molar extinction coefficient within the ranges, the core-shell dye may have excellent coloring strength.

The fluorescent quantum efficiency of the core-shell dye is measured as follows. 4 mg to 7 mg of the core-shell dye according to a molecular weight is diluted in 3 mL to 6 mL of a cyclohexanone solution to prepare 2.5×10⁻⁷ mol/L of a dye solution to have UV intensity (abs) of less than 0.1 au. Subsequently, the diluted solution is measured with respect to fluorescence quantum efficiency by using Quantaurus-QY C11347 (HAMAMATSU Photonics K.K.) equipment at room temperature, wherein the Quantaurus-QY C11347 equipment uses a 150 W Xenon lamp as a light source, and a maximum absorption wavelength of each sample is set as an excitation wavelength (a full width at half maximum (FWHM) of 10 nm or less).

The fluorescent quantum efficiency of the core-shell dye, which is measured under the aforementioned measurement conditions, may be for example, less than or equal to 5%, for example, less than or equal to 4.5%, for example, less than or equal to 4%, for example, less than or equal to 3.5%, for example, less than or equal to 3%, or for example, less than or equal to 2.5% but is not limited thereto.

As the core-shell dye has a molar extinction coefficient and fluorescent quantum efficiency within the above ranges, dye coloring strength, chemical resistance, a contrast ratio, and luminescence characteristics of the photosensitive resin composition including the core-shell dye may be improved.

The compound represented by Chemical Formula 1 or Chemical Formula 2 is illustrated to have one type of resonance structure for convenience in this specification, but the compound represented by Chemical Formula 1 or Chemical Formula 2 may have all possible resonance structures in addition to the aforementioned resonance structure.

The compound represented by Chemical Formula 1 may be represented by any one of Chemical Formula 1-1 to Chemical Formula 1-3, and the compound represented by Chemical Formula 2 may be represented by any one of Chemical Formula 2-1 to Chemical Formula 2-4.

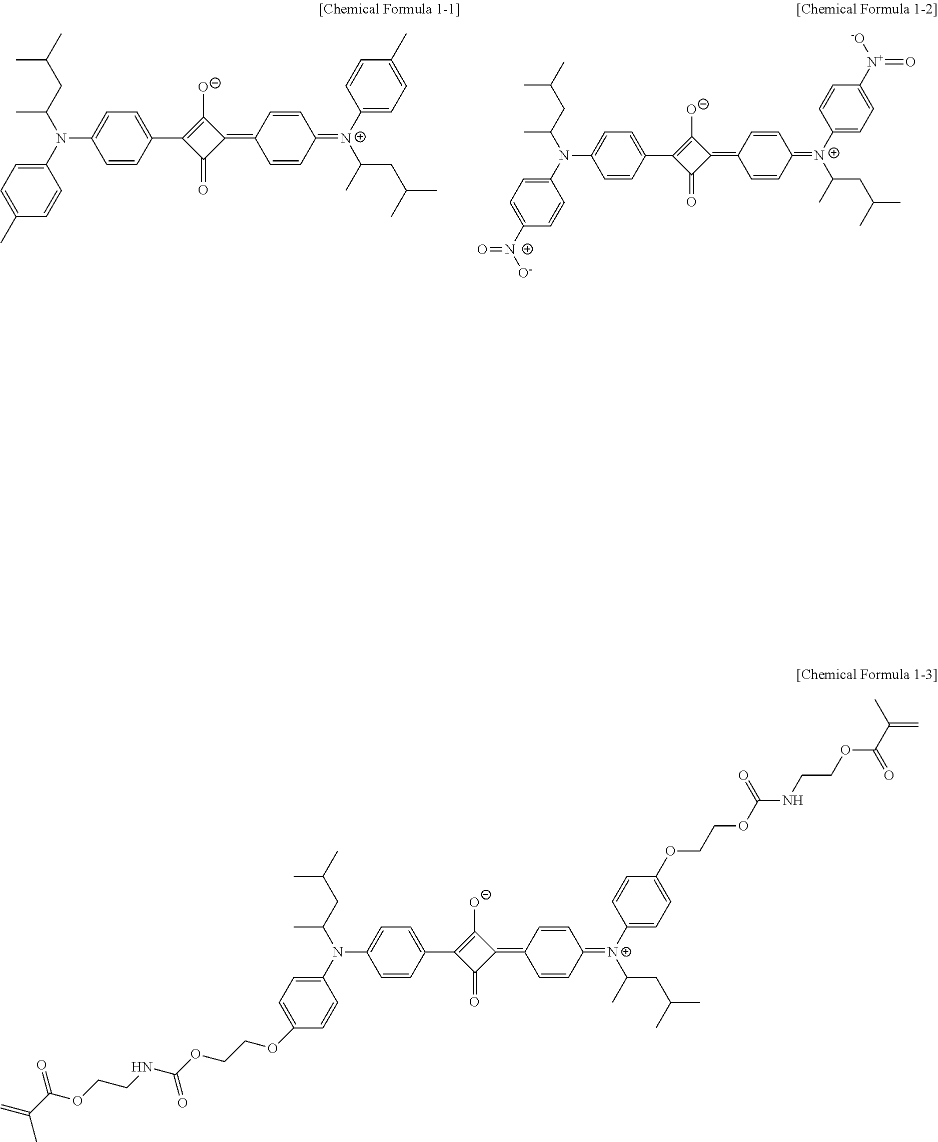

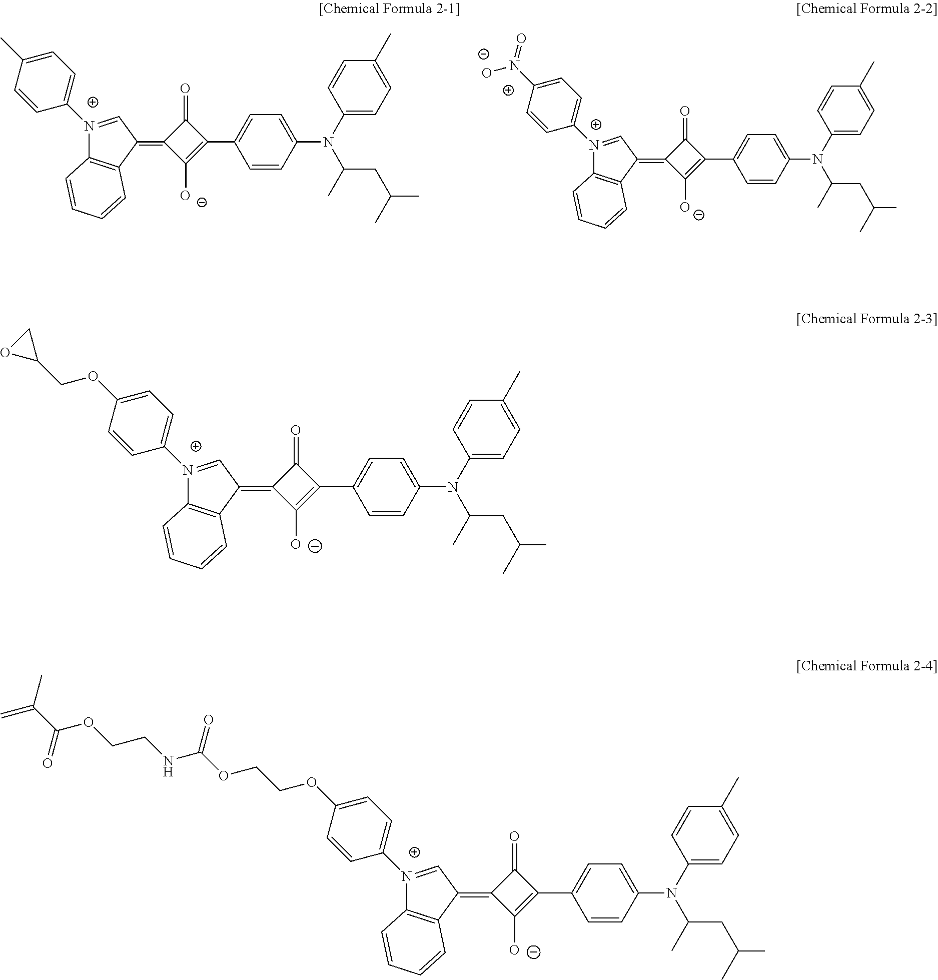

The shell may be represented by Chemical Formula 4 or Chemical Formula 5.

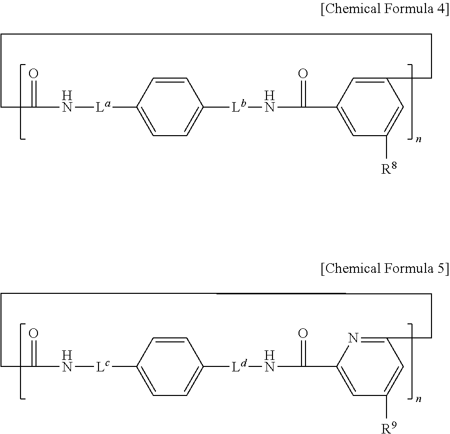

In Chemical Formula 4 or Chemical Formula 5,
R⁸ and R⁹ are each independently hydrogen, a substituted or unsubstituted C1 to C20 alkyl group, a substituted or unsubstituted C1 to C20 alkoxy group, a nitro group (—NO₂), a glycidoxy group, a (meth)acrylate group, a carbamate group, or a combination thereof, L^{a} to L^{d} are each independently a single bond, or a substituted or unsubstituted C1 to C10 alkylene group, and n is an integer from 1 to 4. L^{a} to L^{d} may each independently be a substituted or unsubstituted C1 to C10 alkylene group.

In an embodiment, the shell corresponding to a macrocyclic compound forms a structure of surrounding the compound represented by Chemical Formula 1 or Chemical Formula 2, that is, a structure of having the compound represented by Chemical Formula 1 or Chemical Formula 2 inside the macro-ring and thus may improve durability of the core-shell dye and thereby realize a color filter with high luminance and a high contrast ratio.

On the other hand, the shell represented by Chemical Formula 4 or 5 has a R⁸ or R⁹ group as a substituent in the ring, wherein the R⁸ and R⁹ may be each independently hydrogen, a substituted or unsubstituted C1 to C20 alkyl group, a substituted or unsubstituted C1 to C20 alkoxy group, a nitro group (—NO₂), a glycidoxy group, a (meth)acrylate group, a carbamate group, or a combination thereof. As the shell has R⁸ or R⁹ group as a substituent, durability characteristics of the photosensitive resin composition including the core-shell dye may be improved.

The shell may be represented by Chemical Formula 4-1 or Chemical Formula 5-1.

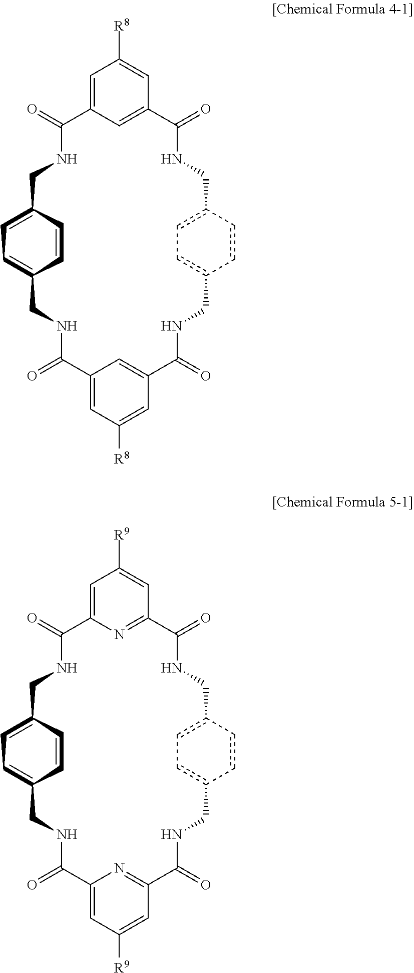

In Chemical Formula 4-1 or Chemical Formula 5-1, R⁸ and R⁹ are defined as described above.

The shell may be represented by, for example, any one of Chemical Formula 4-a to Chemical Formula 4-d and Chemical Formula 5-a to Chemical Formula 5-d.

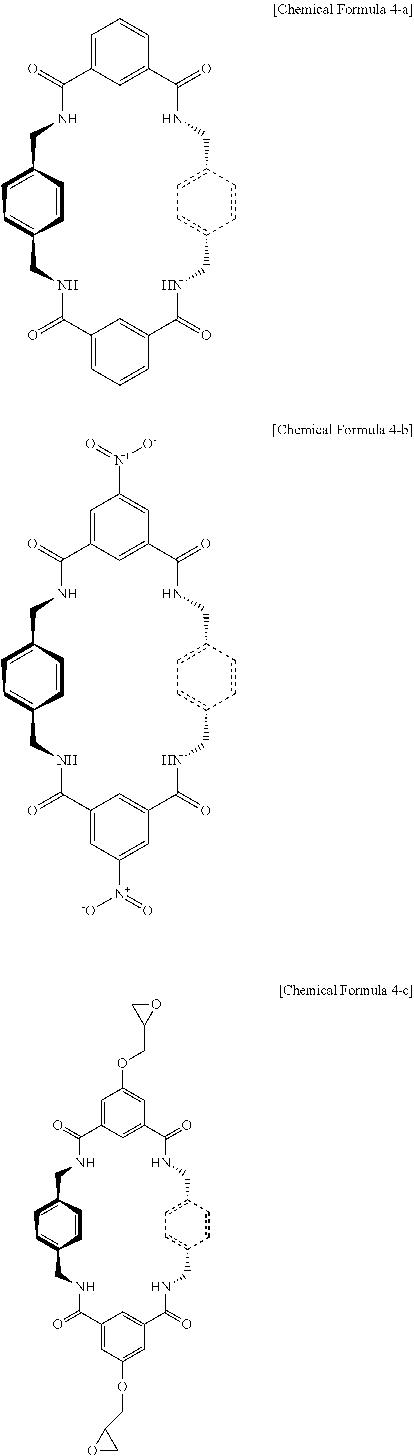

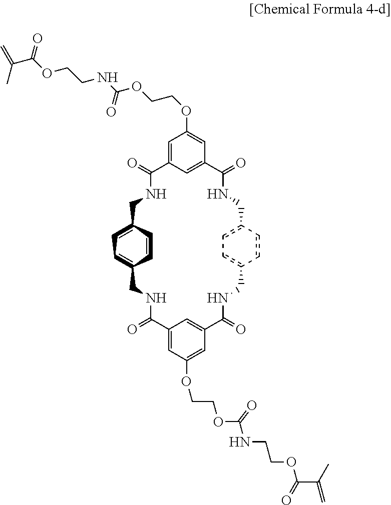

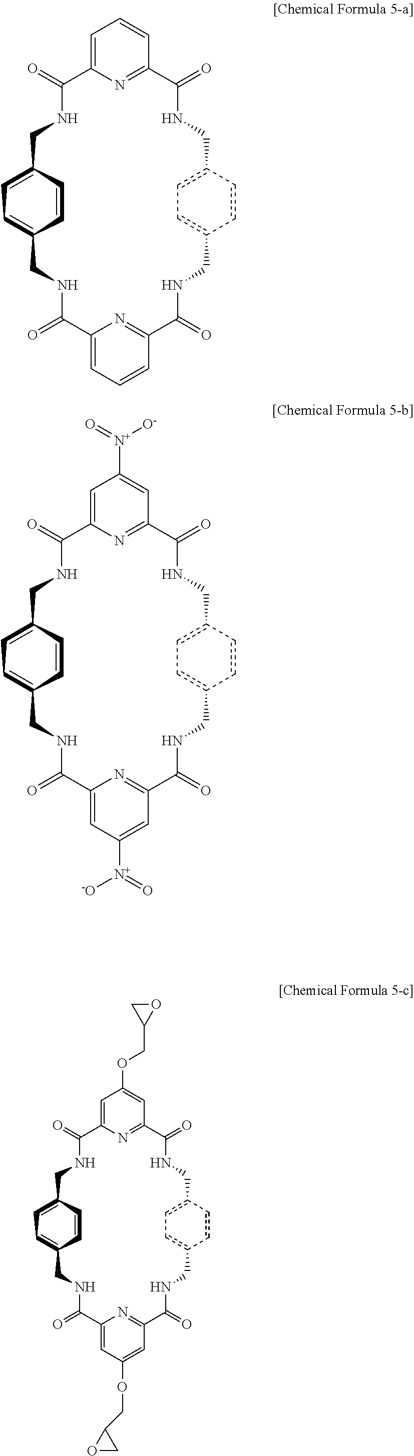

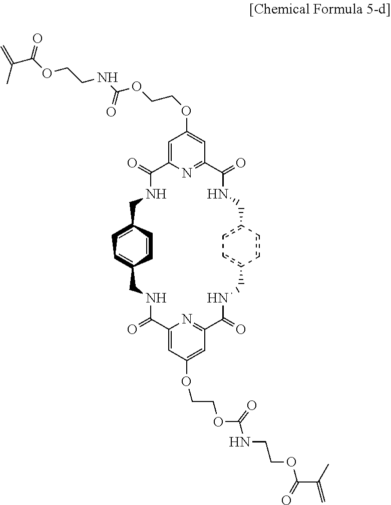

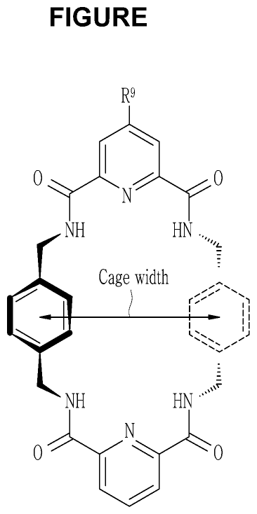

The shell may have a cage width of 6.5 Å to 7.5 Å, a volume of 10 Å to 16 Å, and a length of 1 nm to 3 nm. In this specification, the cage width refers to a distance inside the shell, for example, a distance between two different phenylene groups linked with methylene groups at both sides in the shell represented by Chemical Formula 4-1 or 5-1 (refer to FIG. 1). When the shell has a cage width within the ranges, the core-shell dye with the structure of surrounding the core including the compound represented by Chemical Formula 1 or Chemical Formula 2 may be obtained, and accordingly, when the core-shell dye is added to a photosensitive resin composition, a color filter having excellent durability and high luminance may be realized.

The compound represented by Chemical Formula 1 or Chemical Formula 2 included in the core or constituting the core may have a length of 1 nm to 3 nm, for example 1.5 nm to 2 nm. When the compound represented by Chemical Formula 1 has a length within the ranges, the core-shell dye having the structure of the core and the shell surrounding the core structure may be easily formed. In other words, as the compound represented by Chemical Formula 1 has a length within the ranges, the shell of the macrocyclic compound may have a structure of surrounding the compound represented by Chemical Formula 1. When another compound not having a length within the ranges is used, since for the shell may hardly form the structure of surrounding the compound of the core, durability of a dye may not be improved.

The compound represented by Chemical Formula 1 or Chemical Formula 2 included in the core or constituting the core may have a maximum absorption peak at a wavelength of 590 nm to 670 nm. The core-shell dye using the compound represented by Chemical Formula 1 or Chemical Formula 2 having the spectral characteristics as a core may be used, for example, as a green dye, obtaining a photosensitive resin composition for a color filter having high luminance and excellent durability.

The core-shell dye may include the core including the compound represented by Chemical Formula 1 or Chemical Formula 2 and the shell in a mole ratio of 1:1. When the core and the shell are present in this mole ratio, a coating layer (shell) surrounding the core including the compound represented by Chemical Formula 1 or Chemical Formula 2 may be well formed.

For example, the core-shell dye may be represented as one compound represented by one of Chemical Formula 6 to Chemical Formula 57, but is not limited thereto.

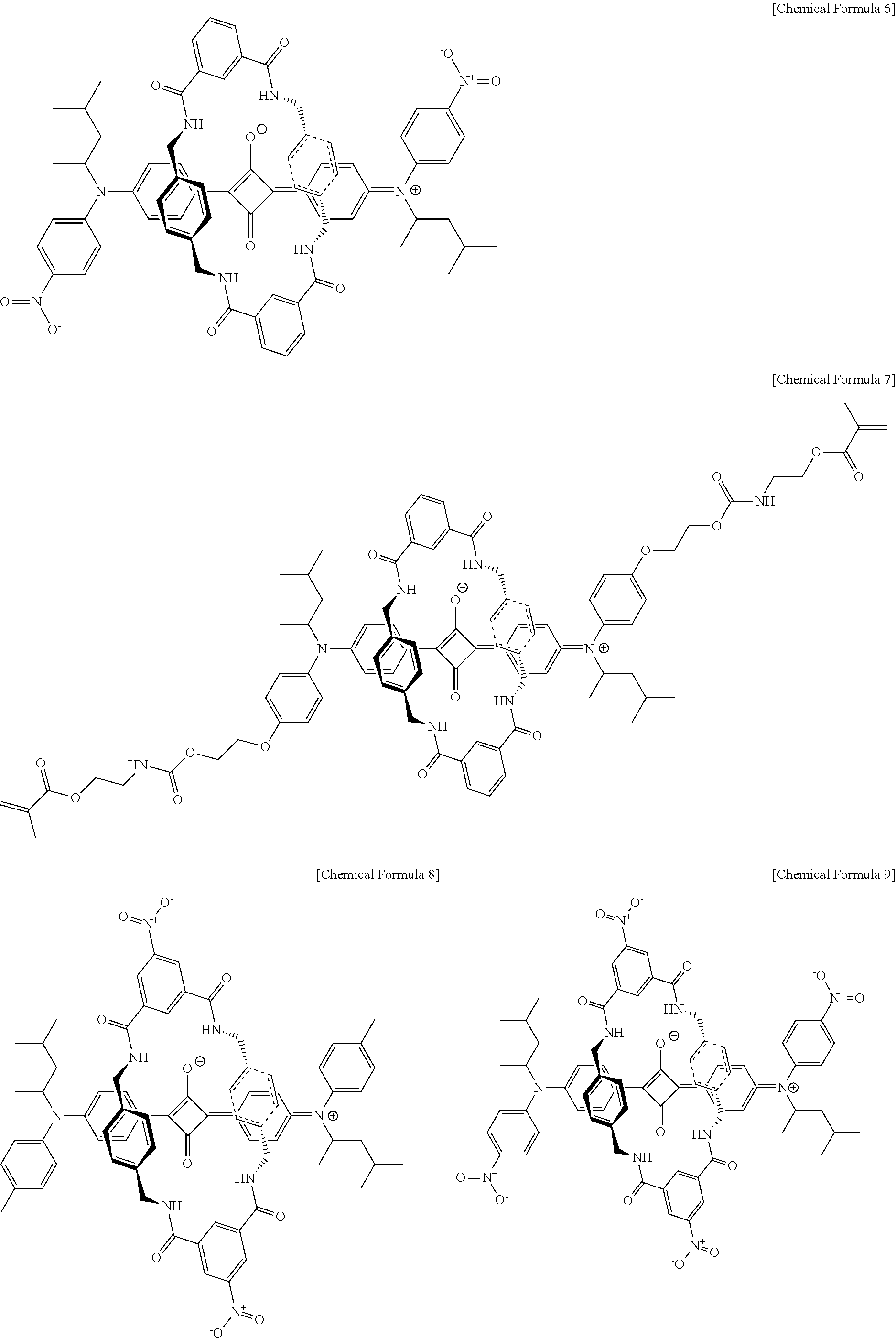

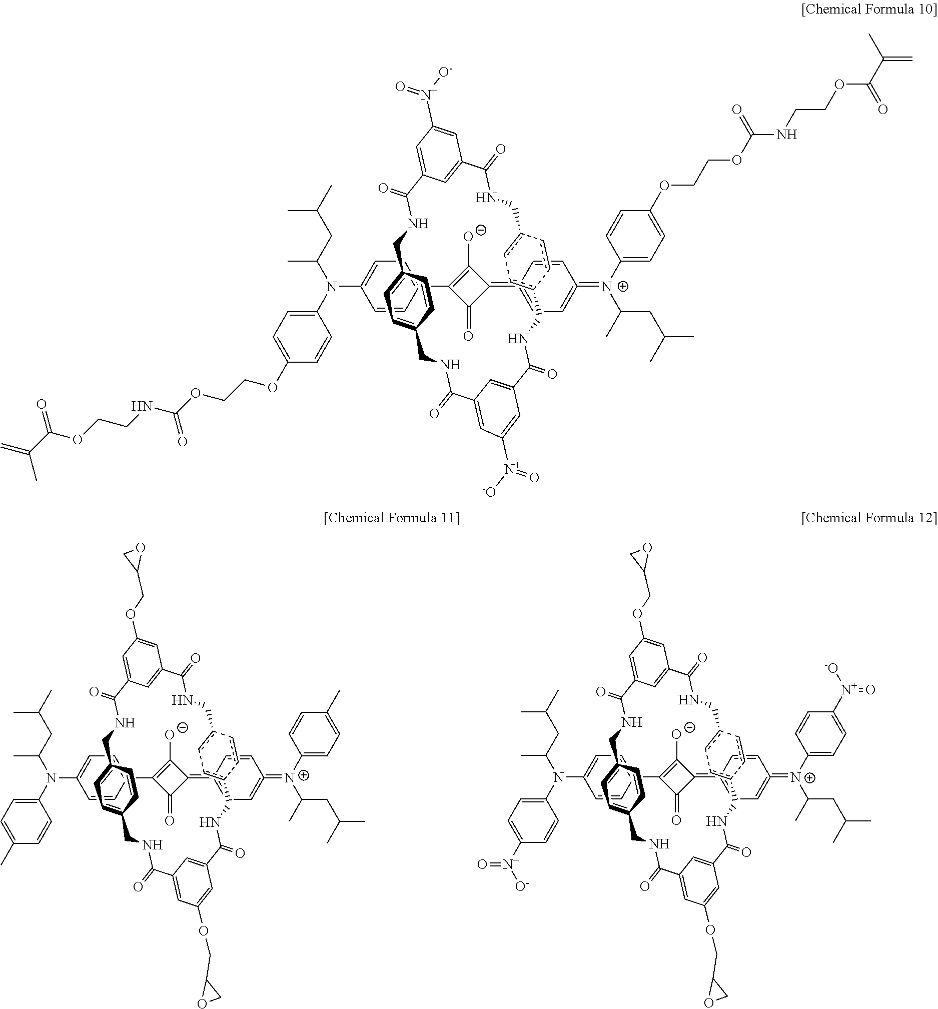

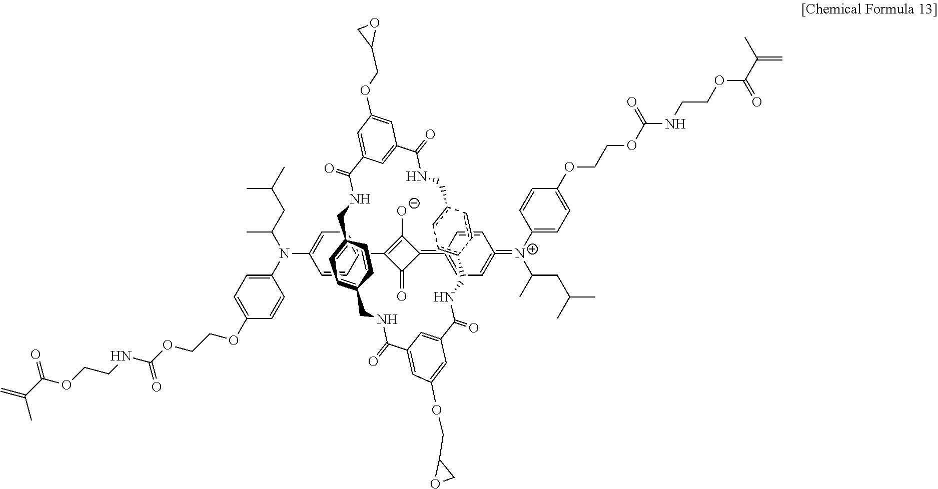

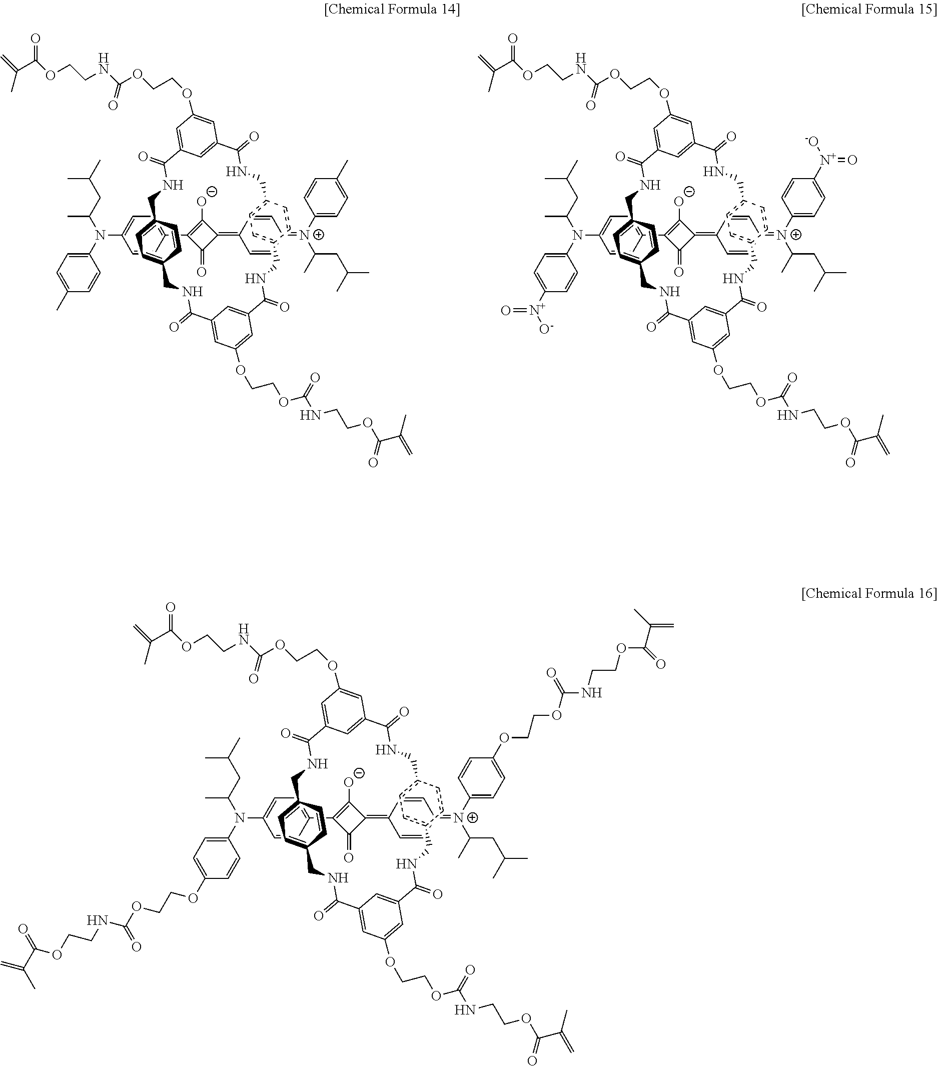

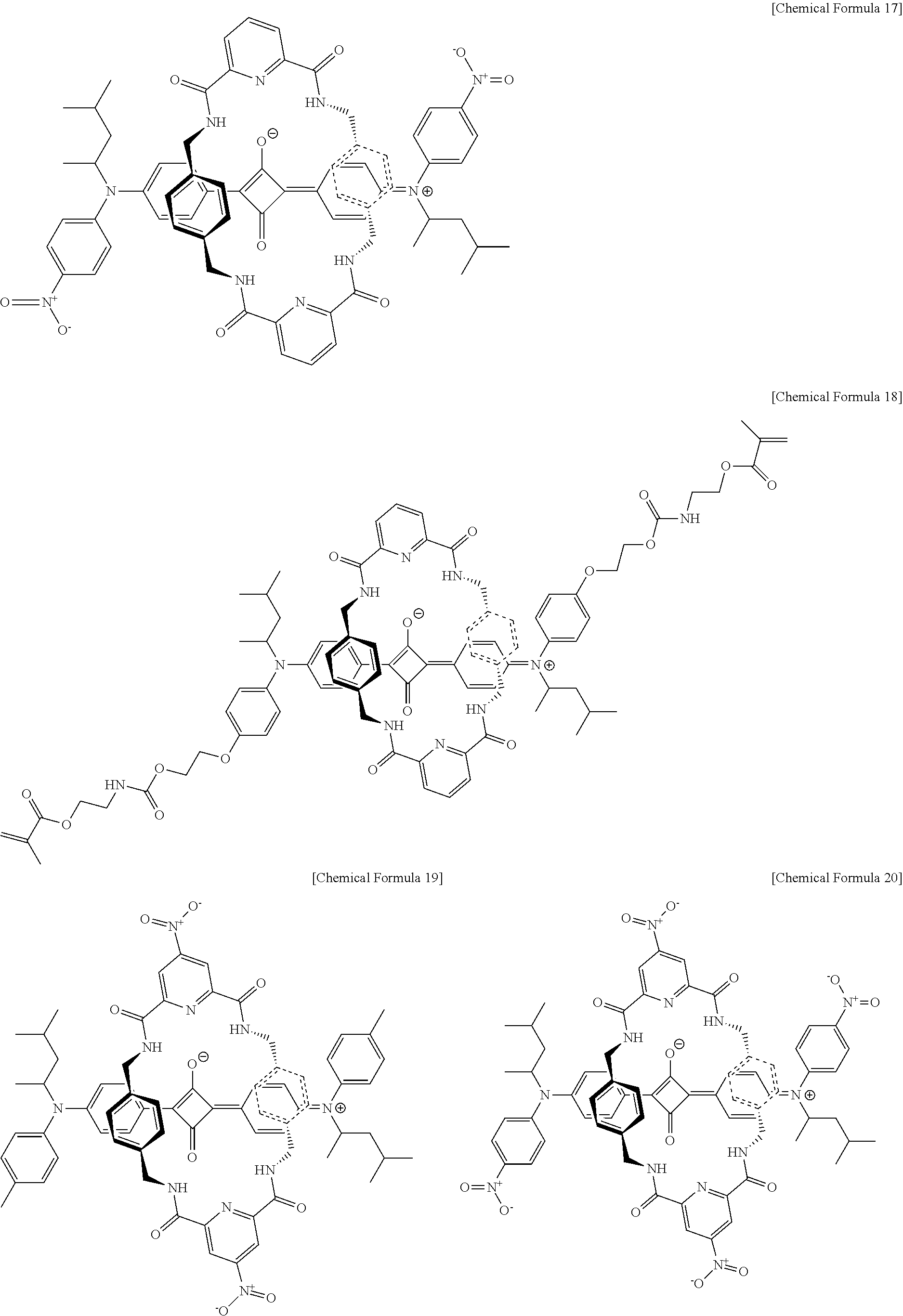

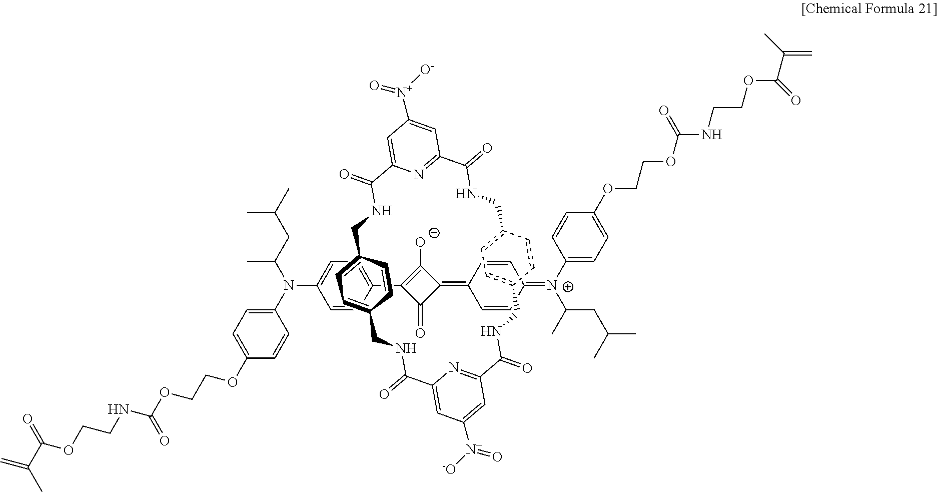

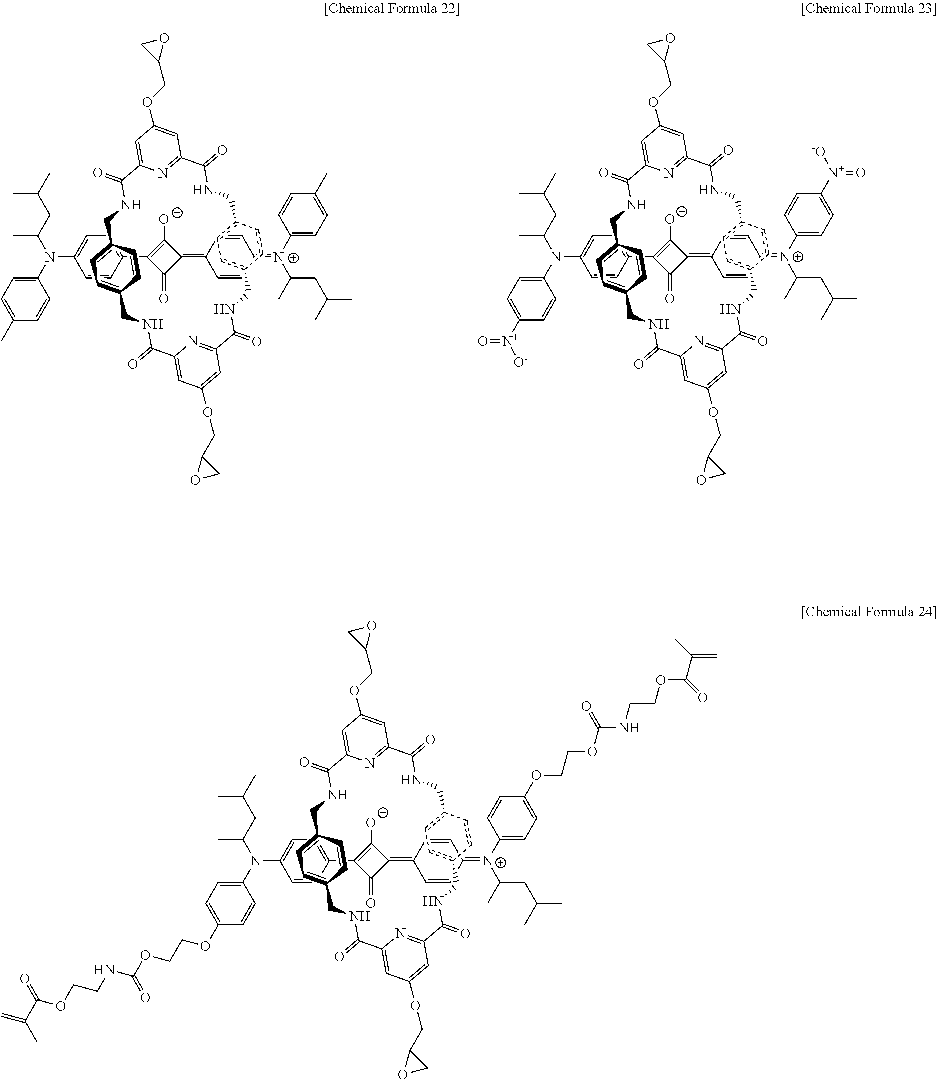

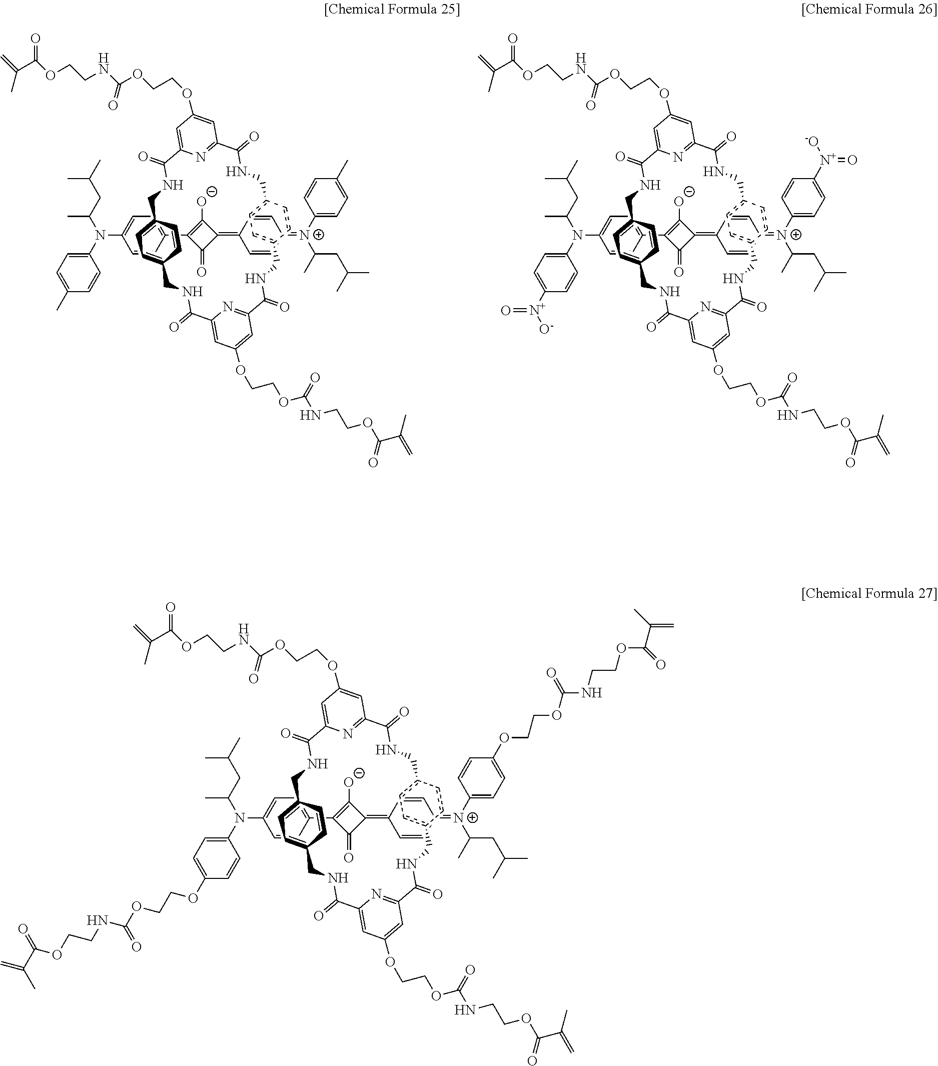

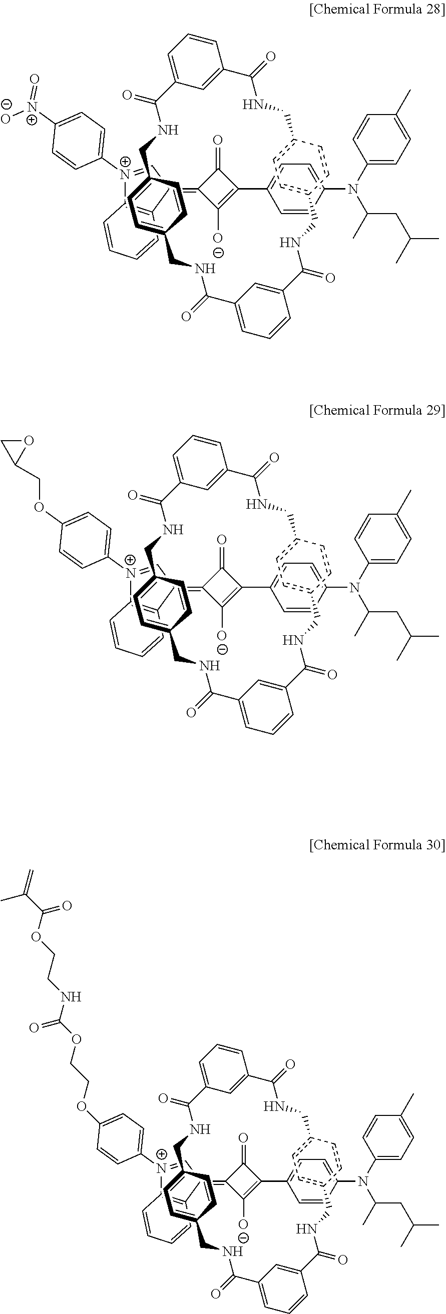

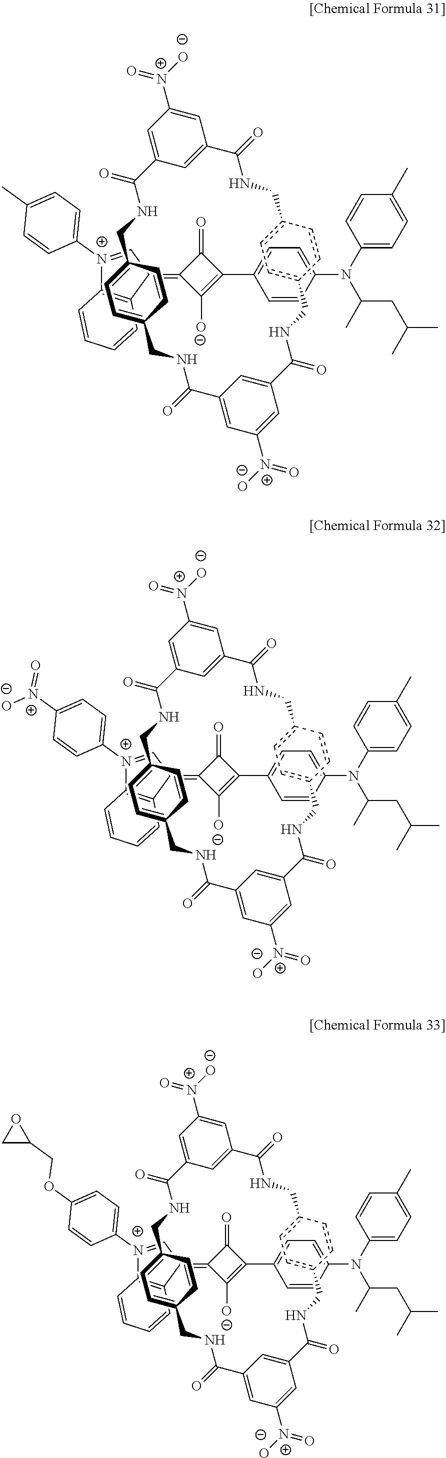

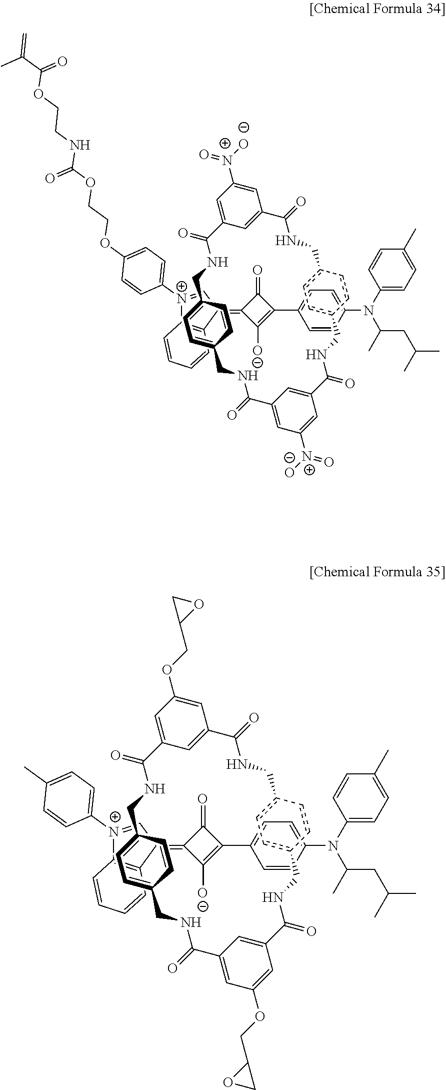

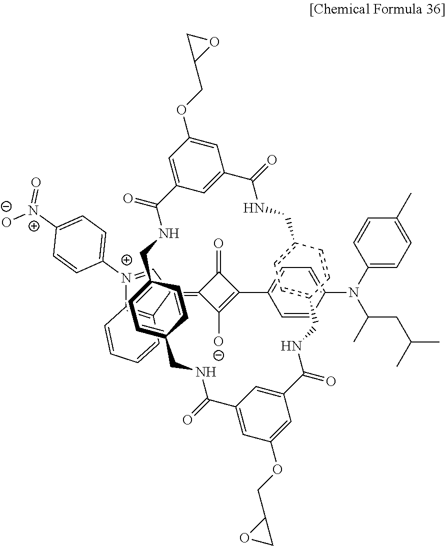

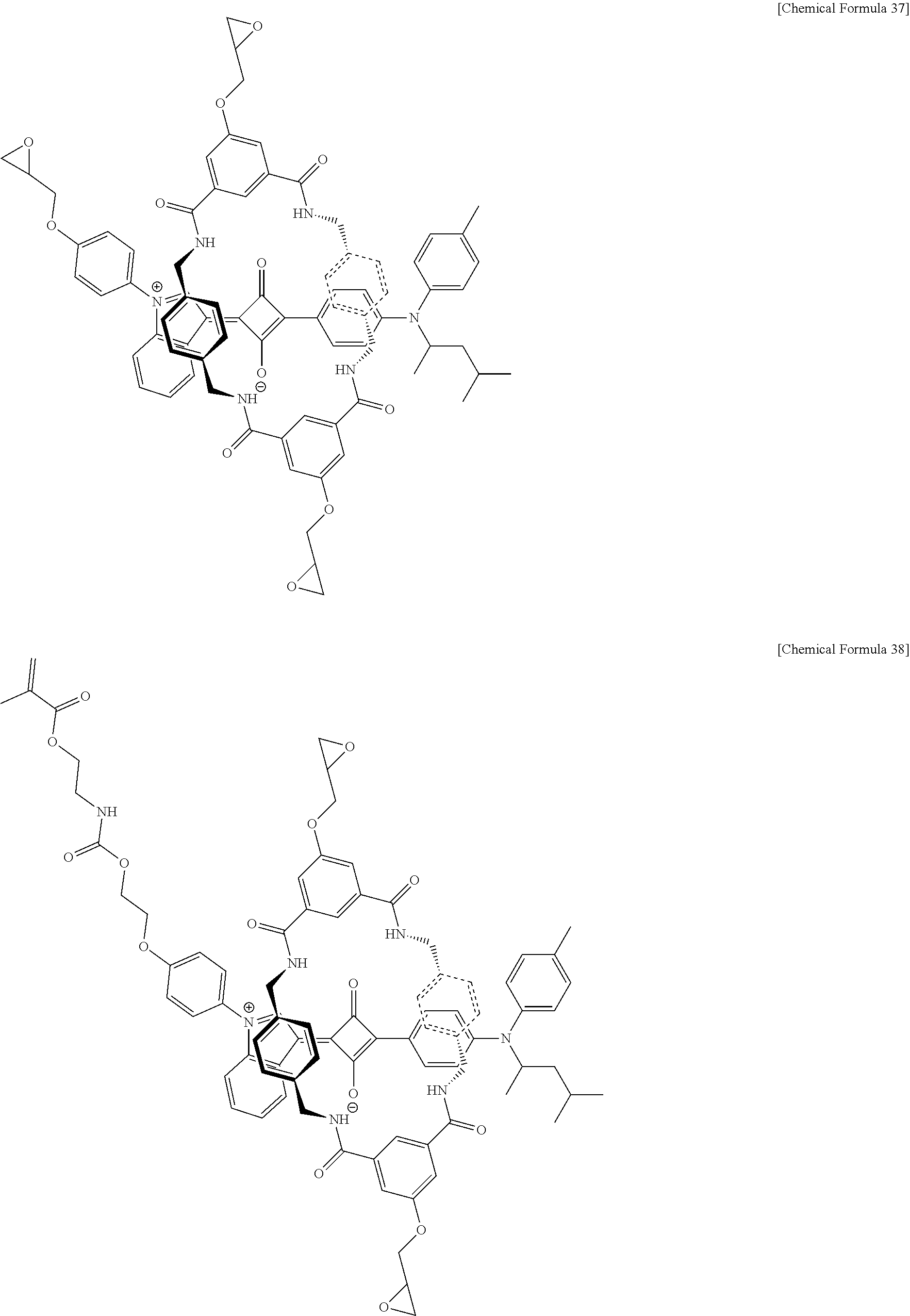

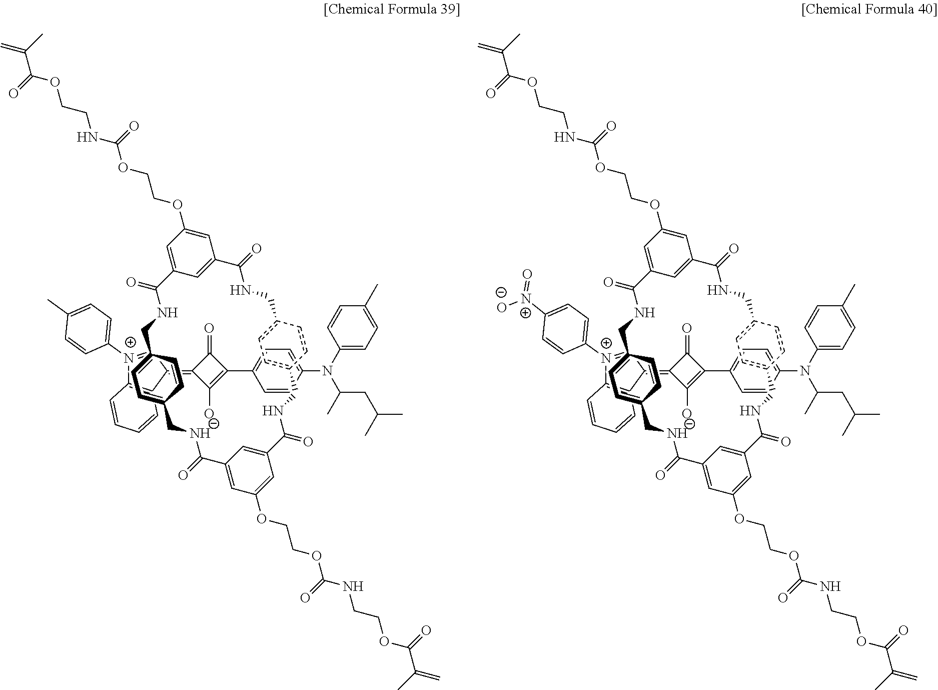

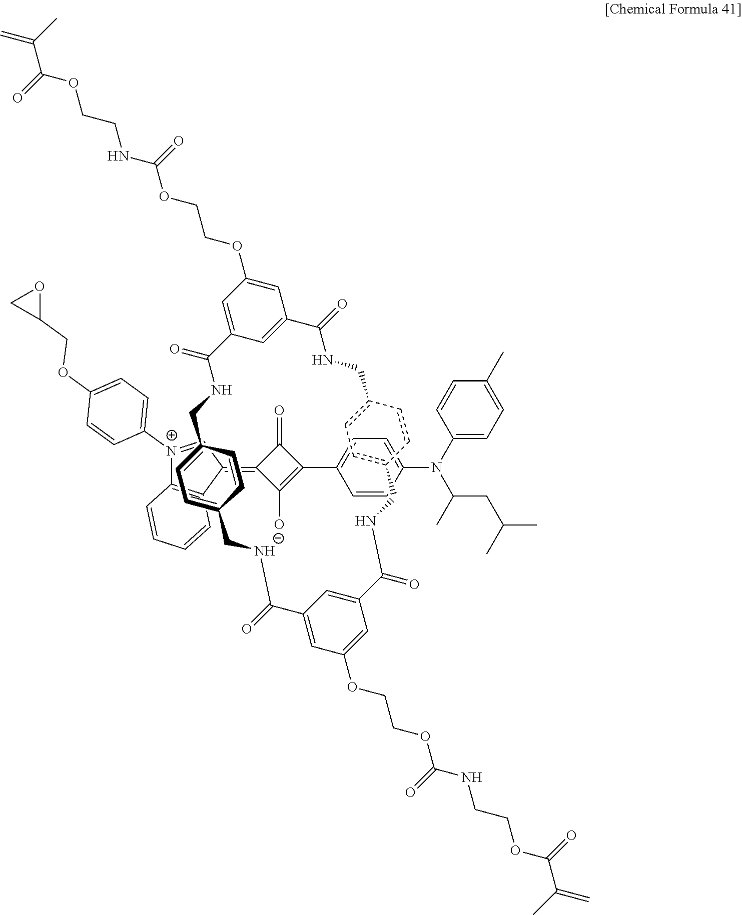

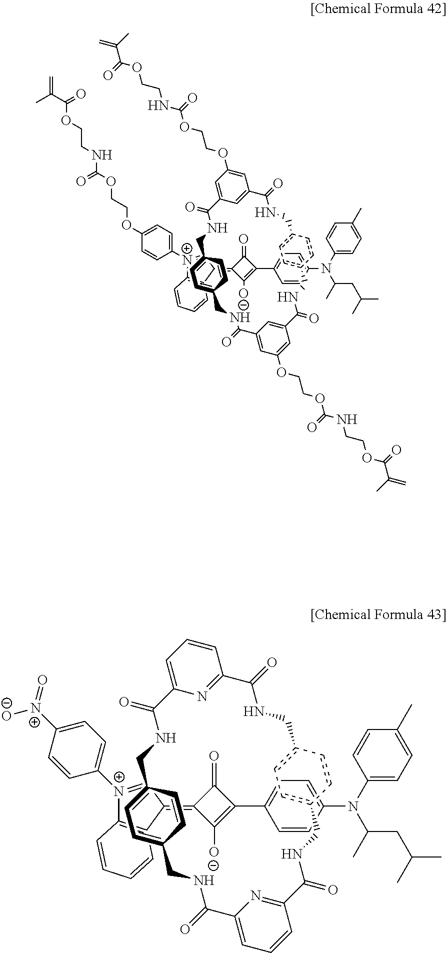

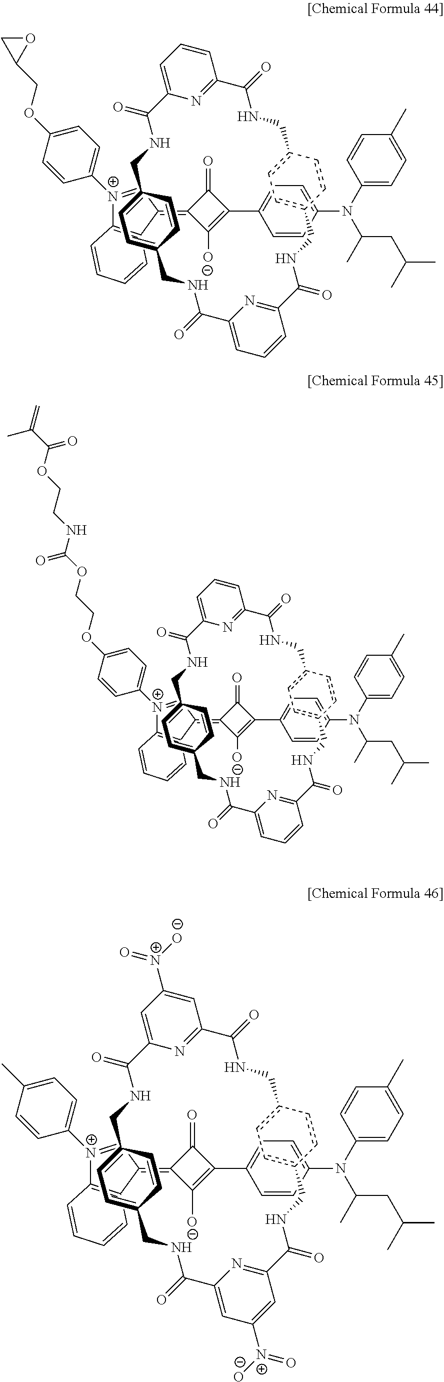

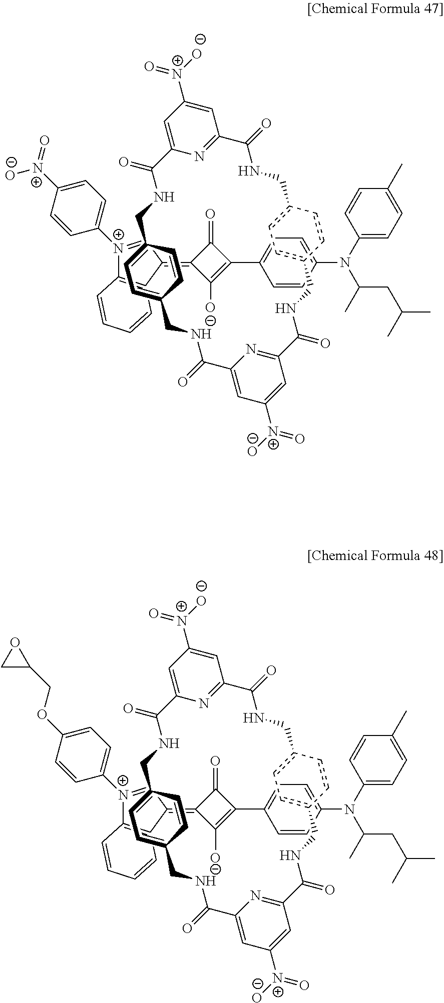

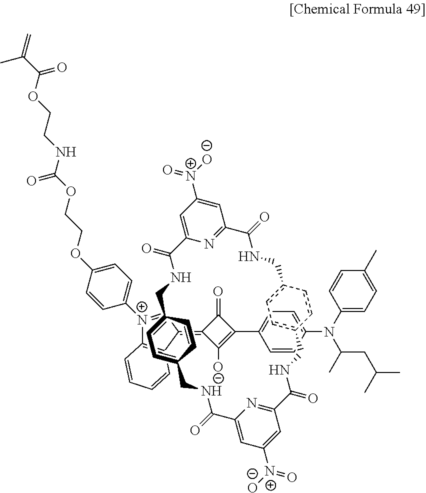

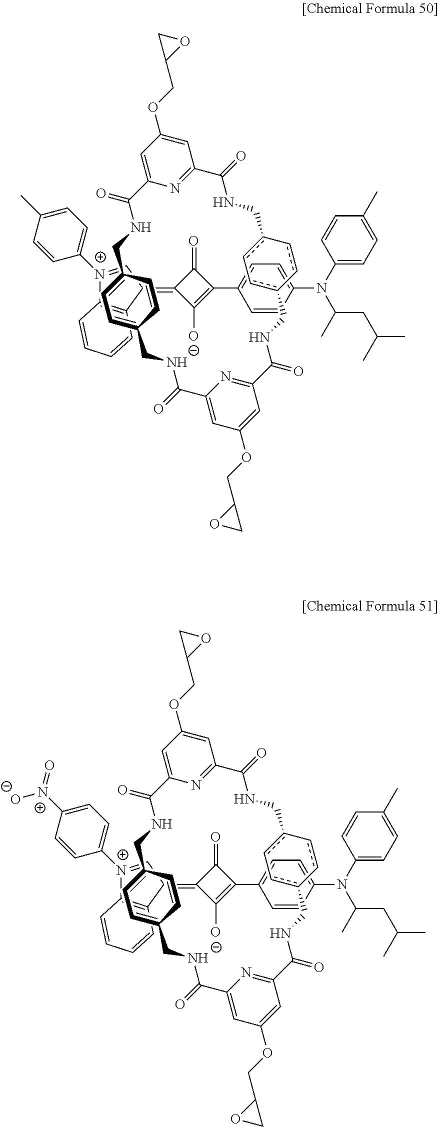

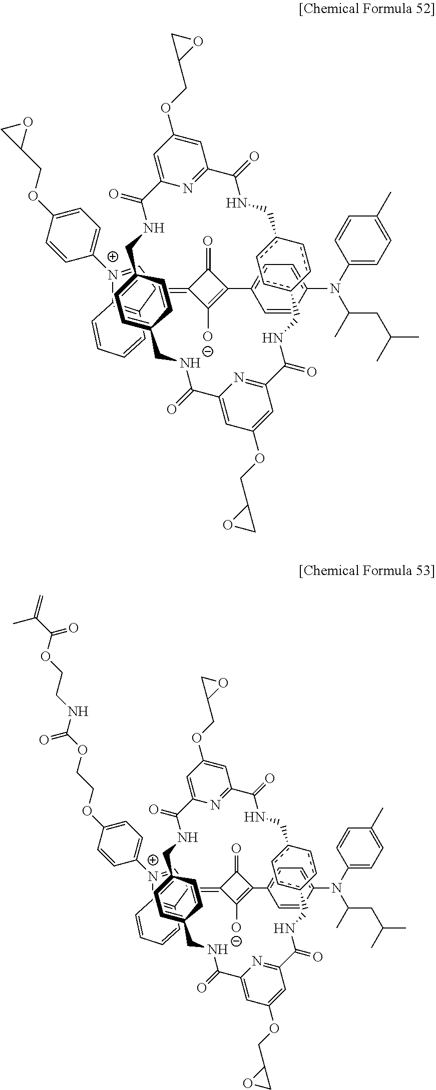

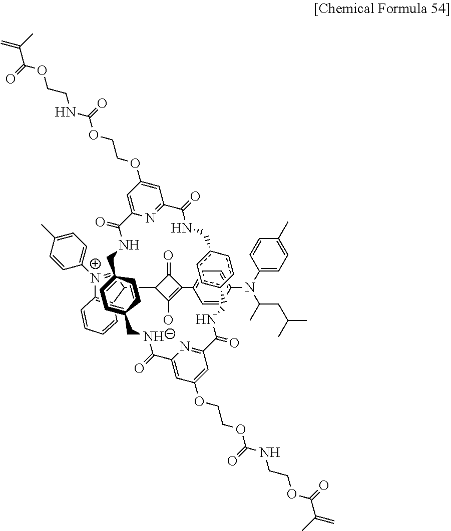

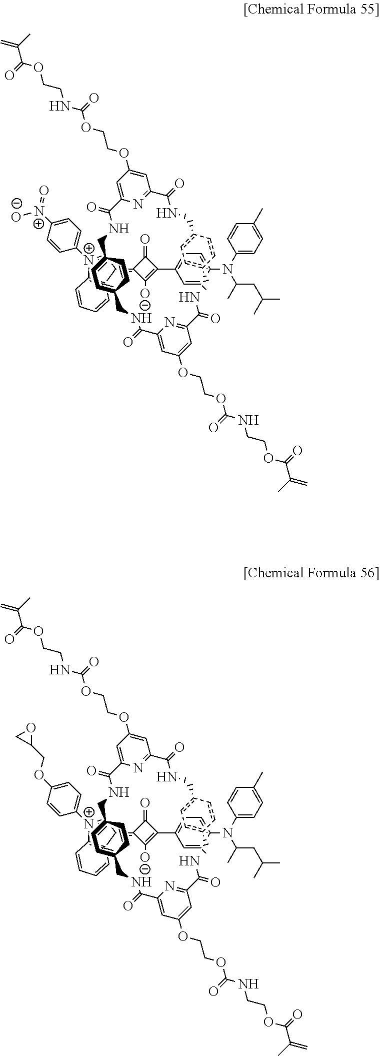

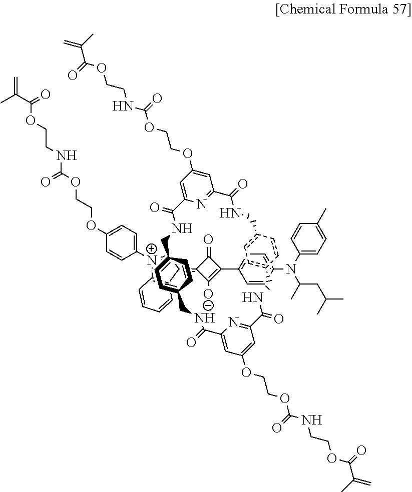

The core-shell dye may be used alone as a green dye and may be mixed with an auxiliary dye.

The auxiliary dye may be a triarylmethane-based dye, an anthraquinone-based dye, a benzylidene-based dye, a cyanine-based dye, phthalocyanine-based dye, an azaporphyrin-based dye, an indigo-based dye, a xanthene-based dye, a pyridone azo-based dye, and the like.

The core-shell dye may be mixed with a pigment.

The pigment may be a red pigment, a green pigment, a blue pigment, a yellow pigment, a black pigment, and the like.

Examples of the red pigment may be C.I. red pigment 254, C.I. red pigment 255, C.I. red pigment 264, C.I. red pigment 270, C.I. red pigment 272, C.I. red pigment 177, C.I. red pigment 89, and the like. Examples of the green pigment may be C.I. green pigment 7, C.I. green pigment 36, C.I. green pigment 58, C.I. green pigment 59, and the like. Examples of the blue pigment may be a copper phthalocyanine pigment such as C.I. blue pigment 15:6, C.I. blue pigment 15, C.I. blue pigment 15:1, C.I. blue pigment 15:2, C.I. blue pigment 15:3, C.I. blue pigment 15:4, C.I. blue pigment 15:5, C.I. blue pigment 16, and the like. Examples of the yellow pigment may be an isoindoline-based pigment such as C.I. yellow pigment 139, and the like, a quinophthalone-based pigment such as C.I. yellow pigment 138, and the like, a nickel complex pigment such as C.I. yellow pigment 150, and the like. Examples of the black pigment may be aniline black, perylene black, titanium black, carbon black, and the like. The pigment may be used alone or as a mixture of two or more and is not limited thereto.

The pigment may be included in the photosensitive resin composition for a color filter in a pigment dispersion liquid state. The pigment dispersion liquid may consist of the pigment and a solvent, a dispersant, a dispersion resin, and the like.

The solvent may be ethylene glycol acetate, ethyl cellosolve, propylene glycol methyl ether acetate, ethyl lactate, polyethylene glycol, cyclohexanone, propylene glycol methyl ether, and the like, and desirably propylene glycol methyl ether acetate.

The dispersant helps uniform dispersion of the pigment, and may include a non-ionic, anionic, or cationic dispersant. Specific examples may be polyalkylene glycol or esters thereof, polyoxy alkylene, polyhydric alcohol ester alkylene oxide adducts, alcohol alkylene oxide addition products, sulfonate esters, sulfonate salts, carboxylate esters, carboxylate salts, alkyl amide alkylene oxide adducts, alkyl amines, and may be used alone or as a mixture of two or more.

The dispersion resin may be an acryl-based resin including a carboxyl group, and improves stability of the pigment dispersion liquid and pattern properties of a pixel.

When the core-shell dye and the pigment are mixed, the core-shell dye and the pigment may be mixed in a weight ratio of 1:9 to 9:1 and specifically in a weight ratio of 3:7 to 7:3. When they are mixed within the weight ratio range, high luminance and contrast ratios may be obtained while color characteristics are maintained.

According to another embodiment, a photosensitive resin composition including the core-shell dye is provided.

The photosensitive resin composition may further include (A) a colorant, (B) a binder resin, (C) a photopolymerizable monomer, (D) a photopolymerization initiator, and (E) a solvent.

Hereinafter, each component is described in detail.

### (A) Colorant

The colorant may include the core-shell dye, which has been described above.

The colorant may further include a pigment in addition to the core-shell dye, and the pigment has been described above.

The core-shell dye may be included in an amount of 0.5 wt % to 10 wt %, for example, 0.5 wt % to 5 wt %, based on the total amount of the photosensitive resin composition for the color filter. When the core-shell dye is used within the above range, high luminance and contrast ratio may be exhibited in a desired color coordinate.

### (B) Binder Resin

The binder resin may be a copolymer of a first ethylenic unsaturated monomer and a second ethylenic unsaturated monomer that is copolymerizable with the first ethylenic unsaturated monomer, and a resin including at least one acryl-based repeating unit.

The first ethylenic unsaturated monomer is an ethylenic unsaturated monomer including at least one carboxyl group. Examples of the monomer include acrylic acid, methacrylic acid, maleic acid, itaconic acid, fumaric acid, or a combination thereof.

The first ethylenic unsaturated monomer may be included in an amount of 5 wt % to 50 wt %, for example 10 wt % to 40 wt % based on a total amount of the alkali soluble resin.

Examples of the second ethylenic unsaturated monomer may include an aromatic vinyl compound such as styrene, α-methylstyrene, vinyltoluene, vinylbenzylmethylether, and the like; an unsaturated carboxylic acid ester compound such as methyl (meth)acrylate, ethyl (meth)acrylate, butyl(meth)acrylate, 2-hydroxyethyl(meth)acrylate, 2-hydroxy butyl(meth)acrylate, benzyl(meth)acrylate, cyclohexyl(meth)acrylate, phenyl(meth)acrylate, and the like; an unsaturated carboxylic acid amino alkyl ester compound such as 2-aminoethyl (meth)acrylate, 2-dimethylaminoethyl(meth)acrylate, and the like; a carboxylic acid vinyl ester compound such as vinyl acetate, vinyl benzoate, and the like; an unsaturated carboxylic acid glycidyl ester compound such as glycidyl(meth)acrylate and the like; a vinyl cyanide compound such as (meth)acrylonitrile and the like; an unsaturated amide compound such as (meth)acrylamide and the like; and the like and they may be used alone or as a mixture of two or more.

Examples of the binder resin may include a methacrylic acid/benzylmethacrylate copolymer, a methacrylic acid/benzylmethacrylate/styrene copolymer, a methacrylic acid/benzylmethacrylate/2-hydroxyethylmethacrylate copolymer, a methacrylic acid/benzylmethacrylate/styrene/2-hydroxyethylmethacrylate copolymer, and the like, but are not limited thereto and they may be used alone or as a mixture of two or more.

The binder resin may have a weight average molecular weight of 3,000 g/mol to 150,000 g/mol, for example 5,000 g/mol to 50,000 g/mol or 20,000 g/mol to 30,000 g/mol. When the binder resin has a weight average molecular weight within the range, the composition may have an excellent close contacting property with a substrate, good physical and chemical properties, and appropriate viscosity.

The binder resin may have an acid value of 15 mgKOH/g to 60 mgKOH/g, for example 20 mgKOH/g to 50 mgKOH/g. When the binder resin has an acid value within the range, it may bring about excellent pixel resolution.

The binder resin may be included in an amount of 0.1 wt % to 30 wt %, for example 5 wt % to 20 wt % based on a total amount of the photosensitive resin composition. When the binder resin is included within the range, the composition may have an excellent developability and improved crosslinking, and thus has excellent surface flatness when manufactured into a color filter.

### (C) Photopolymerizable Monomer

The photopolymerizable monomer may be mono-functional or multi-functional ester of (meth)acrylic acid including at least one ethylenic unsaturated double bond.

The photopolymerizable monomer has the ethylenic unsaturated double bond and thus, may cause sufficient polymerization during exposure in a pattern-forming process and form a pattern having excellent heat resistance, light resistance, and chemical resistance.

Specific examples of the photopolymerizable monomer may be ethylene glycol di(meth)acrylate, diethylene glycol di(meth)acrylate, triethylene glycol di(meth)acrylate, propylene glycol di(meth)acrylate, neopentyl glycol di(meth)acrylate, 1,4-butanediol di(meth)acrylate, 1,6-hexanediol di(meth)acrylate, bisphenol A di(meth)acrylate, pentaerythritol di(meth)acrylate, pentaerythritol tri(meth)acrylate, pentaerythritol tetra(meth)acrylate, pentaerythritol hexa(meth)acrylate, dipentaerythritol di(meth)acrylate, dipentaerythritol tri(meth)acrylate, dipentaerythritol penta(meth)acrylate, dipentaerythritol hexa(meth)acrylate, bisphenol A epoxy (meth)acrylate, ethylene glycol monomethylether (meth)acrylate, trimethylol propane tri(meth)acrylate, tris(meth)acryloyloxyethyl phosphate, novolac epoxy (meth)acrylate, and the like.

Commercially available examples of the photopolymerizable monomer are as follows. The mono-functional (meth)acrylic acid ester may include Aronix M-101®, M-111®, M-114® (Toagosei Chemistry Industry Co., Ltd.); KAYARAD TC-110S®, TC-120S® (Nippon Kayaku Co., Ltd.); V-158®, V-2311® (Osaka Organic Chemical Ind., Ltd.), and the like. Examples of a difunctional (meth)acrylic acid ester may include Aronix M-210®, M-240®, M-6200® (Toagosei Chemistry Industry Co., Ltd.), KAYARAD HDDAR, HX-220®, R-604® (Nippon Kayaku Co., Ltd.), V-260®, V-312®, V-335 HP® (Osaka Organic Chemical Ind., Ltd.), and the like. Examples of a tri-functional (meth)acrylic acid ester may include Aronix M-309®, M-400®, M-405®, M-450®, M-7100®, M-8030®, M-8060® (Toagosei Chemistry Industry Co., Ltd.), KAYARAD TMPTA®, DPCA-20®, DPCA-30®, DPCA-60®, DPCA-120® (Nippon Kayaku Co., Ltd.), V-295® V-300®, V-360®, V-GPT®, V-3PAR, V-400® (Osaka Yuki Kayaku Kogyo Co. Ltd.), and the like. These may be used alone or as a mixture of two or more.

The photopolymerizable monomer may be treated with acid anhydride to improve developability.

The photopolymerizable monomer may be included in an amount of 0.1 wt % to 30 wt %, for example 5 wt % to 20 wt % based on the total amount of the photosensitive resin composition. When the photopolymerizable monomer is included within the range, pattern characteristics.

### (D) Photopolymerization Initiator

The photopolymerization initiator may include an acetophenone-based compound, a benzophenone-based compound, a thioxanthone-based compound, a benzoin-based compound, a triazine-based compound, an oxime-based compound, and the like.

Examples of the acetophenone-based compound may include 2,2′-diethoxy acetophenone, 2,2′-dibutoxy acetophenone, 2-hydroxy-2-methylpropinophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, and the like.

Examples of the benzophenone-based compound may include benzophenone, benzoyl benzoate, benzoyl methyl benzoate, 4-phenyl benzophenone, hydroxy benzophenone, acrylated benzophenone, 4,4′-bis(dimethyl amino)benzophenone, 4,4′-bis(diethylamino)benzophenone, 4,4′-dimethylaminobenzophenone, 4,4′-dichlorobenzophenone, 3,3′-dimethyl-2-methoxybenzophenone, and the like.

Examples of the thioxanthone-based compound may include thioxanthone, 2-methylthioxanthone, isopropyl thioxanthone, 2,4-diethyl thioxanthone, 2,4-diisopropyl thioxanthone, 2-chlorothioxanthone, and the like.

Examples of the benzoin-based compound may include benzoin, benzoin methyl ether, benzoin ethyl ether, benzoin isopropyl ether, benzoin isobutyl ether, benzyldimethylketal, and the like.

Examples of the triazine-based compound may include 2,4,6-trichloro-s-triazine, 2-phenyl 4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloro methyl)-s-triazine, 2-biphenyl 4,6-bis(trichloro methyl)-s-triazine, bis(trichloromethyl)-6-styryl-s-triazine, 2-(naphtho1-yl)-4,6-bis(trichloromethyl)-s-triazine, 2-(4-methoxynaphtho1-yl)-4,6-bis(trichloromethyl)-s-triazine, 2-4-trichloromethyl(piperonyl)-6-triazine, 2-4-trichloromethyl (4′-methoxystyryl)-6-triazine, and the like.

Examples of the oxime-based compound may include 2-(o-benzoyloxime)-1-[4-(phenylthio)phenyl]-1,2-octandione, 1-(o-acetyloxime)-1-[9-ethyl-6-(2-methylbenzoyl)-9H-carbazol-3-yl]ethanone, and the like.

The photopolymerization initiator may include a carbazole-based compound, a diketone-based compound, a sulfonium borate-based compound, a diazo-based compound, an imidazole-based compound, a biimidazole-based compound, a fluorene-based compound, and the like, besides the compounds.

The photopolymerization initiator may be included in an amount of 0.1 wt % to 5 wt %, for example 1 wt % to 3 wt % based on the total amount of the photosensitive resin composition. When the photopolymerization initiator is included within the range, the composition may be sufficiently photopolymerized when exposed to light during the pattern-forming process for preparing a color filter, accomplishing excellent sensitivity and improving transmittance.

### (E) Solvent

The solvent is not specifically limited, but examples of the solvent include alcohols such as methanol, ethanol, and the like; ethers such as dichloroethyl ether, n-butyl ether, diisoamyl ether, methylphenyl ether, tetrahydrofuran, and the like; glycol ethers such as ethylene glycol methylether, ethylene glycol ethylether, propylene glycol methylether, and the like; cellosolve acetates such as methyl cellosolve acetate, ethyl cellosolve acetate, diethyl cellosolve acetate, and the like; carbitols such as methylethyl carbitol, diethyl carbitol, diethylene glycol monomethylether, diethylene glycol monoethylether, diethylene glycol dimethylether, diethylene glycol methylethylether, diethylene glycol diethylether, and the like; propylene glycol alkylether acetates such as propylene glycol methylether acetate, propylene glycol propylether acetate, and the like; aromatic hydrocarbons such as toluene, xylene, and the like; ketones such as methylethylketone, cyclohexanone, 4-hydroxy-4-methyl-2-pentanone, methyl-n-propylketone, methyl-n-butylketone, methyl-n-amylketone, 2-heptanone, and the like; saturated aliphatic monocarboxylic acid alkyl esters such as ethyl acetate, n-butyl acetate, isobutyl acetate, and the like; lactic acid alkyl esters such as methyl lactate, ethyl lactate, and the like; hydroxyacetic acid alkyl esters such as methyl hydroxyacetate, ethyl hydroxyacetate, butyl hydroxyacetate, and the like; acetic acid alkoxyalkyl esters such as methoxymethyl acetate, methoxyethyl acetate, methoxybutyl acetate, ethoxymethyl acetate, ethoxyethyl acetate, and the like; 3-hydroxypropionic acid alkyl esters such as methyl 3-hydroxypropionate, ethyl 3-hydroxypropionate, and the like; 3-alkoxypropionic acid alkyl esters such as methyl 3-methoxypropionate, ethyl 3-methoxypropionate, ethyl 3-ethoxypropionate, methyl 3-ethoxypropionate, and the like; 2-hydroxypropionic acid alkyl esters such as methyl 2-hydroxypropionate, ethyl 2-hydroxypropionate, propyl 2-hydroxypropionate, and the like; 2-alkoxypropionic acid alkyl esters such as methyl 2-methoxypropionate, ethyl 2-methoxypropionate, ethyl 2-ethoxypropionate, methyl 2-ethoxypropionate, and the like; 2-hydroxy-2-methylpropionic acid alkyl esters such as methyl 2-hydroxy-2-methylpropionate, ethyl 2-hydroxy-2-methylpropionate, and the like; 2-alkoxy-2-methylpropionic acid alkyl esters such as methyl 2-methoxy-2-methylpropionate, ethyl 2-ethoxy-2-methylpropionate, and the like; esters such as 2-hydroxyethyl propionate, 2-hydroxy-2-methylethyl propionate, hydroxyethyl acetate, methyl 2-hydroxy-3-methylbutanoate, and the like; or ketonic acid ester compounds such as ethyl pyruvate. Furthermore, the solvent may be N-methylformamide, N,N-dimethylformamide, N-methylformanilide, N-methylacetamide, N,N-dimethylacetamide, N-methylpyrrolidone, dimethylsulfoxide, benzylethylether, dihexylether, acetyl acetone, isophorone, caproic acid, caprylic acid, 1-octanol, 1-nonanol, benzylalcohol, benzyl acetate, ethyl benzoate, diethyl oxalate, diethyl maleate, γ-butyrolactone, ethylene carbonate, propylene carbonate, phenyl cellosolve acetate, and the like. These may be used alone or as a mixture of two or more.

Considering miscibility, reactivity, and the like, the solvent may include glycol ethers such as ethylene glycol monoethyl ether, and the like; ethylene glycol alkylether acetates such as ethyl cellosolve acetate, and the like; esters such as 2-hydroxyethyl propionate, and the like; diethylene glycols such as diethylene glycol monomethyl ether, and the like; propylene glycol alkylether acetates such as propylene glycol monomethylether acetate, propylene glycol propylether acetate, and the like.

The solvent may be included in a balance amount, and specifically, in an amount of 20 wt % to 90 wt % based on the total amount of the photosensitive resin composition

When the solvent is included within the range, the photosensitive resin composition may have excellent coating properties and maintain excellent flatness in a layer having a thickness of greater than or equal to 3 μm.

### (F) Other Additives

The photosensitive resin composition may further include other additives such as malonic acid; 3-amino-1,2-propanediol; a silane-based coupling agent including a vinyl group or a (meth)acryloxy group; a leveling agent; a fluorine-based surfactant; a radical polymerization initiator, in order to prevent stains or spots during the coating, to adjust leveling, or to prevent pattern residue due to non-development.

The photosensitive resin composition may further include an epoxy compound in order to improve close-contacting properties with a substrate.

Examples of the epoxy compound may include a phenol novolac epoxy compound, a tetramethyl biphenyl epoxy compound, a bisphenol A epoxy compound, an alicyclic epoxy compound, or a combination thereof.

A use amount of the additive may be controlled depending on desired properties.

Another embodiment provides a photosensitive resin film manufactured using the aforementioned photosensitive resin composition.

Another embodiment provides a color filter including the photosensitive resin film. A method of manufacturing the color filter is as follows.

The photosensitive resin composition for a color filter is coated to have a thickness of 3.1 μm to 3.4 μm using an appropriate method such as a spin coating, a slit coating and the like, on a bare glass substrate or on a glass substrate on which a protective layer, SiNₓ is coated in a thickness of 500 Å to 1500 Å. After the coating, the composition is irradiated with light to form a pattern required for a color filter. After irradiation of the light, the coating layer is treated with an alkali developing solution, and the non-irradiated region thereof may be dissolved, forming a pattern for a color filter. This process is repeated depending on the necessary number of R, G, and B colors, manufacturing a color filter having a desired pattern.

In addition, the image pattern acquired by the development is cured through heat treatment, actinic ray irradiation, or the like, resultantly improving crack resistance, solvent resistance, and the like.

Another embodiment provides a CMOS image sensor including the color filter.

### Detailed Description of the Embodiments

Hereinafter, the present invention is illustrated in more detail with reference to examples. These examples, however, are not in any sense to be interpreted as limiting the scope of the invention.

### Preparation of Compounds

### Synthesis Example 1: Synthesis of Core Dye Represented by Chemical Formula 1-1

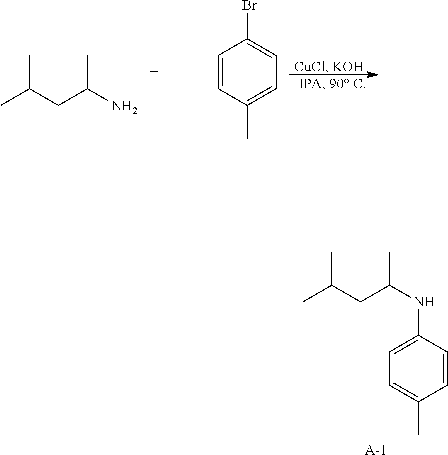

1,3-dimethylbuytlamine (60 mmol), 4-bromotoluene (30 mmol), KOH (60 mmol), and CuCl (0.3 mmol) were added to isopropyl alcohol and then, heated to 90° C. and stirred for 12 hours. Subsequently, ethyl acetate was added to the solution and then, twice washed with a sat. NH₄Cl aqueous solution and a 10% NaCl aqueous solution, extracting an organic layer. The extracted organic layer was distilled under a reduced pressure and purified through column chromatography, obtaining Intermediate A-1.

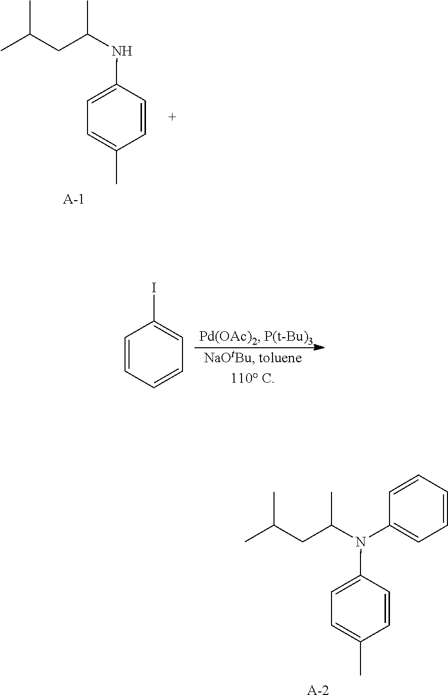 [SMILES: Cc1ccc(NC(C)CC(C)C)cc1 ; "A-1" ; Ic1ccccc1 ; Cc1ccc(N(c2ccccc2)C(C)CC(C)C)cc1 ; "A-2"]

Intermediate A-1 (20 mmol), Pd(OAc)₂ (0.002 mmol), sodium t-butoxide (30 mmol), and iodobenzene (20 mmol) were added to a toluene solvent and then, stirred at room temperature for 30 minutes, and P(t-Bu)₃ (0.004 mmol) was added thereto and then, stirred at 110° C. for 15 hours. Subsequently, ethyl acetate was added to the solution and then, twice washed with water, extracting an organic layer. The extracted organic layer was distilled under a reduced pressure and purified through column chromatography, obtaining Intermediate A-2.

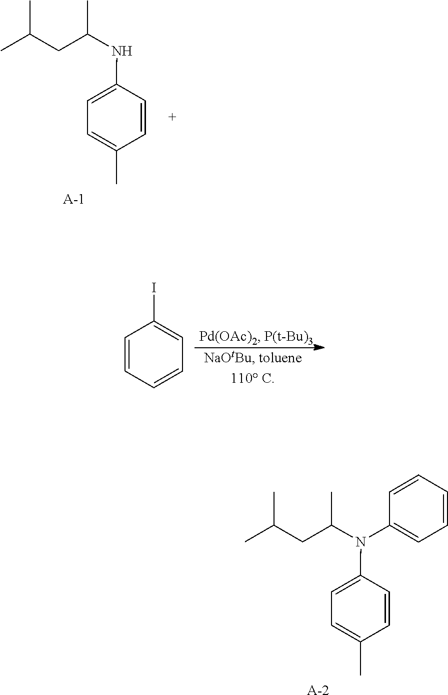 [SMILES: Cc1ccc(NC(C)CC(C)C)cc1 ; "A-1" ; Ic1ccccc1 ; Cc1ccc(N(c2ccccc2)C(C)CC(C)C)cc1 ; "A-2"]

Intermediate A-2 (60 mmol) and 3,4-dihydroxy-3-cyclobutyne-1,2-dione (30 mmol) were added to toluene (200 mL) and butanol (200 mL) and then, refluxed, and water produced therefrom was removed through Dean-stark distillation device. After stirring for 12 hours, a green reactant therefrom was distilled under a reduced pressure and purified through column chromatography, obtaining a compound represented by Chemical Formula 1-1.

### Synthesis Example 2: Synthesis of Core Dye Represented by Chemical Formula 1-2

A compound represented by Chemical Formula 1-2 was synthesized in the same manner as in Synthesis Example 1 except that N-(4-methylpentan-2-yl)-4-nitro-N-phenylaniline was used instead of Intermediate A-2.

### Synthesis Example 3: Synthesis of Core Dye Represented by Chemical Formula 1-3

A compound represented by Chemical Formula 1-3 was synthesized in the same manner as in Synthesis Example 1 except that 2-(((2-(4-((4-methylpentan-2-yl)(phenyl)amino)phenoxy)ethoxy)carbonyl)amino)ethyl methacrylate was used instead of Intermediate A-2.

### Synthesis Example 4: Synthesis of Core Dye Represented by Chemical Formula 2-1

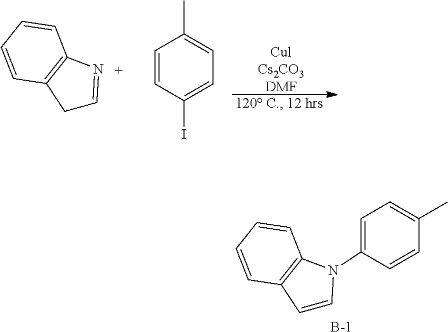

A mixture of 12 mmol (1 eq) of indole, 12 mmol (1 eq) of 4-iodotoluene, 2.4 mmol (0.2 eq) of copper (I) iodide, 24 mmol (2 eq) of cesium carbonate, and 20 mL of DMF was stirred at 120° C. for 12 hours. Subsequently, ethyl acetate was added to the solution and then, twice washed with water, extracting an organic layer. The extracted organic layer was distilled under a reduced pressure and purified through column chromatography, obtaining Intermediate B-1 in a yield of 30%.

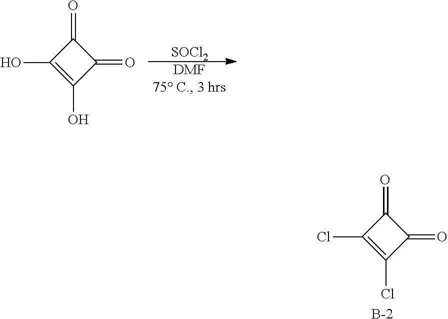

A mixture of 32 mmol (1 eq) of squaric acid, 80 mmol (2.5 eq) of thionyl chloride, and 10 drops of N,N-dimethyl formamide were reacted at 75° C. for 3 hours, and yellow crystals obtained therefrom were filtered at room temperature, obtaining Intermediate B-2 in a yield of 50%.

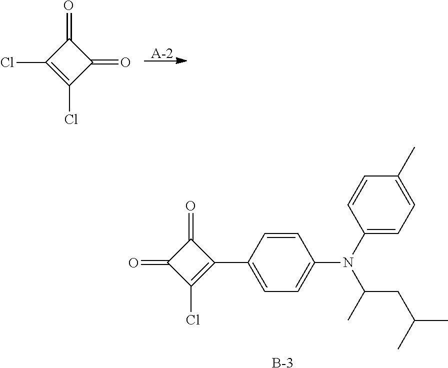

A 0.2 M toluene solution of Intermediate A-2 was added in a dropwise fashion to a 0.3 M toluene solution of Intermediate B-2 and then, stirred at room temperature for 1 hour and also, stirred at 80° C. for 12 hours. After removing the toluene under a reduced pressure, the residue was purified through column chromatography, obtaining Intermediate B-3 in a yield of 50%.

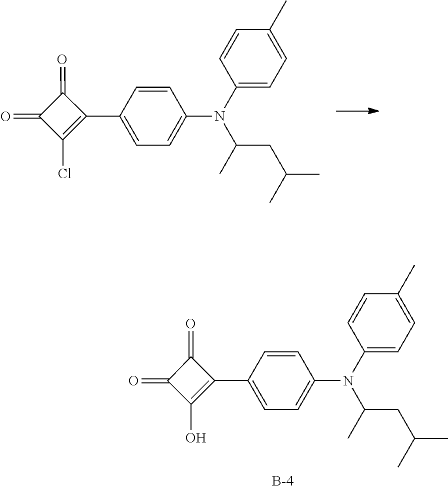

A mixture of 1 fold of Intermediate B-3, 8 folds of acetic acid, 8 folds of water, and 0.1 fold of concentrated hydrochloric acid were stirred at 130° C. for 12 hours. Subsequently, methylene chloride was added to the solution and then, twice washed with a 10% hydrochloric acid aqueous solution, extracting an organic layer. The extracted organic layer was distilled under a reduced pressure, obtaining Intermediate B-4 in a yield of 100%.

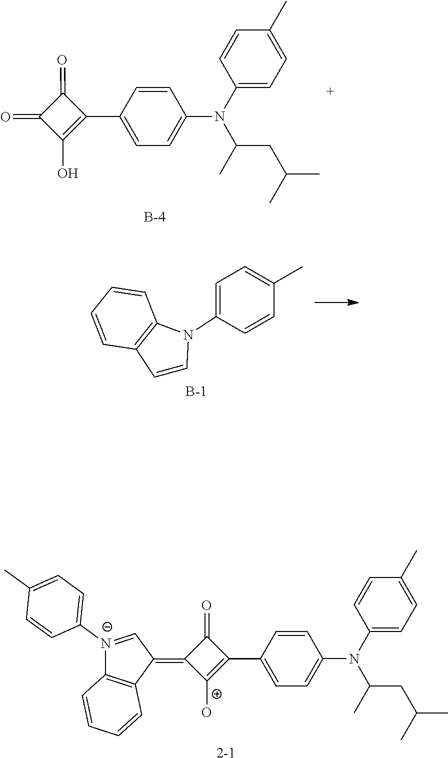

60 mmol of Intermediate B-1 and 60 mmol of Intermediate B-4 were added to toluene (200 mL) and butanol (200 mL) and then, refluxed, and water produced therefrom was removed with a Dean-stark distillation device. After stirred for 12 hours, a green reactant therefrom was distilled under a reduced pressure and purified through column chromatography, obtaining a compound represented by Chemical Formula 2-1.

### Synthesis of Core-Shell Dyes

### Synthesis Example 5: Synthesis of Core-shell Dye Represented by Chemical Formula 17

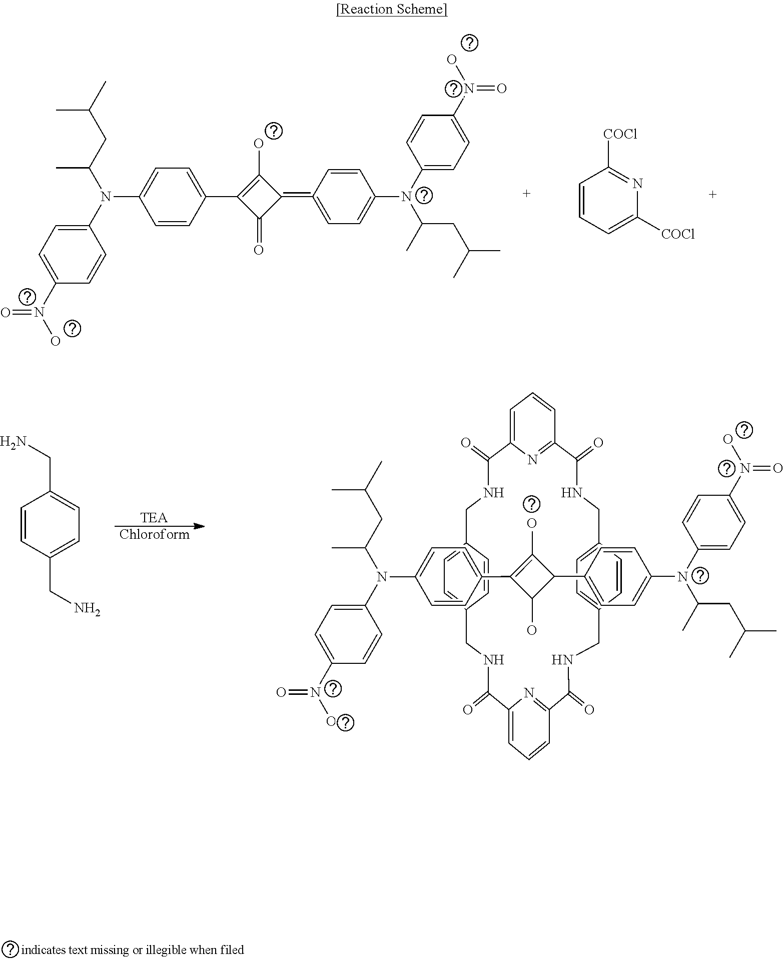

The compound represented by Chemical Formula 1-2 (5 mmol) was dissolved in 600 mL of a chloroform solvent, and triethylamine (50 mmol) was added thereto. 2,6-pyridinedicarbonyl dichloride (20 mmol) and p-xylylenediamine (20 mmol) were dissolved in 60 mL of chloroform and then, simultaneously added dropwise thereto at room temperature for 5 hours. After 12 hours, the reactant was distilled under a reduced pressure and separated through column chromatography, obtaining a compound represented by Chemical Formula 17.

### Synthesis Example 6: Synthesis of Core-Shell Dye Represented by Chemical Formula 18

A compound represented by Chemical Formula 18 was synthesized in the same manner as in Synthesis Example 5 except that the compound represented by Chemical Formula 1-3 was used the compound represented by Chemical Formula 1-2.

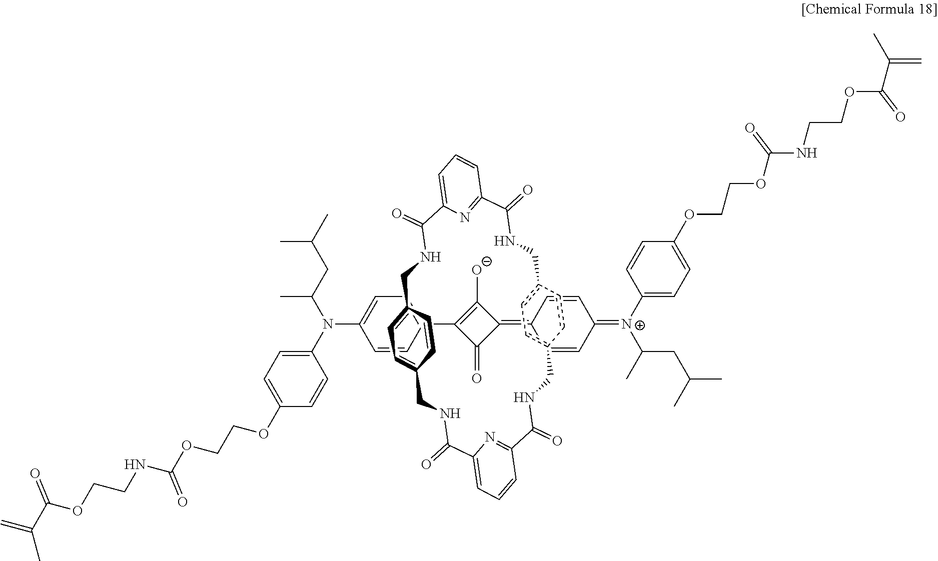

### Synthesis Example 7: Synthesis of Core-Shell Dye Represented by Chemical Formula 22

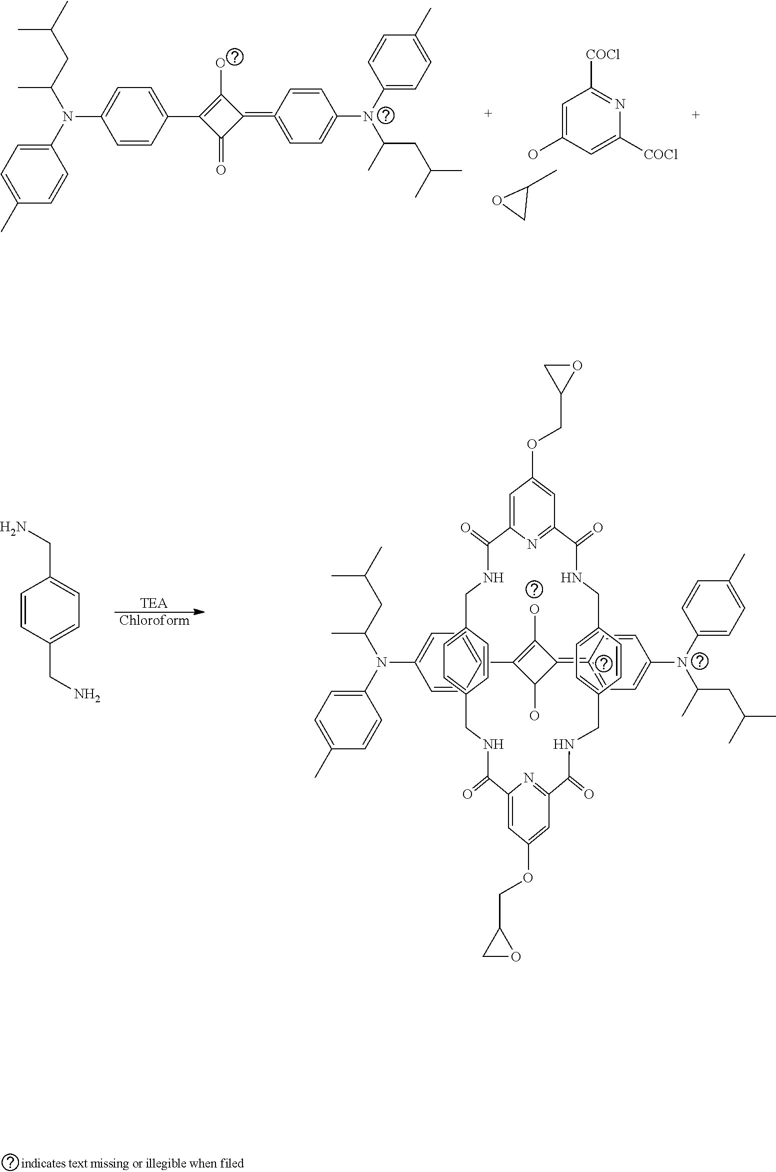

The compound represented by Chemical Formula 1-1 (5 mmol) was dissolved in 600 mL of a chloroform solvent, and then, triethylamine (50 mmol) was added thereto. Subsequently, 4-(oxiran-2-ylmethoxy)pyridine-2,6-dicarbonyl dichloride (20 mmol) and p-xylylenediamine (20 mmol) were dissolved in 60 mL of chloroform and then, simultaneously added dropwise thereto for 5 hours. After 12 hours, the reactant was distilled under a reduced pressure and separated through column chromatography, obtaining a compound represented by Chemical Formula 22.

### Synthesis Example 8: Synthesis of Core-Shell Dye Represented by Chemical Formula 23

A compound represented by Chemical Formula 23 was synthesized in the same manner as in Synthesis Example 7 except that the compound represented by Chemical Formula 1-2 was used instead of the compound represented by Chemical Formula 1-1.

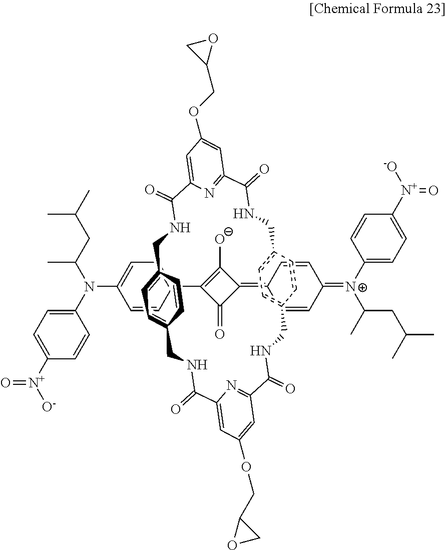

### Synthesis Example 9: Synthesis of Core-Shell Dye Represented by Chemical Formula 24

A compound represented by Chemical Formula 24 was synthesized in the same manner as in Synthesis Example 7 except that the compound represented by Chemical Formula 1-3 was used instead of the compound represented by Chemical Formula 1-1.

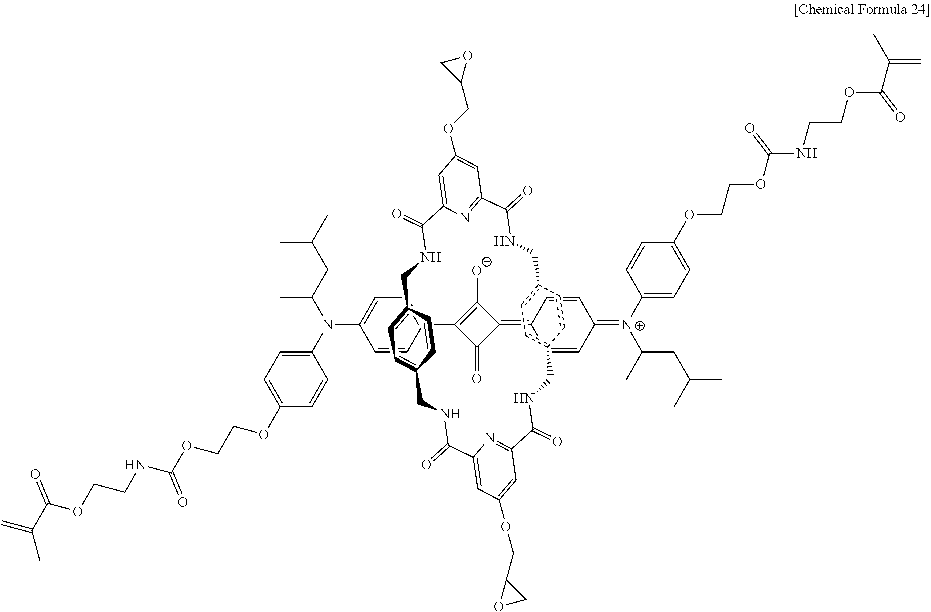

### Synthesis Example 10: Synthesis of Core-Shell Dye Represented by Chemical Formula 25

A compound represented by Chemical Formula 25 was synthesized in the same manner as in Synthesis Example 7 except that a compound of 2-(((2-((2,6-bis(chlorocarbonyl)pyridin-4-yl)oxy)ethoxy)carbonyl)amino)ethyl methacrylate was used instead of the compound of 4-(oxiran-2-ylmethoxy)pyridine-2,6-dicarbonyl dichloride.

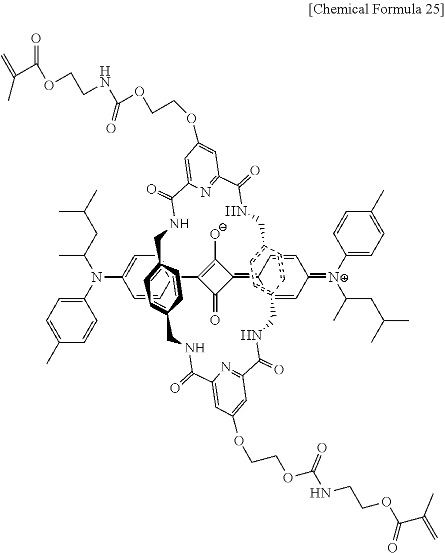

### Synthesis Example 11: Synthesis of Core-Shell Dye Represented by Chemical Formula 26

A compound represented by Chemical Formula 26 was synthesized in the same manner as in Synthesis Example 7 except that a compound of 2-(((2-((2,6-bis(chlorocarbonyl)pyridin-4-yl)oxy)ethoxy)carbonyl)amino)ethyl methacrylate was used instead of the compound of 4-(oxiran-2-ylmethoxy)pyridine-2,6-dicarbonyl dichloride, and the compound represented by Chemical Formula 1-2 was used instead of the compound represented by Chemical Formula 1-1.

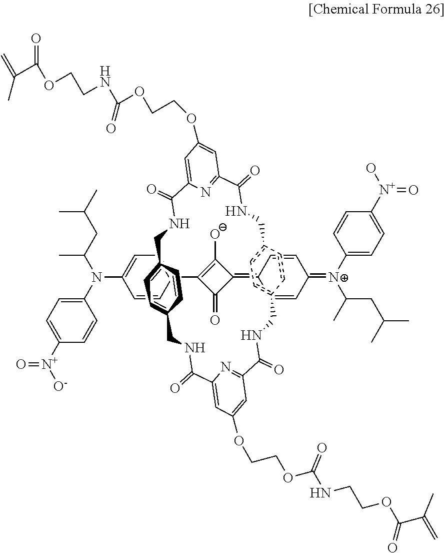

### Synthesis Example 12: Synthesis of Core-Shell Dye Represented by Chemical Formula 27

A compound represented by Chemical Formula 27 was synthesized in the same manner as in Synthesis Example 7 except that a compound of 2-(((2-((2,6-bis(chlorocarbonyl)pyridin-4-yl)oxy)ethoxy)carbonyl)amino)ethyl methacrylate was used instead of the compound of 4-(oxiran-2-ylmethoxy)pyridine-2,6-dicarbonyl dichloride, and the compound represented by Chemical Formula 1-3 was used instead of the compound represented by Chemical Formula 1-1.

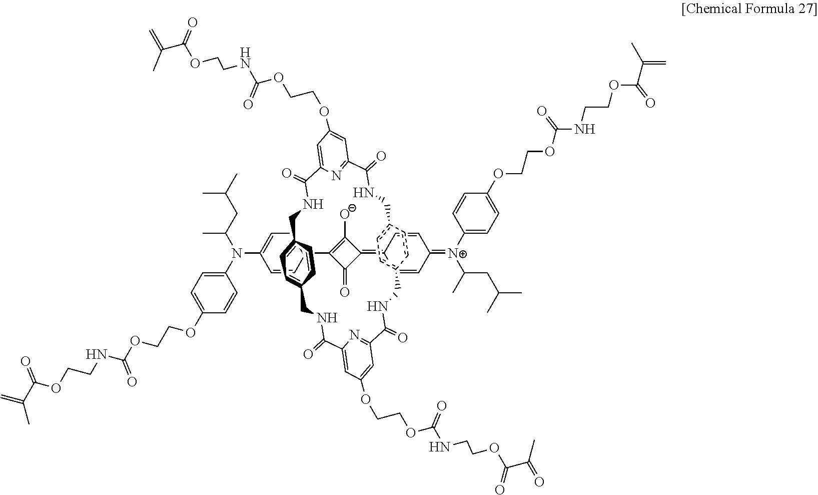

### Synthesis Example 13: Synthesis of Core-Shell Dye Represented by Chemical Formula 50

A compound represented by Chemical Formula 50 was synthesized in the same manner as in Synthesis Example 7 except that the compound represented by Chemical Formula 2-1 was used instead of the compound represented by Chemical Formula 1-1.

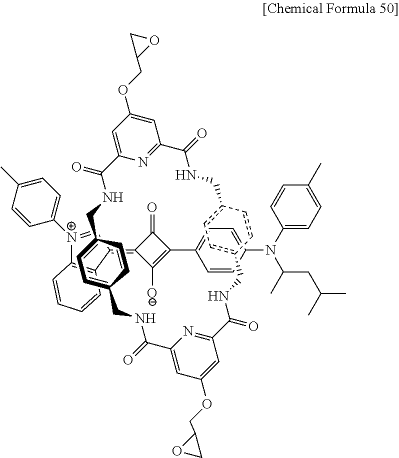

### Synthesis Example 14: Synthesis of Core-Shell Dye Represented by Chemical Formula 54

A compound represented by Chemical Formula 54 was synthesized in the same manner as in Synthesis Example 7 except that a compound of 2-(((2-((2,6-bis(chlorocarbonyl)pyridin-4-yl)oxy)ethoxy)carbonyl)amino)ethyl methacrylate was used instead of the compound of 4-(oxiran-2-ylmethoxy)pyridine-2,6-dicarbonyl dichloride, and the compound represented by Chemical Formula 2-1 was used instead of the compound represented by Chemical Formula 1-1.

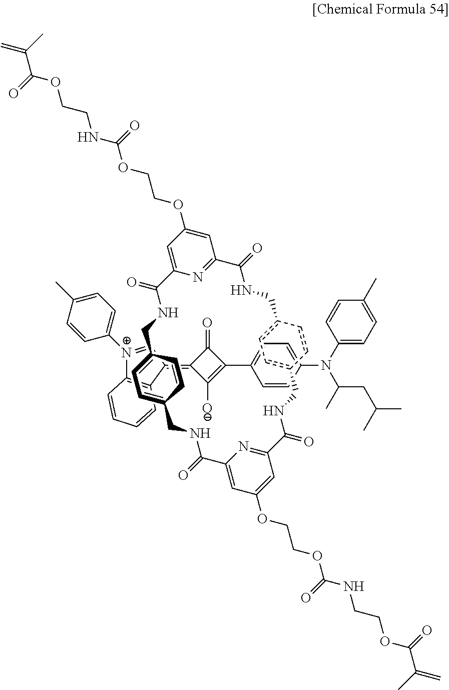

### Comparative Synthesis Example 1: Synthesis of Symmetric Structured Core-Shell Dye

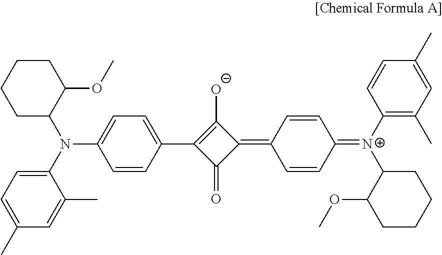 [SMILES: COC1CCCCC1N(c1ccc(C2=C([O-])C(=C3C=CC(=[N+](c4ccc(C)cc4C)C4CCCCC4OC)C=C3)C2=O)cc1)c1ccc(C)cc1C]

A compound represented by Chemical Formula A was synthesized in the same manner as the last step of Synthesis Example 1 except that N-(2-methoxycyclohexyl)-2,4-dimethyl-N-phenylaniline was used instead of Intermediate A-2. A core-shell dye of Comparative Synthesis Example 1 was synthesized in the same manner as in Synthesis Example 5 except that the compound represented by Chemical Formula A was used instead of the compound represented by Chemical Formula 1-2.

### Comparative Synthesis Example 2: Synthesis of Symmetric Structured Core-Shell Dye

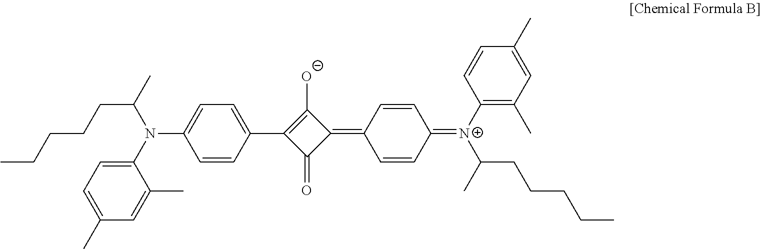 [SMILES: CCCCCC(C)N(c1ccc(C2=C([O-])C(=C3C=CC(=[N+](c4ccc(C)cc4C)C(C)CCCCC)C=C3)C2=O)cc1)c1ccc(C)cc1C]

A compound represented by Chemical Formula B was synthesized in the same manner as in the last step of Synthesis Example 1 except that N-(heptan-2-yl)-2,4-dimethyl-N-phenylaniline was used instead of Intermediate A-2. A core-shell dye of Comparative Synthesis Example 2 was synthesized in the same manner as in Synthesis Example 5 except that the compound represented by Chemical Formula B was used instead of the compound represented by Chemical Formula 1-2.

### Comparative Synthesis Example 3: Synthesis of Asymmetric Structured Core-Shell Dye

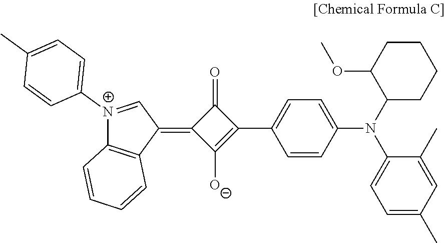

A compound represented by Chemical Formula C was synthesized in the same manner as in Synthesis Example 4 except that N-(2-methoxycyclohexyl)-2,4-dimethyl-N-phenylaniline instead of Intermediate A-2 was reacted with Intermediate B-2. A core-shell dye of Comparative Synthesis Example 3 was synthesized in the same manner as in Synthesis Example 5 except that the compound represented by Chemical Formula C was used instead of the compound represented by Chemical Formula 1-2.

### Comparative Synthesis Example 4: Synthesis of Asymmetric Structured Core-Shell Dye

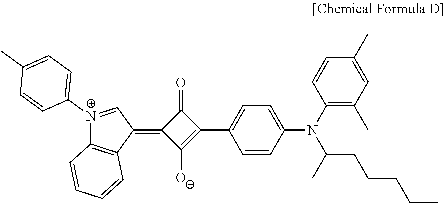 [SMILES: CCCCCC(C)N(c1ccc(C2=C([O-])/C(=C3/C=[N+](c4ccc(C)cc4)c4ccccc43)C2=O)cc1)c1ccc(C)cc1C]

A compound represented by Chemical Formula D was synthesized in the same manner as in Synthesis Example 4 except that N-(heptan-2-yl)-2,4-dimethyl-N-phenylaniline instead of Intermediate A-2 was reacted with Intermediate B-2. A core-shell dye of Comparative Synthesis Example 4 was synthesized in the same manner as in Synthesis Example 5 except that the compound represented by Chemical Formula D was used instead of the compound represented by Chemical Formula 1-2.

### Evaluation

### Evaluation 1: Fluorescence Quantum Efficiency

The core-shell dyes according to Synthesis Examples 5 to 14 and Comparative Synthesis Examples 1 to 4 in an amount of 4 mg to 7 mg according to each molecular weight were respectively added to 3 mL to 6 mL of a cyclohexanone solution and diluted therein to prepare 2.5×10−7 mol/L of a dye solution, wherein the solution was diluted to have UV intensity (abs) of less than 0.1 au. Subsequently, each diluted solution was measured with respect to fluorescence quantum efficiency by using Quantaurus-QY C11347 (HAMAMATSU Photonics K.K.) at room temperature, and the results are shown in Table 1. The Quantaurus-QY C11347 equipment used a 150 W Xenon lamp as a light source, and a maximum absorption wavelength of each sample was set to be an excitation wavelength (a full width at half maximum (FWHM) of 10 nm or less).

TABLE 1
(unit: %)

| | Fluorescence quantum efficiency |
|---|---|
| Synthesis Example 5 | 5 |
| Synthesis Example 6 | 4 |
| Synthesis Example 7 | 5 |
| Synthesis Example 8 | 5 |
| Synthesis Example 9 | 4 |
| Synthesis Example 10 | 2 |
| Synthesis Example 11 | 3 |
| Synthesis Example 12 | 4 |
| Synthesis Example 13 | 37 |
| Synthesis Example 14 | 32 |
| Comparative Synthesis Example 1 | 71 |
| Comparative Synthesis Example 2 | 58 |
| Comparative Synthesis Example 3 | 95 |
| Comparative Synthesis Example 4 | 90 |

Referring to Table 1, the symmetrical core-shell dyes according to Synthesis Examples 5 to 12 exhibited fluorescent quantum efficiency, which was measured under the aforementioned conditions, in a range of 5% or less, but the core-shell dyes of Comparative Synthesis Examples 1 and 2 exhibited much higher fluorescence quantum efficiency. The asymmetric core-shell dyes of Synthesis Examples 13 and 14 exhibited greater than or equal to 30% higher fluorescence quantum efficiency, which were measured under the aforementioned conditions, than the symmetric core-shell dyes but about ⅓ reduced fluorescence quantum efficiency y, compared with the asymmetric core-shell dyes of Comparison Synthesis Examples 3 and 4. Accordingly, the symmetric core-shell dyes of Synthesis Example 5 to 12 (the asymmetric core-shell dyes of Synthesis Examples 13 and 14) exhibited excellent contrast ratio characteristics, when included in a photosensitive resin composition, compared with the symmetric core-shell dyes of Comparative Synthesis Examples 1 and 2 (the asymmetric core-shell dyes of Comparative Synthesis Examples 3 and 4).

### Evaluation 2: Molar Extinction Coefficient

The core-shell dyes according to Synthesis Examples 5 to 14 and Comparative Synthesis Examples 1 to 4 were respectively diluted in a dilution solvent (cyclohexanone) at a concentration of 0.001 wt % and then, measured with respect to a maximum absorption wavelength of a UV-Vis. Spectrum at room temperature by using UV-1800 (SHIMADZU Co., Ltd.) equipment, which was used to calculate a molar extinction coefficient, and the results are shown in Table 2.

TABLE 2
(unit: M⁻¹ · cm⁻¹)

| | Molar extinction coefficient |
|---|---|
| Synthesis Example 5 | 3.10 × 10⁵ |
| Synthesis Example 6 | 3.12 × 10⁵ |
| Synthesis Example 7 | 3.11 × 10⁵ |
| Synthesis Example 8 | 3.15 × 10⁵ |
| Synthesis Example 9 | 3.14 × 10⁵ |
| Synthesis Example 10 | 3.11 × 10⁵ |
| Synthesis Example 11 | 3.21 × 10⁵ |
| Synthesis Example 12 | 3.13 × 10⁵ |
| Synthesis Example 13 | 2.15 × 10⁵ |
| Synthesis Example 14 | 2.10 × 10⁵ |
| Comparative Synthesis Example 1 | 2.87 × 10⁵ |
| Comparative Synthesis Example 2 | 2.83 × 10⁵ |
| Comparative Synthesis Example 3 | 2.01 × 10⁵ |
| Comparative Synthesis Example 4 | 2.00 × 10⁵ |

Referring to Table 2, the symmetric core-shell dyes of Synthesis Examples 5 to 12 exhibited a molar extinction coefficient, which were measured under the aforementioned conditions, in a range of 3.10×10⁵ M⁻¹·cm⁻¹ or more, and the core-shell dyes of Comparative Synthesis Examples 1 and 2 exhibited 8% or more increased molar extinction coefficient. The asymmetric core-shell dyes of Synthesis Examples 13 and 14 exhibited a molar extinction coefficient, which were measured under the aforementioned conditions, in a range of 2.10×10⁵ M⁻¹·cm⁻¹ or more, and the asymmetric core-shell dyes of Comparative Synthesis Examples 3 and 4 exhibited 5% or more increased molar extinction coefficient.

### (Preparation of Photosensitive Resin Compositions)

Photosensitive resin compositions were prepared using the following components.

### (A) Dye

(A-1) Core-shell dye prepared in Synthesis Example 9 (represented by Chemical Formula 24)
(A-2) Core-shell dye prepared in Synthesis Example 10 (represented by Chemical Formula 25)
(A-3) Core-shell dye prepared in Synthesis Example 11 (represented by Chemical Formula 26)
(A-4) Core-shell dye prepared in Synthesis Example 12 (represented by Chemical Formula 27)
(A-5) Core-shell dye prepared in Comparative Synthesis Example 1 (represented by Chemical Formula A)

### (B) Binder Resin

A methacrylic acid/benzylmethacrylate copolymer having a weight average molecular weight of 22,000 g/mol (a mixing weight ratio: 15 wt %/85 wt %)

### (C) Photopolymerizable Monomer

dipentaerythritolhexaacrylate

### (D) Photopolymerization Initiator

(D-1) 1,2-octandione
(D-2) 2-dimethylamino-2-(4-methyl-benzyl)-1-(4-morpholin-4-yl-phenyl)-butan-1-one

### (E) Solvent

(E-1) Cyclohexanone
(E-2) Propylene glycol monomethylether acetate (PGMEA)

### Example 1 to Example 4 and Comparative Example 1

Photosensitive resin compositions were prepared by mixing each component in the compositions shown in Table 3. Specifically, the photopolymerization initiator was dissolved in a solvent, the solution was stirred at room temperature for 2 hours, the dye (or pigment dispersion) was added thereto, the mixture was stirred for 30 minutes, the binder resin and the photopolymerizable monomer were added thereto, and the obtained mixture was stirred at room temperature for 2 hours. The solution was three times filtered to remove impurities and prepare a photosensitive resin composition.

TABLE 3
(unit: wt %)

| | | Example | Example | Example | Example | Comparative |
|---|---|---|---|---|---|---|
| | | 1 | 2 | 3 | 4 | Example 1 |
| (A) Dye | A-1 | 2 | — | — | — | — |
| | A-2 | — | 2 | — | — | — |
| | A-3 | — | — | 2 | — | — |
| | A-4 | — | — | — | 2 | — |
| | A-5 | — | — | — | — | 2 |
| (B) Binder resin | | 3.5 | 3.5 | 3.5 | 3.5 | 3.5 |
| (C) Photopolymerizable monomer | | 8 | 8 | 8 | 8 | 8 |
| (D) Photopolymerization | D-1 | 1 | 1 | 1 | 1 | 1 |
| initiator | D-2 | 0.5 | 0.5 | 0.5 | 0.5 | 0.5 |
| (E) Solvent | E-1 | 40 | 40 | 40 | 40 | 40 |
| | E-2 | 45 | 45 | 45 | 45 | 45 |

| | | | | | |
|---|---|---|---|---|---|
| Total | 100 | 100 | 100 | 100 | 100 |

### Evaluation 3: Contrast Ratio of Photosensitive Coloring Resin Composition

The photosensitive resin compositions prepared using each core-shell dye according to Synthesis Examples 9 to 12 and Comparative Synthesis Example 1 were respectively coated to be 1 μm to 3 μm thick on a 1 mm-thick degreased glass substrate and dried on a 90° C. hot plate for 2 minutes to form films. Subsequently, the films were exposed to light with a high-pressure mercury lamp having a main wavelength of 365 nm and dried in forced convection drying furnace of a 200° C. oven for 5 minutes. Contrast ratios of pixel layers were measured using a spectrophotometer (MCPD3000, Otsuka electronic Co., Ltd.) and the results are shown in Table 4.

TABLE 4
(unit: %)

| | Contrast ratio |
|---|---|
| Example 1 | 116 |
| Example 2 | 129 |
| Example 3 | 122 |
| Example 4 | 121 |
| Comparative Example 1 | 100 |

Referring to Table 4, the photosensitive resin composition respectively using the core-shell dyes of Synthesis Examples 9 to 12 (Examples 1 to 4) exhibited about 16% to 29% improved contrast ratio measured under the aforementioned conditions, compared with the photosensitive resin composition using the core shell dye of Comparative Synthesis Example 1 (Comparative Example 1).

While this invention has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims. Therefore, the aforementioned embodiments should be understood to be exemplary but not limiting the present invention in any way.

1. A core-shell dye, comprising
a core including a compound represented by Chemical Formula 1 or Chemical Formula 2 and
a shell surrounding the core: 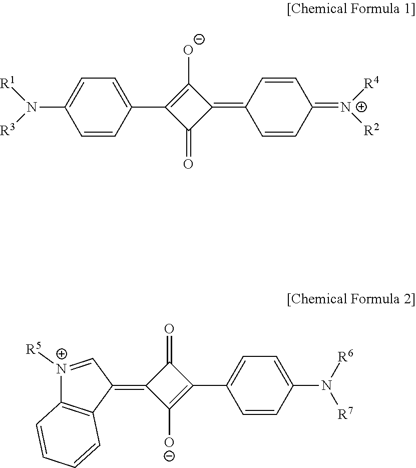
wherein, in Chemical Formula 1 or Chemical Formula 2,
R¹ to R⁷ are each independently a substituted or unsubstituted C1 to C20 alkyl group, a substituted or unsubstituted C3 to C20 cycloalkyl group, a substituted or unsubstituted C6 to C20 aryl group, a substituted or unsubstituted C2 to C20 heteroaryl group, or a combination thereof.

2. The core-shell dye of claim 1, wherein
R¹ to R⁷ are each independently a substituted or unsubstituted C1 to C20 alkyl group or a functional group represented by Chemical Formula 3: 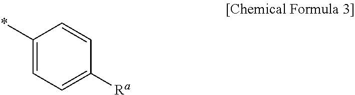
wherein, in Chemical Formula 3,
R^{a} is hydrogen, a substituted or unsubstituted C1 to C20 alkyl group, a substituted or unsubstituted C1 to C20 alkoxy group, a nitro group (—NO₂), a glycidoxy group, a (meth)acrylate group, a carbamate group, or a combination thereof.

3. The core-shell dye of claim 1, wherein
the core-shell dye has a molar extinction coefficient of greater than or equal to 3.1×10⁵ M⁻¹ cm⁻¹ and a fluorescent quantum efficiency of less than or equal to 5%.

4. The core-shell dye of claim 1, wherein
the compound represented by Chemical Formula 1 is represented by any one of Chemical Formula 1-1 to Chemical Formula 1-3 and the compound represented by Chemical Formula 2 is represented by any one of Chemical Formula 2-1 to Chemical Formula 2-4:

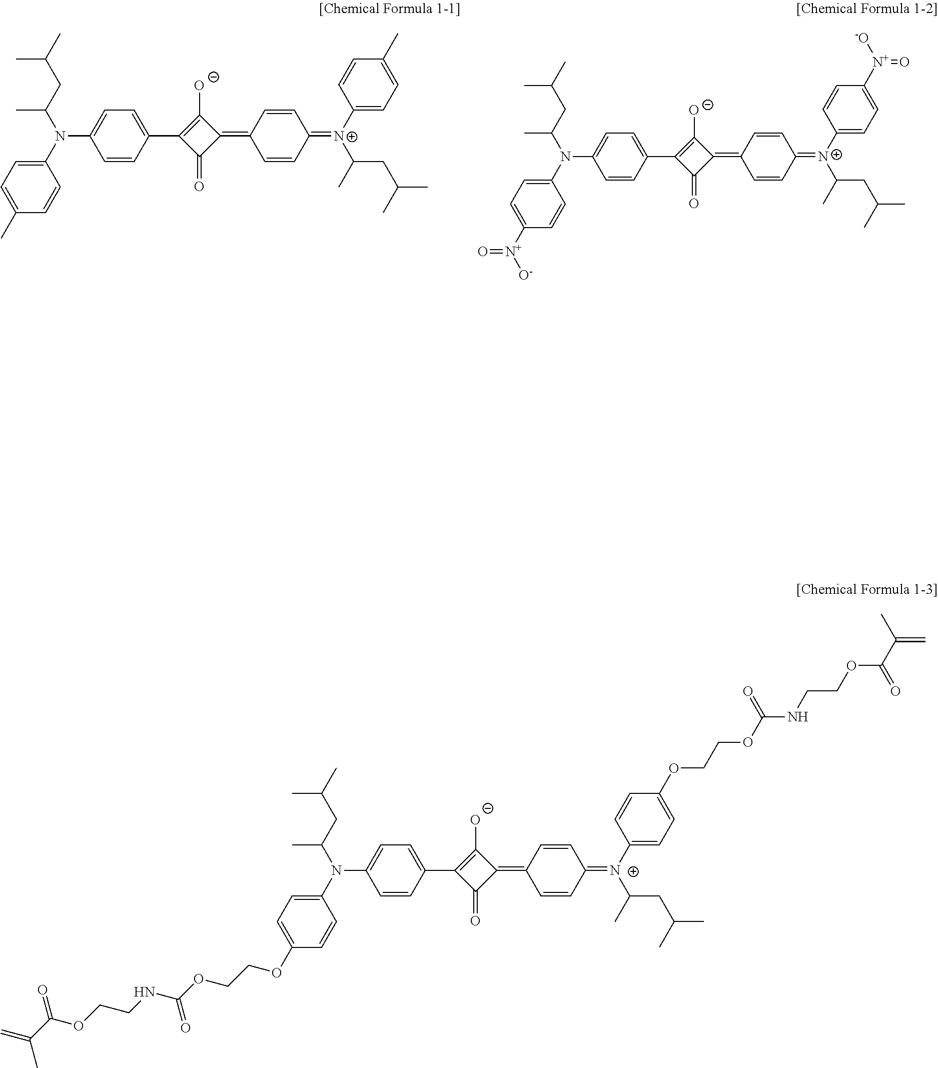

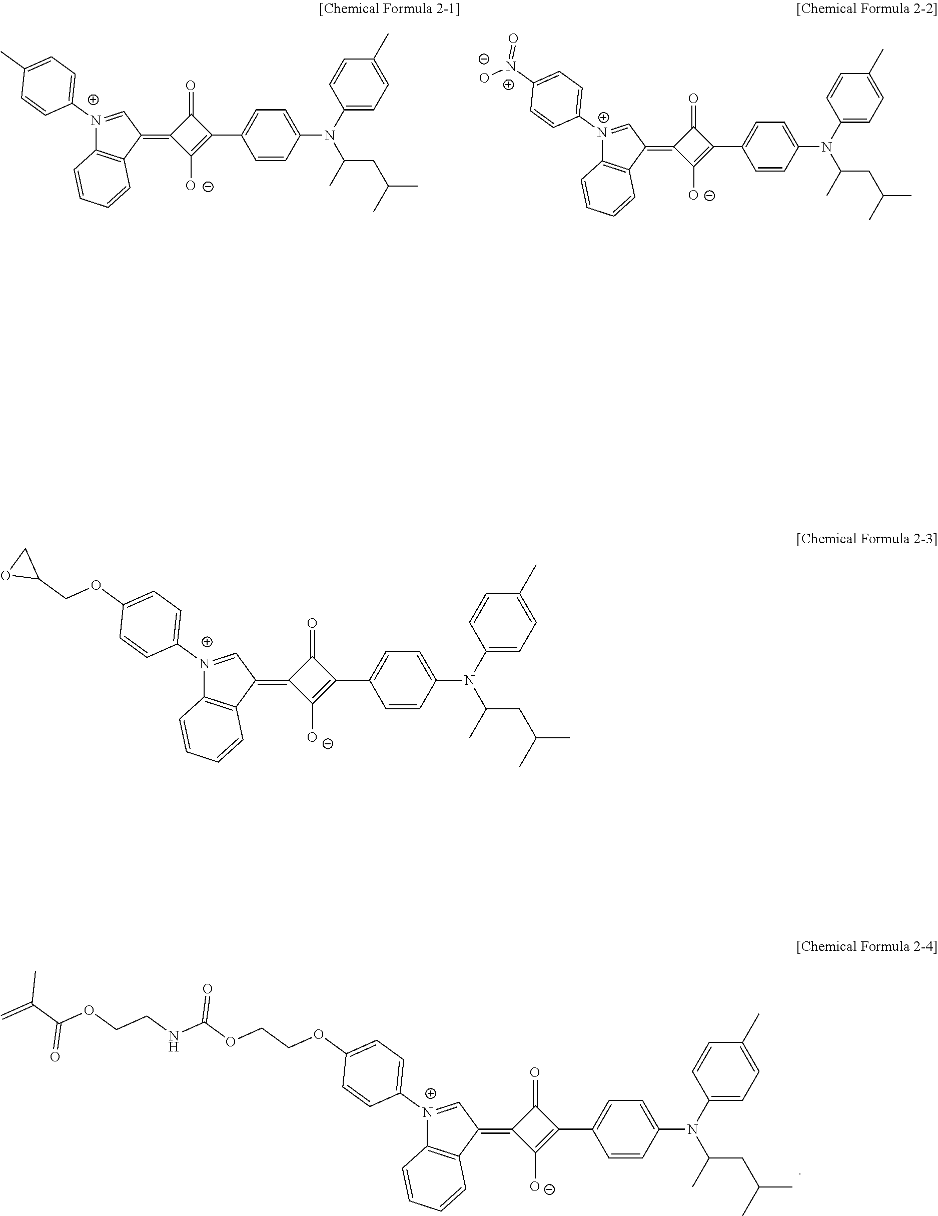

5. The core-shell dye of claim 1, wherein
the shell is represented by Chemical Formula 4 or Chemical Formula 5: 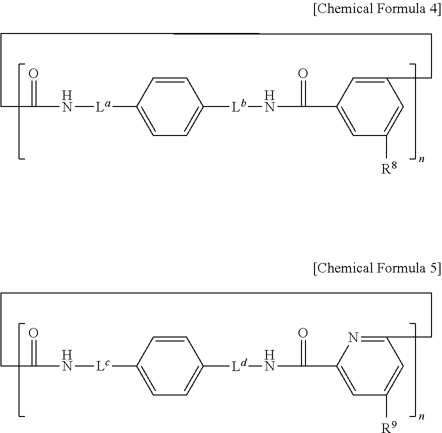
wherein, in Chemical Formula 4 or Chemical Formula 5,
R⁸ and R⁹ are each independently hydrogen, a substituted or unsubstituted C1 to C20 alkyl group, a substituted or unsubstituted C1 to C20 alkoxy group, a nitro group (—NO₂), a glycidoxy group, a (meth)acrylate group, a carbamate group, or a combination thereof,
L^{a} to L^{d} are each independently a single bond, or a substituted or unsubstituted C1 to C10 alkylene group, and
n is an integer from 1 to 4.

6. The core-shell dye of claim 5, wherein
L^{a} to L^{d} are each independently a substituted or unsubstituted C1 to C10 alkylene group.

7. The core-shell dye of claim 5, wherein
the shell is represented by Chemical Formula 4-1 or Chemical Formula 5-1: 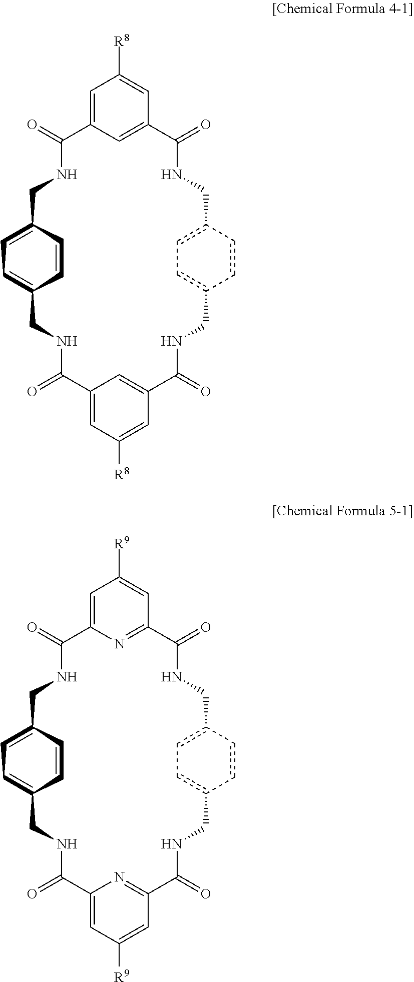
wherein, in Chemical Formulas 4-1 and 5-1,
R⁸ and R⁹ are each independently hydrogen, a substituted or unsubstituted C1 to C20 alkyl group, a substituted or unsubstituted C1 to C20 alkoxy group, a nitro group (—NO₂), a glycidoxy group, a (meth)acrylate group, a carbamate group, or a combination thereof.

8. The core-shell dye of claim 5, wherein
the shell is represented by any one of Chemical Formula 4-a to Chemical Formula 4-d and Chemical Formula 5-a to Chemical Formula 5-d:

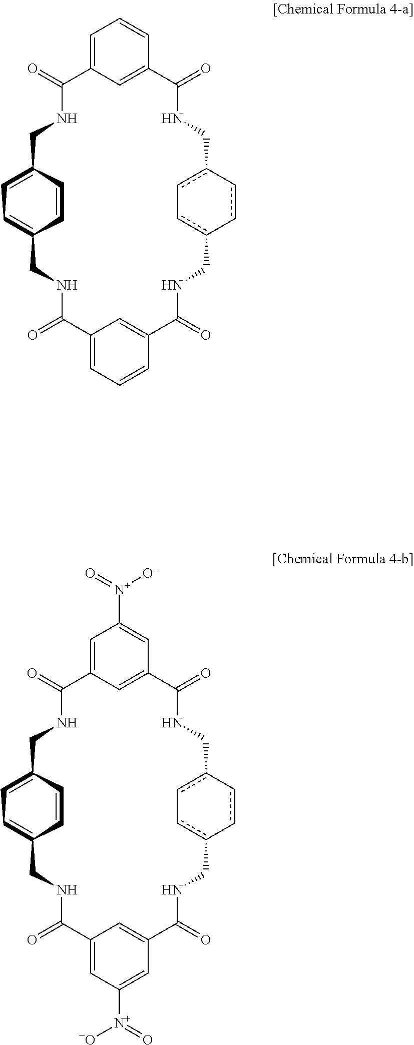

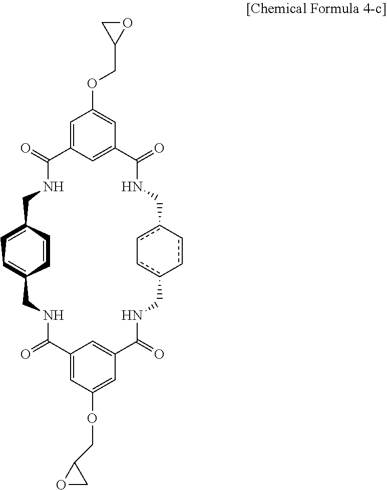

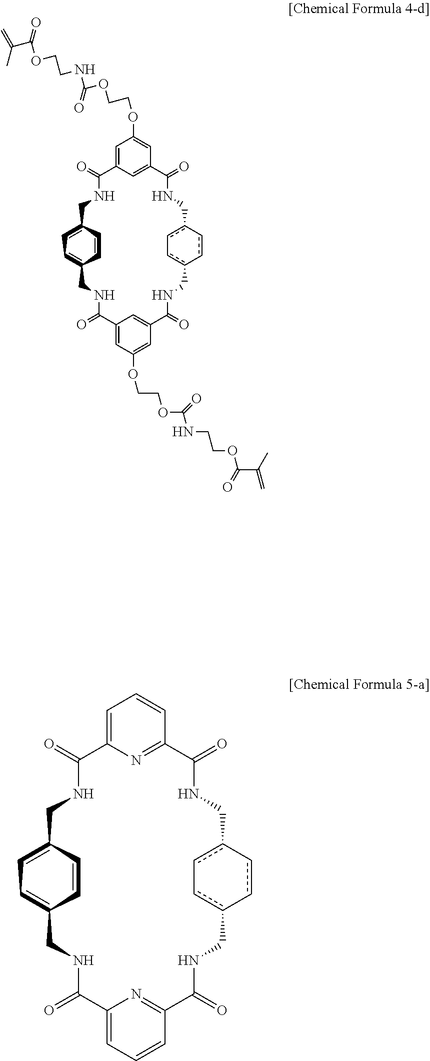

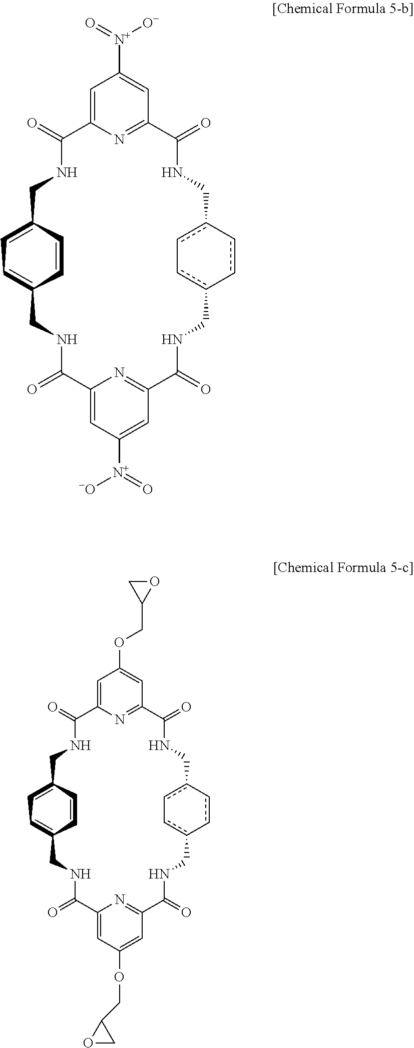

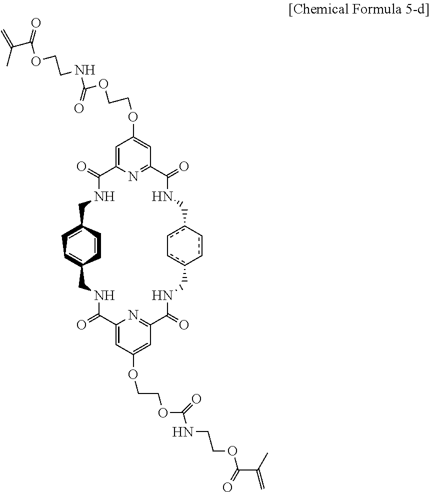

9. The core-shell dye of claim 5, wherein
the shell has a cage width of 6.5 Å to 7.5 Å.

10. The core-shell dye of claim 5, wherein
the core has a length of 1 nm to 3 nm.

11. The core-shell dye of claim 5, wherein
the core has a maximum absorption peak at a wavelength of 590 nm to 670 nm.

12. The core-shell dye of claim 1, wherein
the core-shell dye is represented by any one of the compounds represented by Chemical Formula 6 to Chemical Formula 57:

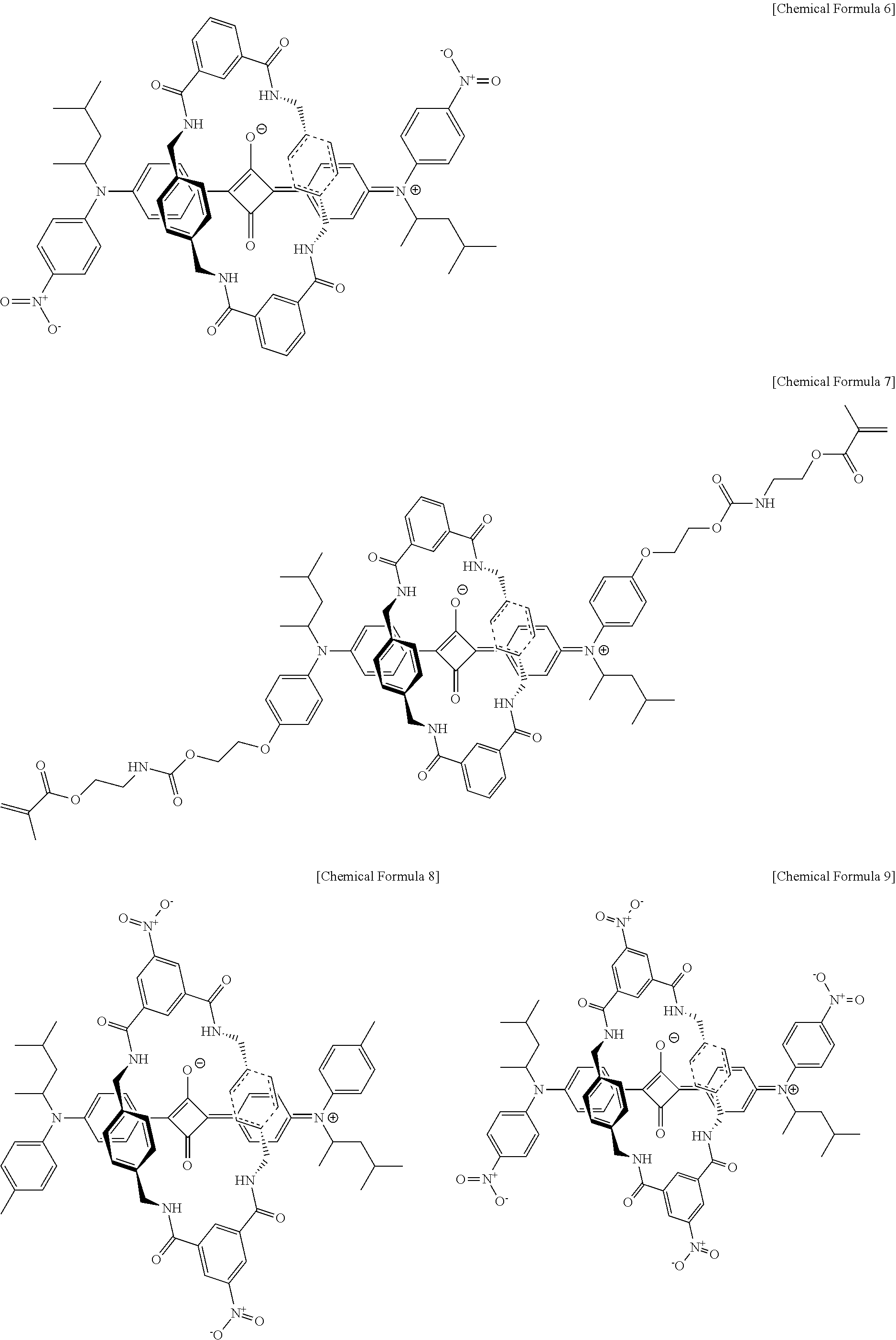

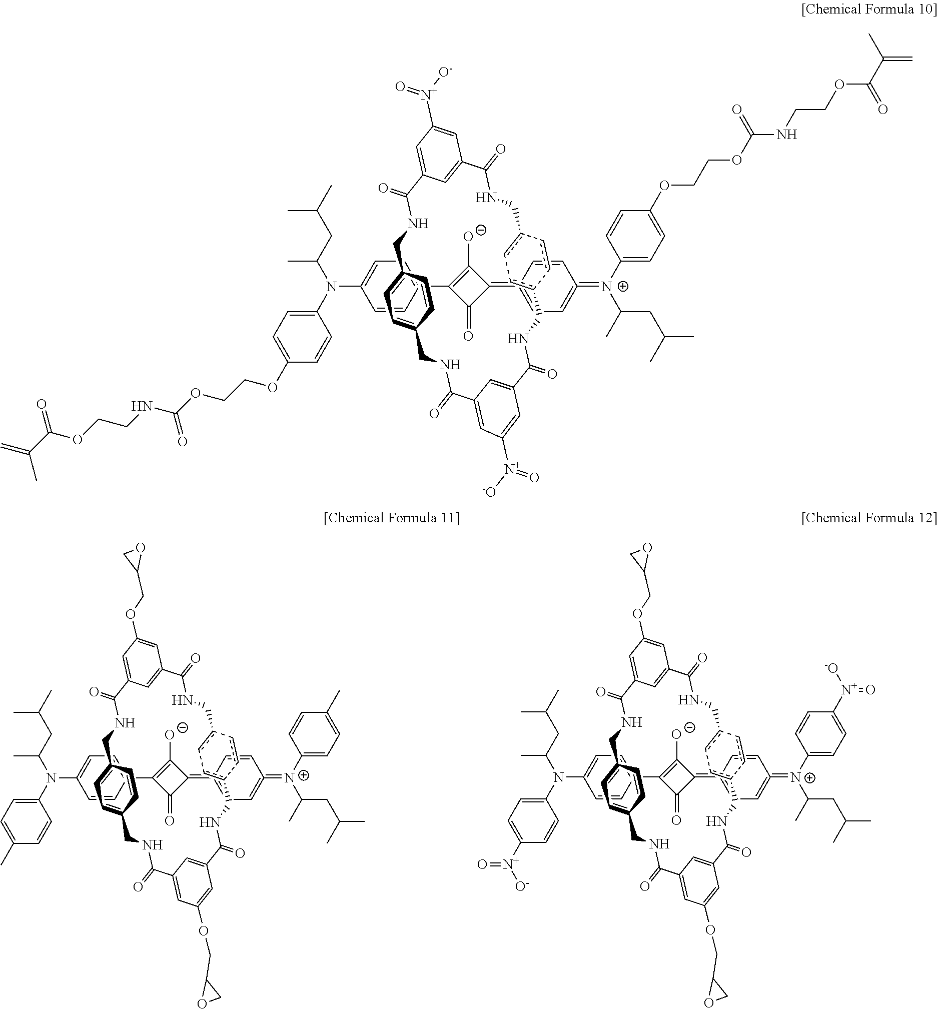

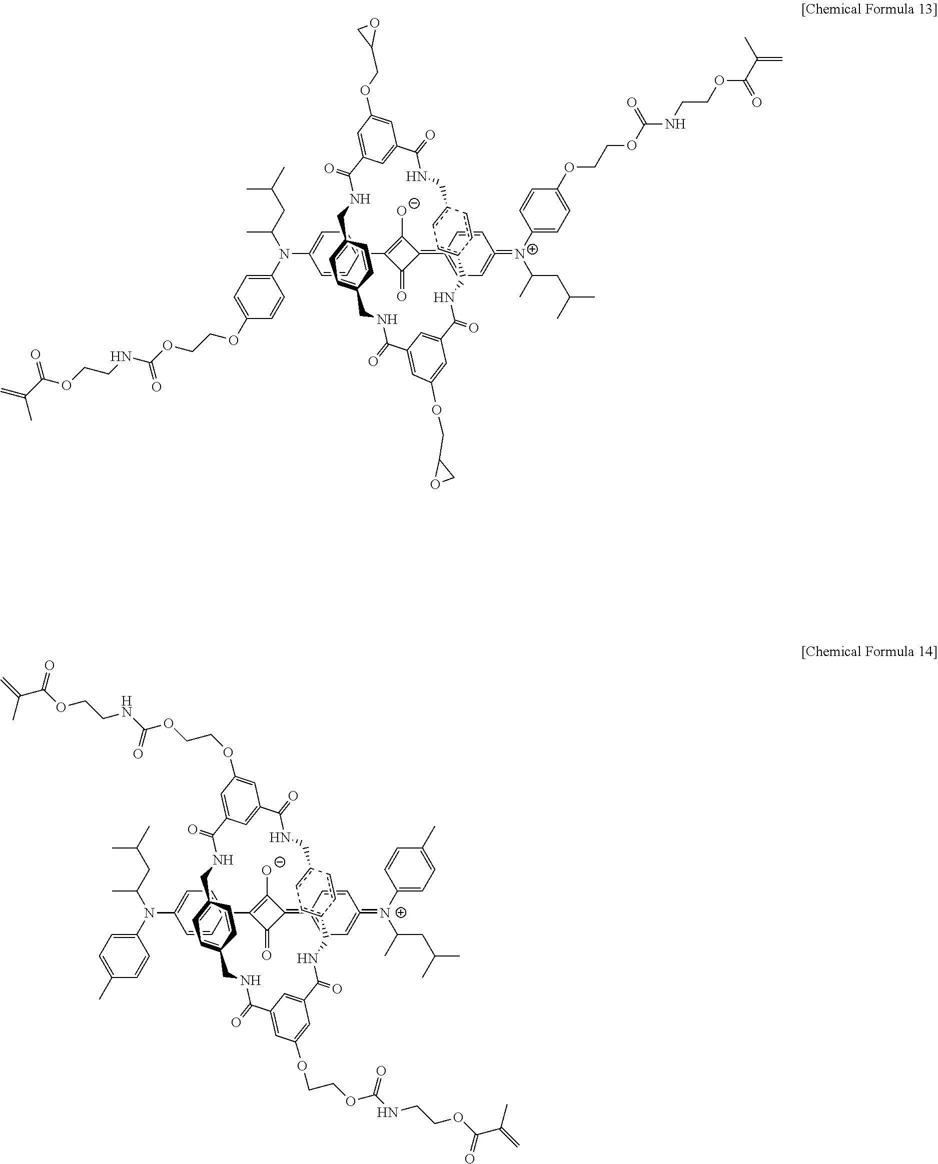

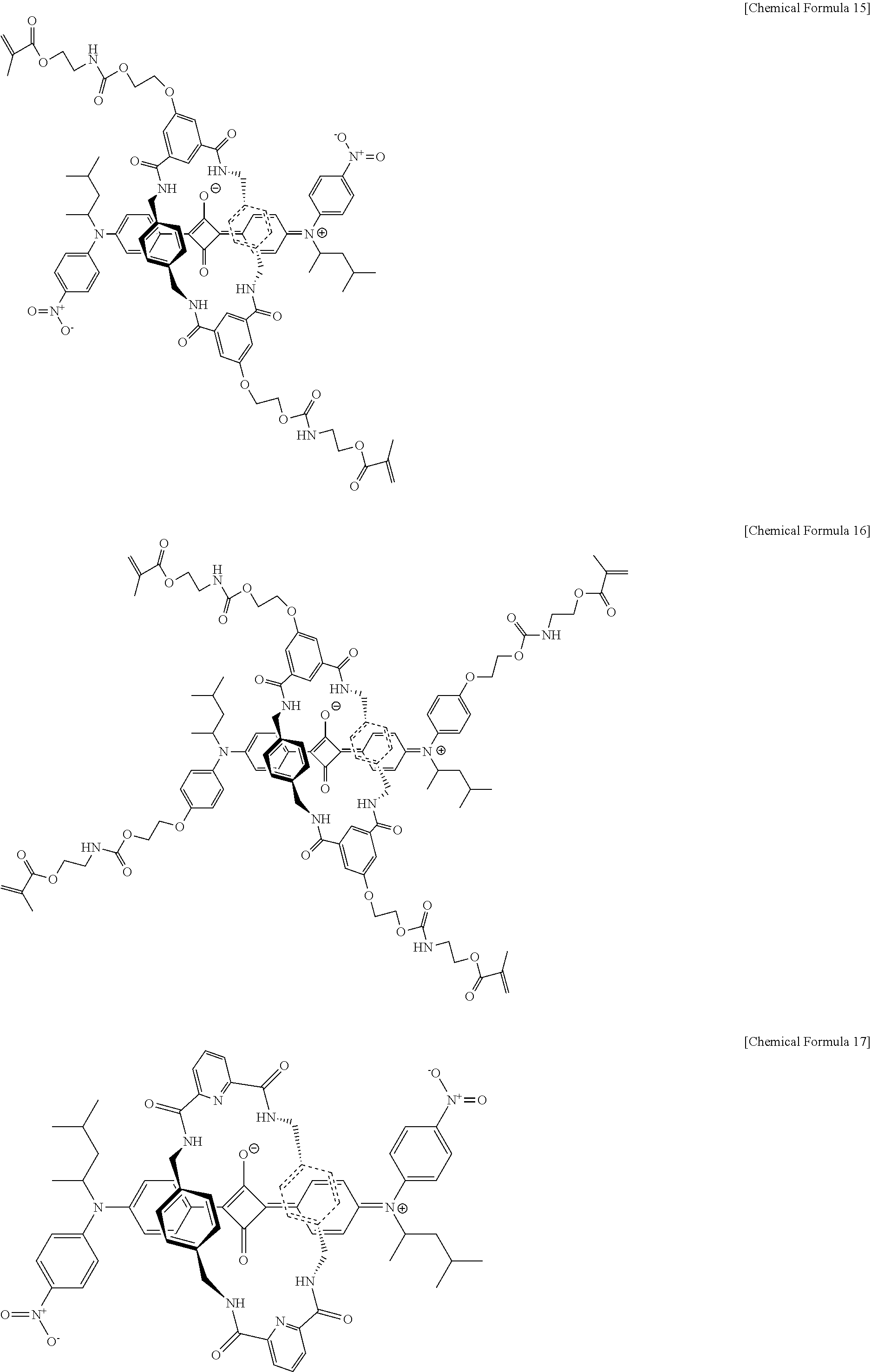

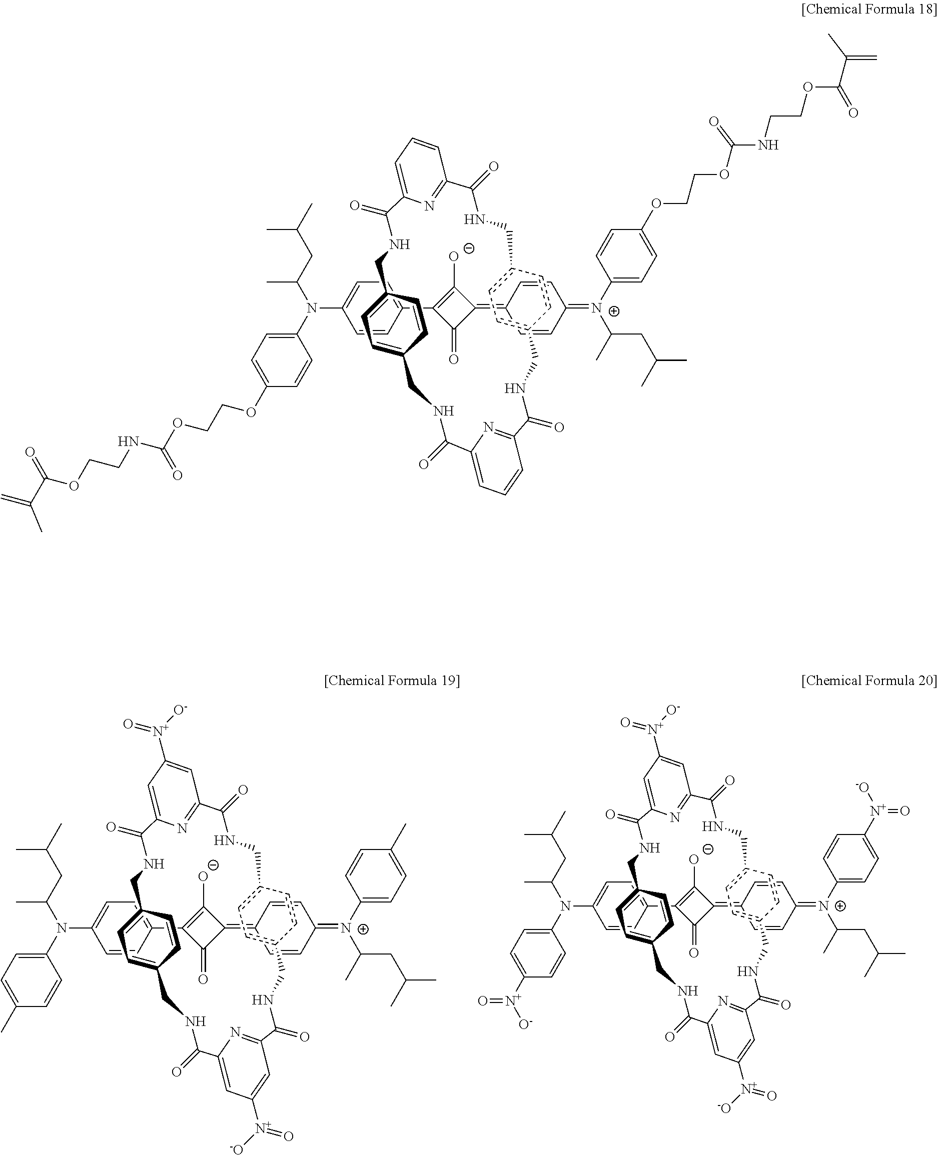

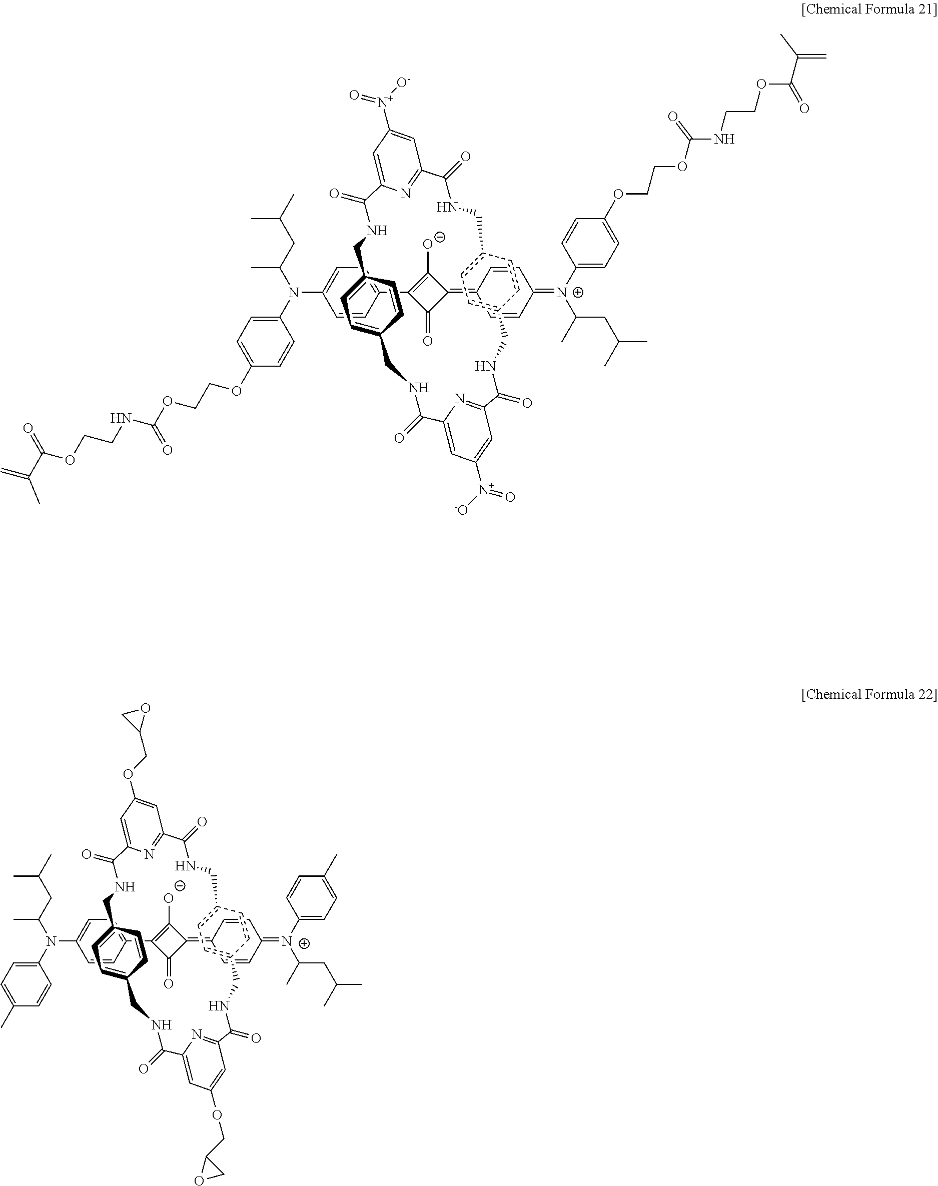

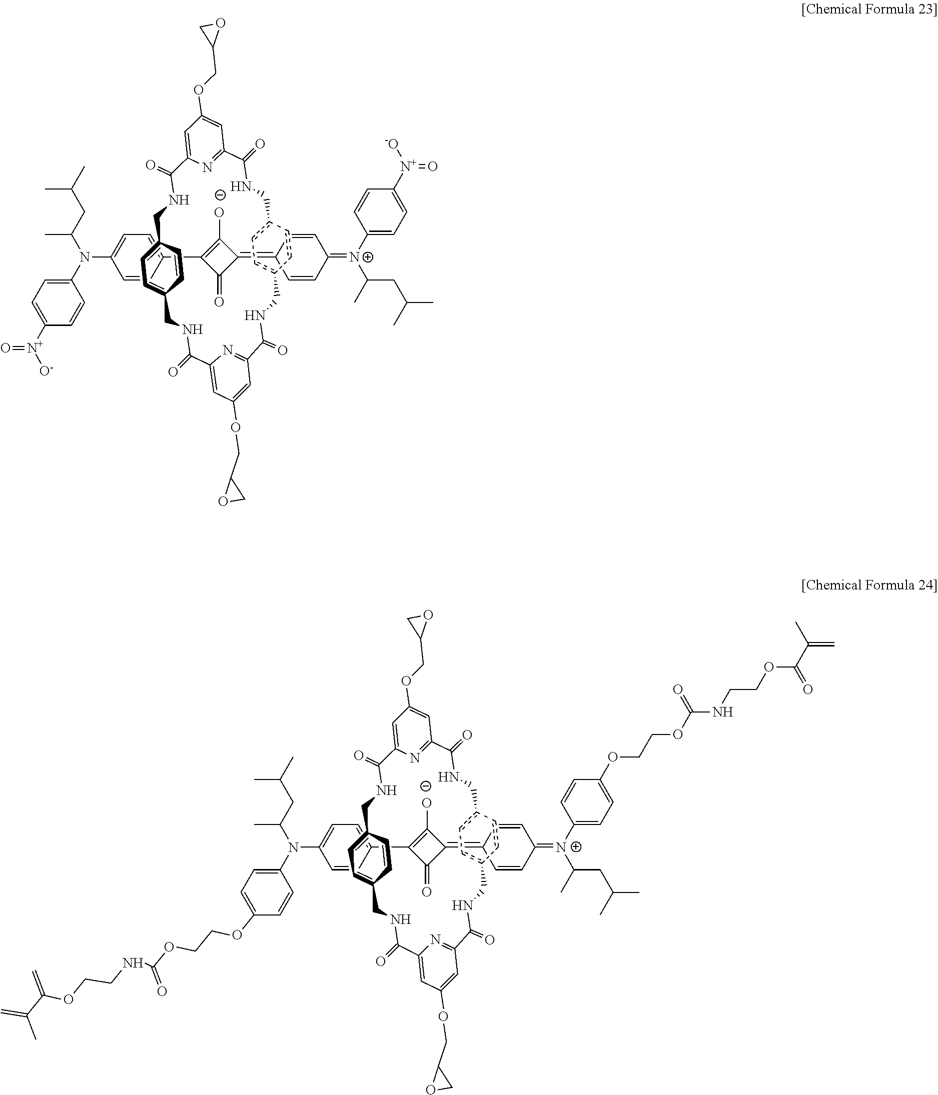

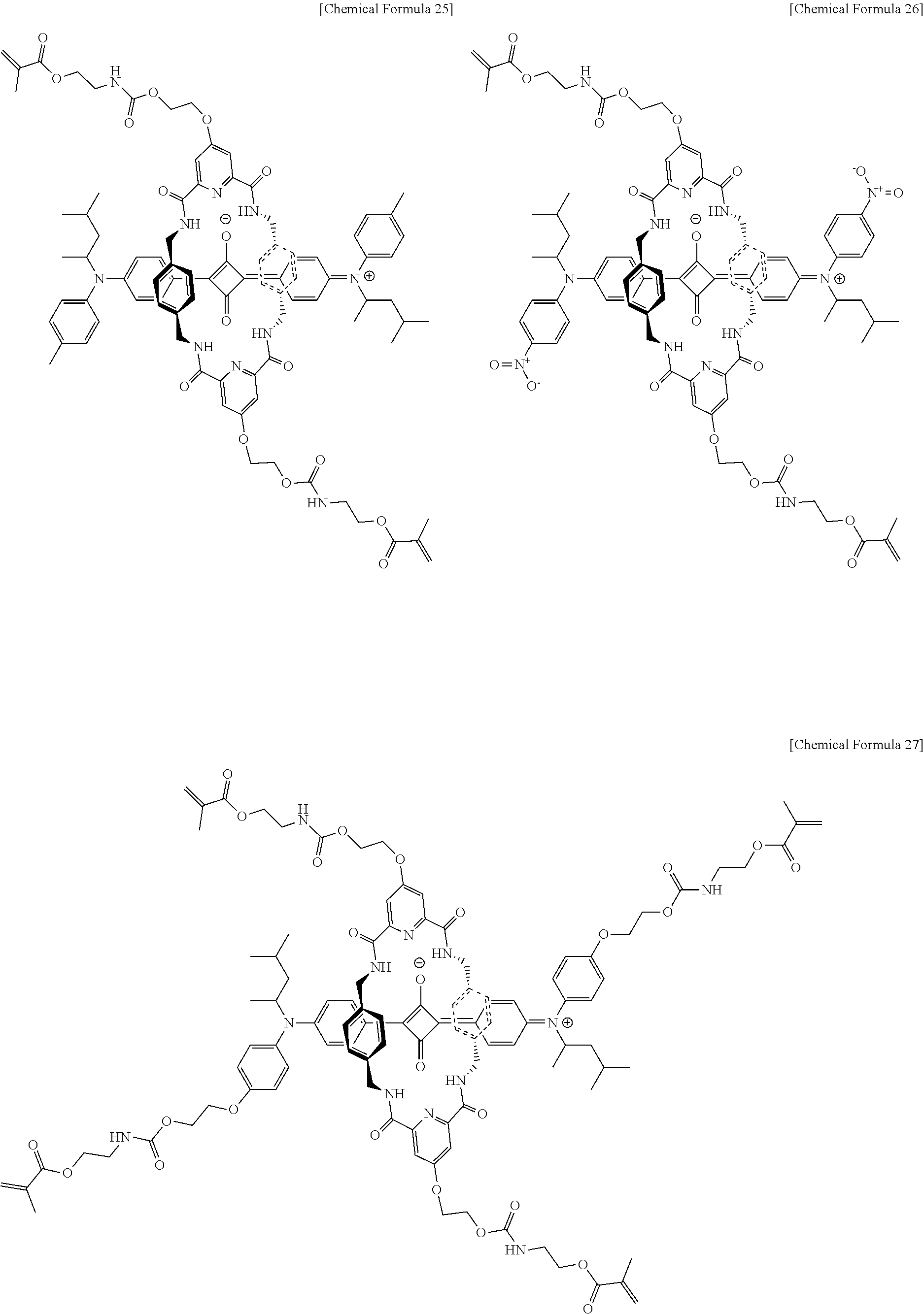

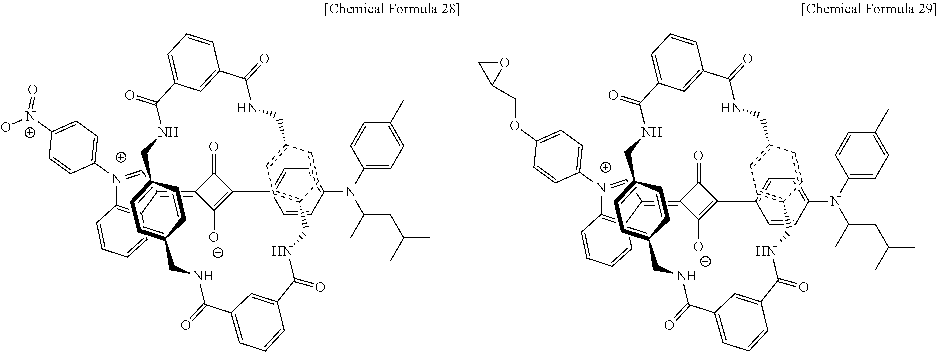

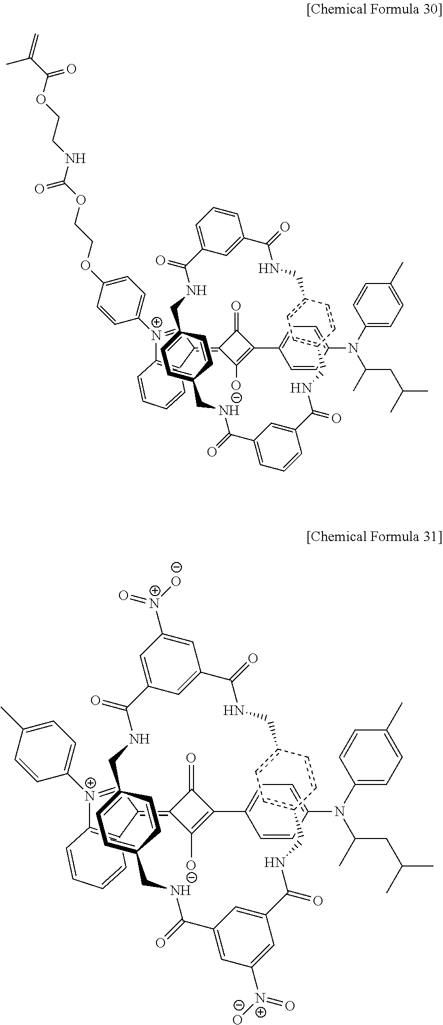

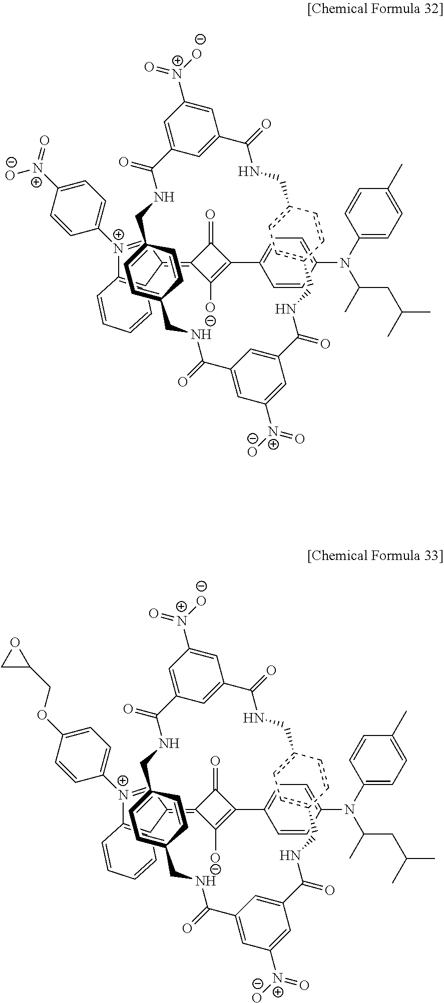

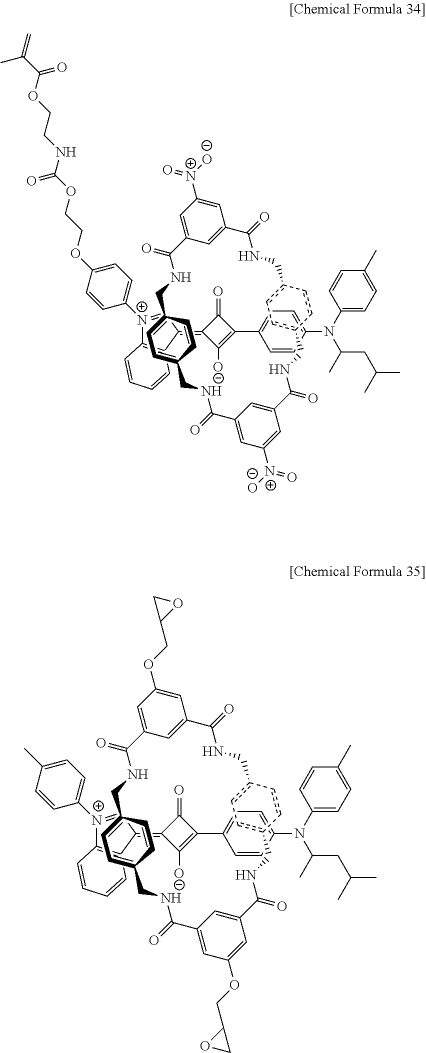

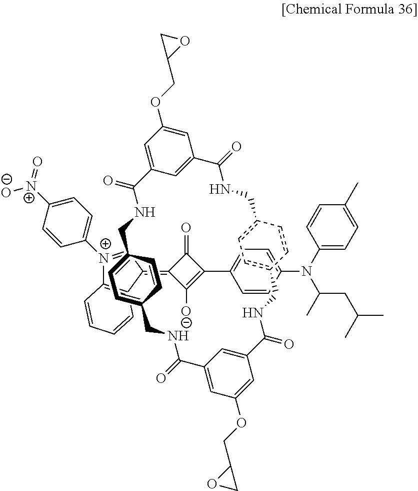

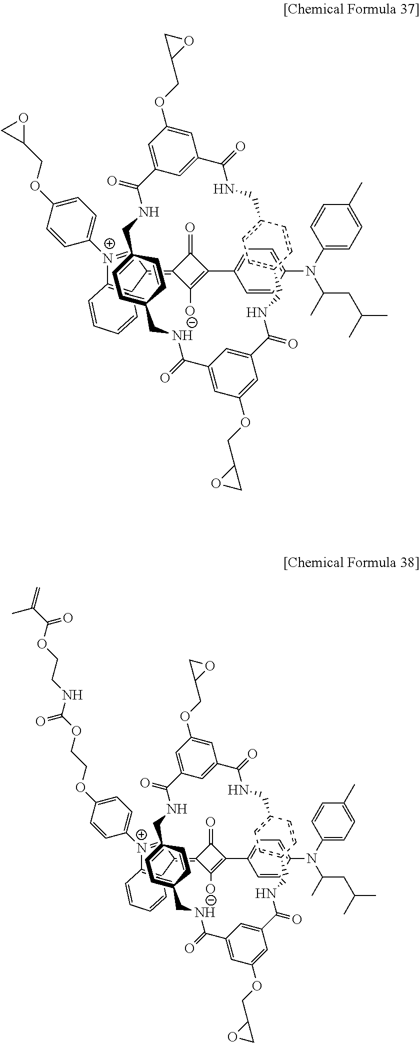

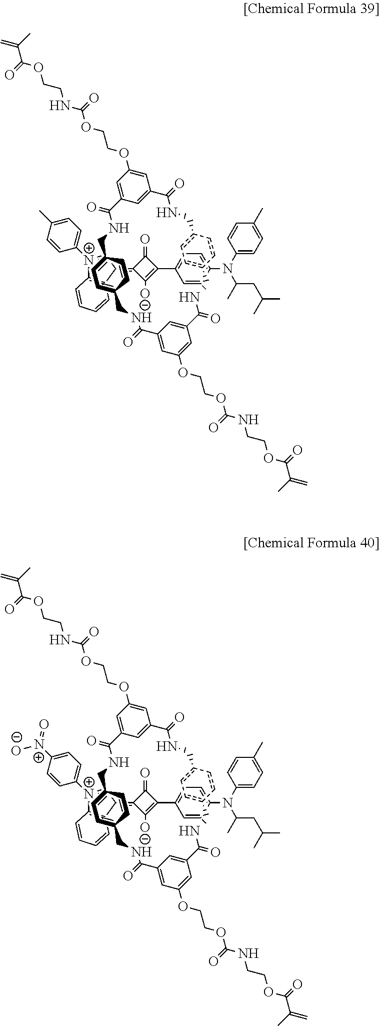

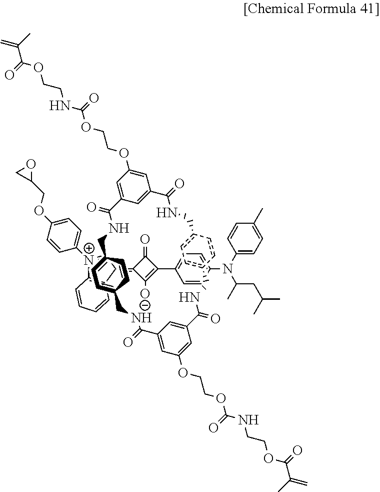

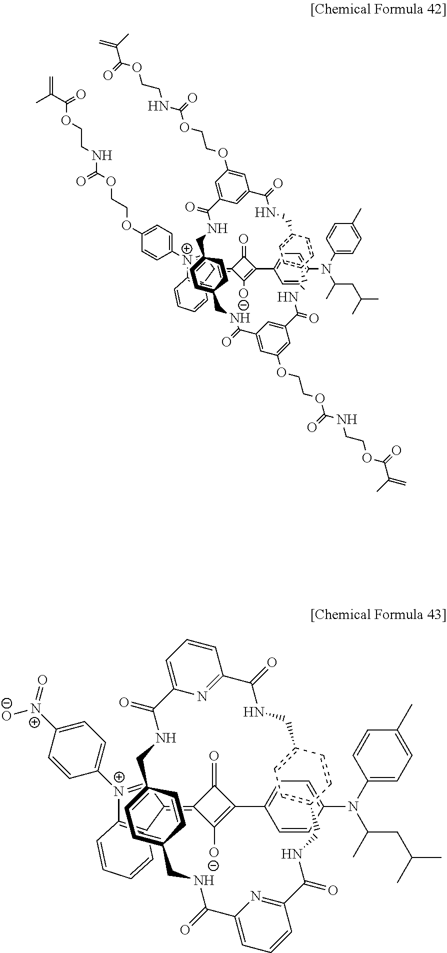

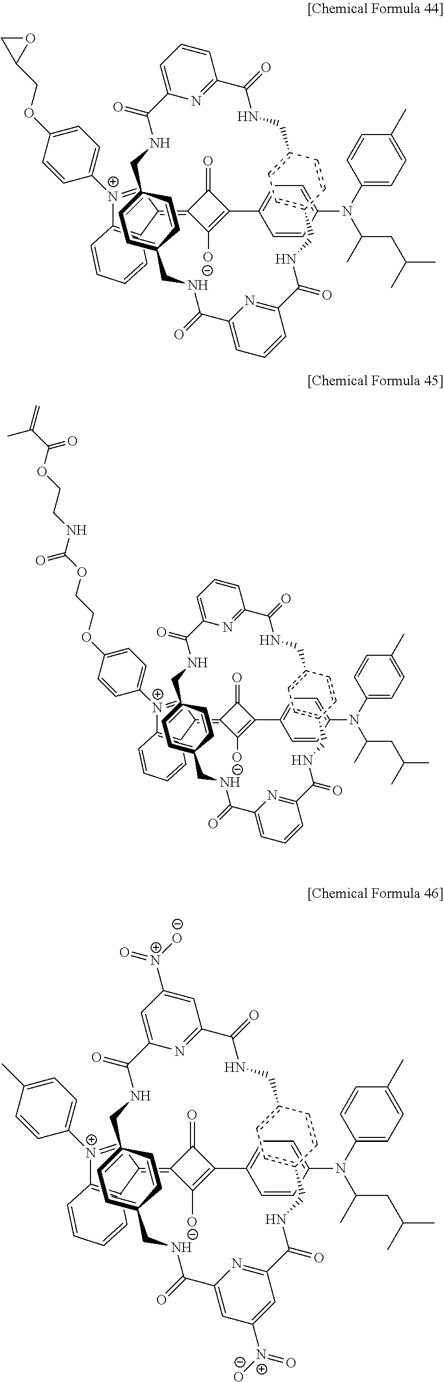

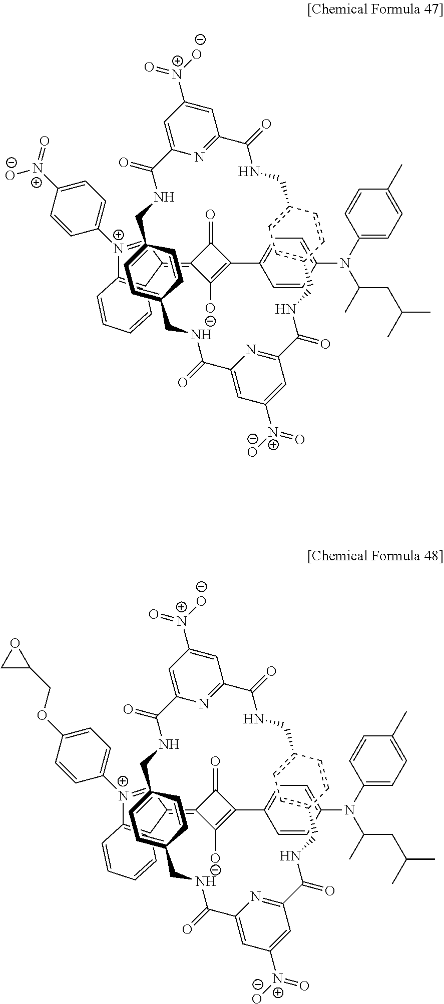

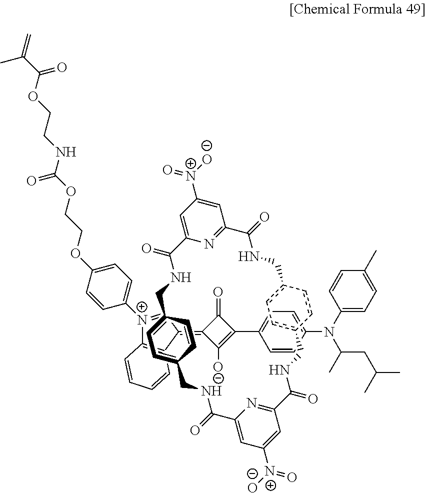

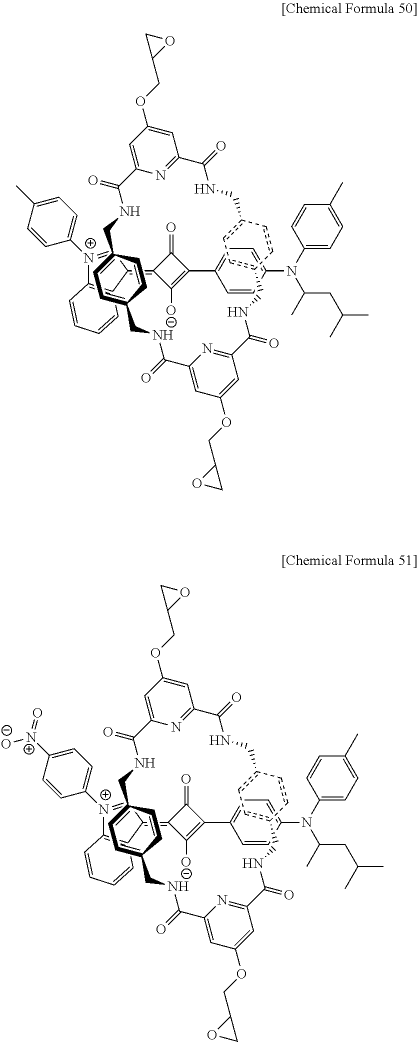

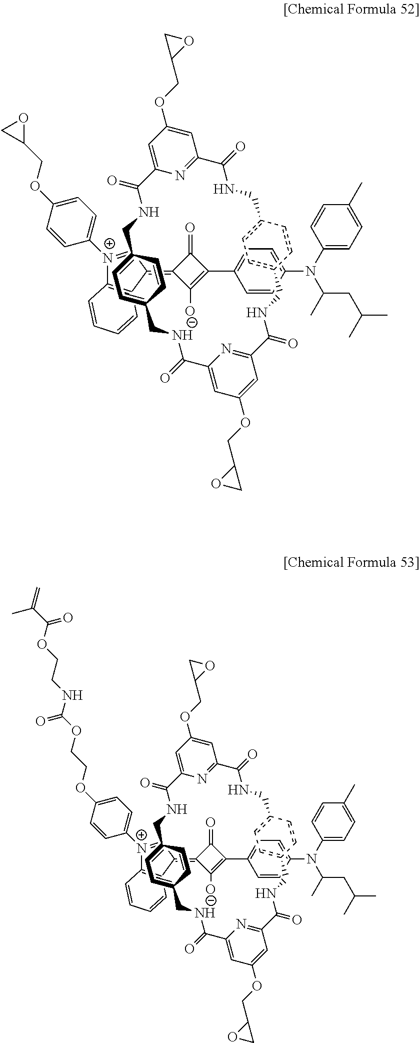

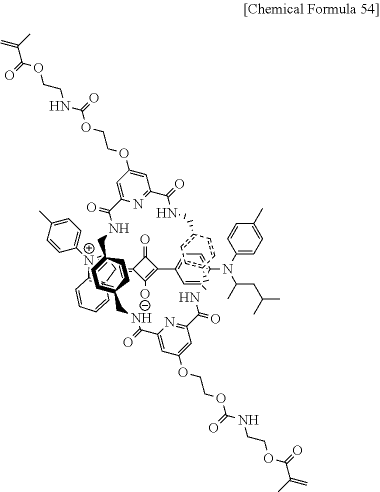

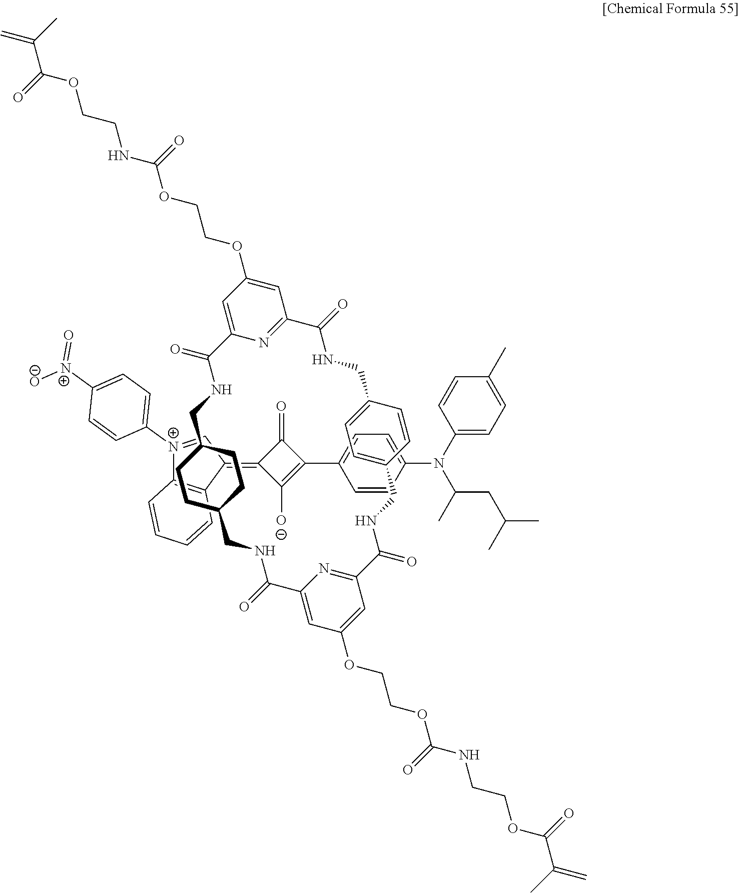

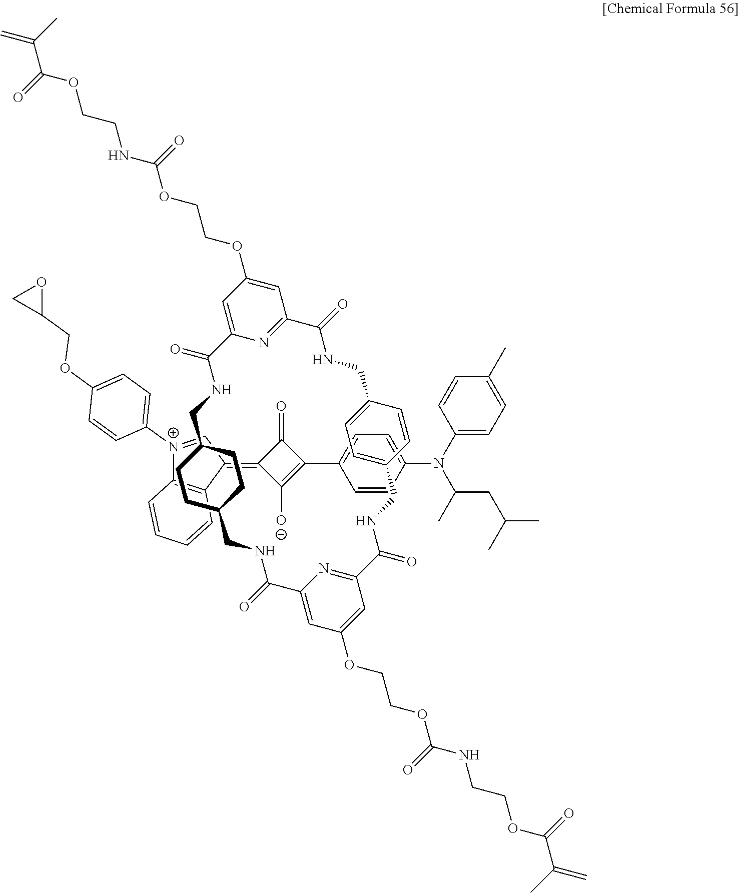

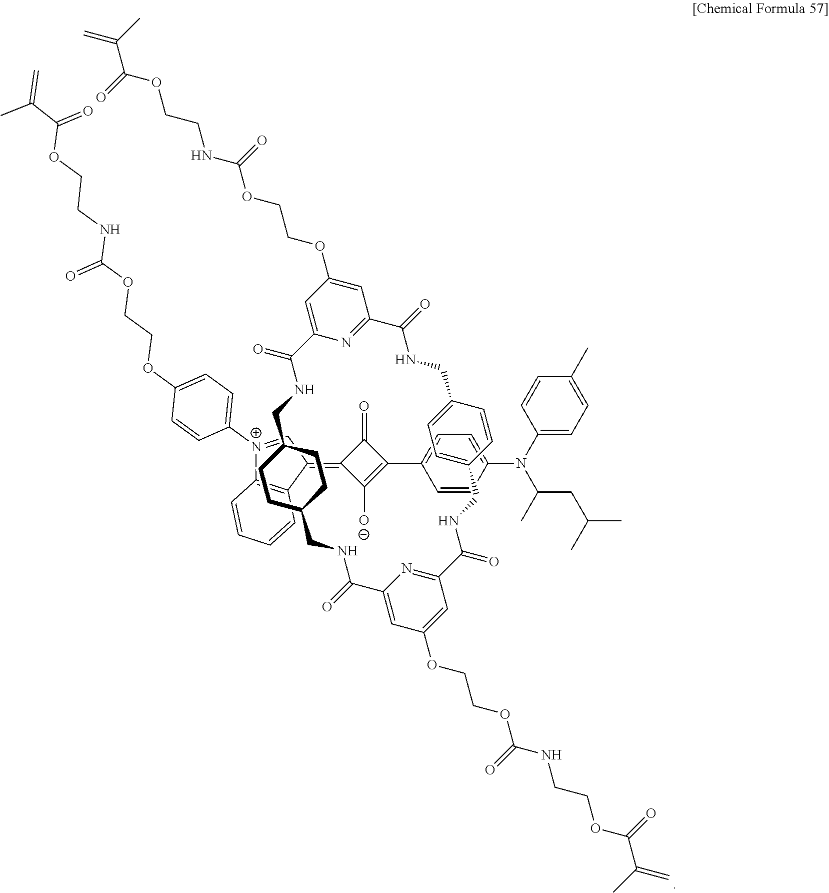

13. The core-shell dye of claim 1, wherein
the core-shell dye includes the core and the shell in a mole ratio of 1:1.

14. A photosensitive resin composition comprising the core-shell dye of any one of claim 1 to claim 13.

15. The photosensitive resin composition of claim 14, wherein
the photosensitive resin composition further includes a binder resin, a photopolymerizable monomer, a photopolymerization initiator, and a solvent.

16. The photosensitive resin composition of claim 15, wherein
the photosensitive resin composition further includes malonic acid, 3-amino-1,2-propanediol, a silane-based coupling agent including a vinyl group or a (meth)acryloxy group, a leveling agent, a surfactant, a radical polymerization initiator, or a combination thereof.

17. A photosensitive resin film manufactured using the photosensitive resin composition of claim 14.

18. A color filter comprising the photosensitive resin film of claim 17.

19. A CMOS image sensor comprising the color filter of claim 18.
